(19) United States
(12) Patent Application Publication
(10) Pub. No.: US 2016/0107178 A1
(43) Pub. Date: Apr. 21, 2016

(54) ELECTROSPRAYING SYSTEMS AND ASSOCIATED METHODS

(71) Applicant: MASSACHUSETTS INSTITUTE OF TECHNOLOGY, Cambridge, MA (US)

(72) Inventors: Luis Fernando Velásquez-García, Newton, MA (US); Frances Ann Hill, Cambridge, MA (US); Philip James, Ponce De Leon, NY (US)

(73) Assignee: Massachusetts Institute of Technology, Cambridge, MA (US)

(21) Appl. No.: 14/892,847

(22) PCT Filed: May 28, 2014
(86) PCT No.: PCT/US14/39851

§ 371 Date: Nov. 20, 2015

Related U.S. Application Data
(63) Continuation-in-part of application No. 13/918,759, filed on Jun. 14, 2013.
Application No. 13/918,759 is a continuation-in-part of application No. 13/918,742, filed on Jun. 14, 2013.
(60) Provisional application No. 61/827,893, filed on May 28, 2013.
(60) Provisional application No. 61/827,905, filed on May 28, 2013.

(51) Int. Cl. B05B 5/057; C23C 16/44; C23C 16/50; B05B 5/025

(52) U.S. Cl. CPC B05B 5/057; B05B 5/0255; C23C 16/44; C23C 16/50

(57) ABSTRACT

Electrospraying systems and associated methods are generally described.

### RELATED APPLICATIONS

This application is a national stage filing under 35 U.S.C. §371 of International Application Number PCT/US2014/039851, filed May 28, 2014, entitled “Electrospraying Systems and Associated Methods,” which is a continuation-in-part of U.S. patent application Ser. No. 13/918,742, filed Jun. 14, 2013, and entitled “Electrospraying Systems and Associated Methods,” which claims priority under 35 U.S.C. §119(e) to U.S. Provisional Patent Application Ser. No. 61/827,905, filed May 28, 2013, and entitled “High-Throughput Manufacturing of Nanofibers Using Massive Arrays of Electrospinning Emitters” and U.S. Provisional Patent Application Ser. No. 61/827,893, filed May 28, 2013, and entitled “Bio-Inspired Electrospray Emitter Arrays for High-Throughput Ionization of Liquids,” each of which applications is incorporated herein by reference in its entirety for all purposes. International Application Number PCT/US2014/039851 is also a continuation-in-part of U.S. patent application Ser. No. 13/918,759, filed Jun. 14, 2013, and entitled “Electrically-Driven Fluid Flow and Related Systems and Methods, Including Electrospinning and Electrospraying Systems and Methods,” which claims priority under 35 U.S.C. §119(e) to U.S. Provisional Patent Application Ser. No. 61/827,905, filed May 28, 2013, and entitled “High-Throughput Manufacturing of Nanofibers Using Massive Arrays of Electrospinning Emitters” and U.S. Provisional Patent Application Ser. No. 61/827,893, filed May 28, 2013, and entitled “Bio-Inspired Electrospray Emitter Arrays for High-Throughput Ionization of Liquids,” each of which applications is incorporated herein by reference in its entirety for all purposes.

### GOVERNMENT SPONSORSHIP

This invention was made with government support under Grant No. W31P4Q-11-1-0007 awarded by the Army Contracting Command. The government has certain rights in the invention.

### TECHNICAL FIELD

Electrospraying systems and associated methods are generally described.

### BACKGROUND

Electrospraying refers to methods in which a voltage is applied to a liquid (e.g., an ionic liquid or other suitable liquid) to produce ions and/or small droplets of charged liquid. In many electrospraying systems, the liquid is fed to a tip of a protrusion (e.g., a needle). Application of a sufficiently high voltage results in electrostatic repulsion within components of the liquid. The electrostatic repulsion counteracts the surface tension of the liquid, and a stream of liquid erupts from the surface. In many electrospraying systems, when the liquid is fed to the tip of the protrusion and the voltage is applied, varicose waves on the surface of the resulting liquid jet lead to the formation of small and highly charged liquid droplets, which are radially dispersed due to Coulomb repulsion.

While electrospraying is known in the art, most electrospraying systems include a single protrusion, for example, in the form of a single needle. Electrospraying systems that include multiple protrusions are generally not able to discharge liquid from the protrusions in a uniform fashion. Increasing the throughput of such systems while avoiding degradation in performance has proven to be difficult. Increasing the throughput from a single protrusion has resulted in modest improvement, but has generally been accompanied by deterioration of the spread in the properties of the emitted liquid (e.g., size, shape, and the like). Increasing throughput by utilizing large arrays with high protrusion density has proven to be challenging.

### SUMMARY

Electrospraying systems and associated methods are generally described. The subject matter of the present invention involves, in some cases, interrelated products, alternative solutions to a particular problem, and/or a plurality of different uses of one or more systems and/or articles.

Certain embodiments relate to emitters configured for use in an electrospraying device. In some embodiments, the emitter comprises an array of protrusions extending from an emitter substrate, at least a portion of the protrusions in the array comprising a plurality of elongated nanostructures extending from external surfaces of the protrusions.

In some embodiments, the emitter comprises an array of protrusions extending from an emitter substrate, at least a portion of the protrusions in the array comprising a plurality of ordered nanostructures extending from external surfaces of the protrusions.

In certain embodiments, the emitter comprises an array of protrusions extending from an emitter substrate, at least a portion of the protrusions in the array comprising a plurality of nanostructures extending from an ordered intermediate material between the nanostructures and external surfaces of the protrusions.

Systems and methods comprising the emitters described herein are also provided. Certain embodiments relate to a method of making an emitter configured for use in an electrospraying device. In some embodiments, the method comprises etching a fabrication substrate to produce a plurality of protrusions extending from the fabrication substrate; and depositing a plurality of nanostructures on external surfaces of the protrusions.

Certain embodiments relate to emitters configured for use in electrospraying and/or electrospinning systems. In some embodiments, the emitter comprises an array of protrusions extending from an emitter substrate, at least a portion of the protrusions in the array comprising a plurality of microstructures extending from external surfaces of the protrusions, wherein the microstructures are arranged on the surfaces of the protrusions in an ordered fashion.

In some of the preceding embodiments, the microstructures can be configured to transport fluid from bases of the protrusions to tips of the protrusions via capillary forces. In some of the preceding embodiments, the protrusions have an aerial density of at least about 9 protrusions/cm². In some such embodiments, the protrusions have an aerial density of from about 9 protrusions/cm² to about 100,000 protrusions/cm². In some of the preceding embodiments, the protrusions do not contain internal fluid passageways. In some of the preceding embodiments, the microstructures can be arranged such that each microstructure has a nearest neighbor distance, and the standard deviation of the nearest neighbor distances of the microstructures is less than about 100% of the average of the nearest neighbor distances of the microstructures. In some of the preceding embodiments, the microstructures can be arranged substantially periodically. In some of the preceding embodiments, the microstructures comprise nanostructures. In some of the preceding embodiments, the protrusions can be substantially uniform in shape. In some of the preceding embodiments, the protrusions have volumes, and the standard deviation of the volumes of the protrusions is less than about 100% of the average of the volumes of the protrusions. In some of the preceding embodiments, the protrusions comprise tips having radii of curvature, and the standard deviation of the radii of curvature of the protrusion tips is less than about 100% of the average of the radii of curvature of the protrusion tips. In some of the preceding embodiments, the array of protrusions is a substantially planar array. In some of the preceding embodiments, the protrusions are substantially perpendicular to the emitter substrate.

In some embodiments, the emitter comprises an emitter substrate; and a protrusion substrate comprising a base that links to the emitter substrate and a plurality of protrusions extending from the base.

In some of the preceding embodiments, the emitter substrate comprises a linking surface area and the protrusion substrate base comprises a linking surface area configured to fasten to the linking surface area of the emitter substrate. In some such embodiments, at least one of the protrusion substrate base and the emitter substrate comprises an indentation into which a portion of the other of the protrusion substrate base and the emitter substrate can be positioned. In some of the preceding embodiments, the protrusion substrate base and the emitter substrate are linked via a tongue and groove fitting.

In some embodiments, the emitter comprises a plurality of protrusion substrate bases linked to the emitter substrate. In some of the preceding embodiments, at least some of the protrusions comprise microstructures extending from an external surface of the protrusion. In some of the preceding embodiments, longitudinal axis of at least some of the protrusions are substantially perpendicular to the emitter substrate. In some of the preceding embodiments, the emitter comprises an array of protrusions having an aerial density of at least about 10 protrusions/cm². In some of the preceding embodiments, at least a portion of the protrusion substrate is made of silicon. In some of the preceding embodiments, the protrusion substrate is microfabricated.

Certain embodiments relate to systems. In some embodiments, the system comprises an emitter comprising an array of at least about 9 protrusions extending from an emitter substrate and having an aerial density of at least about 9 protrusions/cm²; and an electrode; wherein, when a voltage is applied across the emitter and the electrode and the emitter is exposed to a fluid, the fluid is essentially simultaneously emitted in substantially continuous streams from at least about 10% of the protrusions in the array toward the electrode.

In some of the preceding embodiments, the protrusions have an aerial density of between about 9 protrusions/cm² and about 100,000 protrusions/cm². In some of the preceding embodiments, when a voltage is applied across the emitter and the electrode and the emitter is exposed to a fluid, a significant portion of the fluid is externally surface directed from at least about 10% of the protrusions in the array toward the electrode. In some of the preceding embodiments, the protrusions do not contain internal fluid passageways.

In some of the preceding embodiments, the system comprises a voltage source configured to apply the voltage across the emitter and the electrode. In some of the preceding embodiments, when the voltage is applied across the emitter and the electrode and the emitter is exposed to a fluid, the fluid is essentially simultaneously emitted from at least about 99% of the protrusions in the array toward the electrode. In some of the preceding embodiments, when the voltage is applied across the emitter and the electrode and the emitter is exposed to a fluid, the fluid is essentially simultaneously emitted from all of the protrusions in the array toward the electrode. In some of the preceding embodiments, when the voltage is applied across the emitter and the electrode and the emitter is exposed to a fluid, the fluid is emitted in droplets toward the electrode. In some such embodiments, the droplets can be substantially monodisperse. In some of the preceding embodiments, when the voltage is applied across the emitter and the electrode and the emitter is exposed to a fluid, the fluid is emitted in continuous streams toward the electrode. In some such embodiments, the standard deviation of the cross-sectional diameters of the continuous streams is less than 100% of the average of the cross-sectional diameters of the continuous streams. In some of the preceding embodiments, fluid is essentially simultaneously emitted from at least about 10% of the protrusions in the array toward the electrode when a voltage of less than about 10 kilovolts is applied across the emitter and the electrode. In some of the preceding embodiments, fluid is essentially simultaneously emitted from at least about 10% of the protrusions in the array toward the electrode when a voltage of from about 100 volts to about 10 kilovolts is applied across the emitter and the electrode.

In some of the preceding embodiments, the protrusions can be substantially uniform in shape. In some of the preceding embodiments, at least a portion of the protrusions have heights of at least about 1 mm. In some of the preceding embodiments, at least a portion of the protrusions have heights of at least about 2 mm. In some of the preceding embodiments, the protrusions have volumes, and the distribution of the volumes of the protrusions is less than about 100% of the average of the volumes of the protrusions. In some of the preceding embodiments, the protrusions comprise tips having radii of curvature, and the distribution of the radii of curvature of the protrusion tips is less than about 100% of the average of the radii of curvature of the protrusion tips. In some of the preceding embodiments, the array of protrusions is a substantially planar array. In some of the preceding embodiments, the protrusions can be substantially perpendicular to the emitter substrate. In some of the preceding embodiments, the system is configured such that a charged fluid is emitted from the protrusions. In some of the preceding embodiments, the system is configured such that a fluid comprising a polymer is emitted from the protrusions.

In some embodiments, methods are described. The method comprises, in some embodiments, applying a voltage across an emitter comprising an array of at least about 9 protrusions extending from an emitter substrate and having an aerial density of at least about 9 protrusions/cm² and an electrode such that fluid positioned between the emitter and the electrode is essentially simultaneously emitted in substantially continuous streams from at least about 10% of the protrusions in the array toward the electrode.

In some of the preceding embodiments, the protrusions have an aerial density of between about 9 protrusions/cm² and about 100,000 protrusions/cm². In some of the preceding embodiments, applying the voltage across the emitter and the electrode results in a significant portion of the fluid being directed along the external surface of at least about 10% of the protrusions in the array toward the electrode. In some of the preceding embodiments, the protrusions do not contain internal fluid passageways. In some of the preceding embodiments, the fluid is essentially simultaneously emitted from at least about 99% of the protrusions in the array toward the electrode. In some of the preceding embodiments, the fluid is essentially simultaneously emitted from all of the protrusions in the array toward the electrode. In some of the preceding embodiments, droplets of the fluid are emitted from the protrusions toward the electrode. In some such embodiments, the droplets can be substantially monodisperse.

In some of the preceding embodiments, substantially continuous streams of the fluid are emitted from the protrusions toward the electrode. In some such embodiments, the standard deviation of the cross-sectional diameters of the continuous streams is less than 100% of the average of the cross-sectional diameters of the continuous streams.

In some of the preceding embodiments, applying a voltage comprises applying a voltage of less than about 10 kilovolts across the emitter and the electrode. In some of the preceding embodiments, applying a voltage comprises applying a voltage of from about 100 volts to about 10 kilovolts across the emitter and the electrode. In some of the preceding embodiments, the fluid is a charged fluid. In some of the preceding embodiments, the fluid comprises a polymer. In some of the preceding embodiments, the fluid is emitted in a direction that is substantially perpendicular to the emitter substrate. In some of the preceding embodiments, the fluid is emitted in a direction that is substantially parallel to longitudinal axes of the protrusions. In some of the preceding embodiments, the flow rate of the fluid at a plurality of protrusions is at least about 5×10⁻¹³ m³/s per protrusion. In some of the preceding embodiments, the fluid has a viscosity at 25° C. of at least about 1 Pa-s. In some of the preceding embodiments, the fluid is simultaneously emitted from at least about 10% of the protrusions for a continuous period of at least about 30 seconds.

In certain embodiments, the method comprises etching a fabrication substrate to produce a structure comprising a base, a first set of protrusions extending from the base, and a second set of protrusions extending from external surfaces of the first set of protrusions.

In some of the preceding embodiments, etching the fabrication substrate comprises performing reactive ion etching. In some of the preceding embodiments, the method comprises first etching the fabrication substrate to produce the structure comprising the base and the first set of protrusions extending from the base, and subsequently etching the structure comprising the base and the first set of protrusions to produce a second set of protrusions extending from the external surfaces of the first set of protrusions. In some of the preceding embodiments, the method comprises first etching the fabrication substrate to produce the second set of protrusions, and subsequently etching the fabrication substrate to produce the structure comprising the base and the first set of protrusions extending from the base such that the first set of protrusions includes the second set of protrusions extending from the external surfaces of the first set of protrusions. In some of the preceding embodiments, the first and second etching steps can be performed using the same type of etching procedure. In some of the preceding embodiments, the first and second etching steps can be performed using reactive ion etching. In some of the preceding embodiments, the first and second etching steps can be performed using different types of etching procedures.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A is an exemplary schematic illustration of a system used to perform electrospraying comprising a single emitter protrusion;

FIG. 1B is an exemplary schematic illustration of a system used to perform electrospraying comprising an array of emitter protrusions;

FIG. 2A is, according to some embodiments, a perspective view schematic diagram of an emitter substrate comprising an array of protrusions;

FIG. 2B is a perspective view schematic illustration of a protrusion within an emitter substrate, comprising a plurality of nanostructures, according to certain embodiments;

FIG. 2C is an exemplary schematic illustration of an extractor electrode comprising a plurality of apertures;

FIG. 2D is an exemplary schematic illustration of an emitter comprising a plurality of protrusions;

FIG. 2E is a perspective view schematic illustration of an electrospraying system in which an extractor electrode is positioned over an emitter;

FIG. 2F is a cross-sectional schematic illustration of the electrospraying system shown in FIG. 2E, which comprises an extractor electrode positioned over an emitter;

FIGS. 3A-3H are, according to one set of embodiments, cross-sectional schematic diagrams illustrating a process for fabricating an emitter substrate comprising a plurality of protrusions;

FIGS. 3I-3P are, according to one set of embodiments, cross-sectional schematic diagrams illustrating a process for fabricating an extractor electrode;

FIG. 4 is a set of exemplary schematic illustrations of an electrospraying extractor grid die, an exemplary electrospraying emitter die, and the assembly of the extractor and emitter dies into an electrospraying diode using dowel pins and insulating spacers, according to one set of embodiments;

FIG. 5A is a photograph of an exemplary assembled electrospraying emitter, according to certain embodiments;

FIG. 5B is an SEM image illustrating the alignment of a protrusion tip and an extractor aperture, according to one set of embodiments;

FIG. 6A is an exemplary image of an extractor grid for an array of 81 electrospraying protrusions within a 1 cm² area, according to one set of embodiments;

FIG. 6B an exemplary emitter die, according to one set of embodiments, for an array of 81 electrospraying protrusions within a 1 cm² area;

FIG. 7A is, according to certain embodiments, an exemplary SEM image of an electrospraying protrusion;

FIG. 7B is an exemplary SEM image of aligned carbon nanotubes (CNTs) on the external surface of an exemplary electrospraying protrusion, according to some embodiments;

FIG. 8 is, according to one set of embodiments, a schematic of an electrospraying testing circuit;

FIG. 9 is an exemplary plot of collector current per protrusion as a function of emitter-to extractor bias voltage for an emitter comprising a 7 by 7 array of protrusions, with 360 μm and 600 μm emitter-to-extractor spacing. according to one set of embodiments;

FIG. 10 is, according to certain embodiments, an exemplary plot of collector current as a function of emitter to extractor bias voltage for an emitter comprising a 9 by 9 array of emitting protrusions;

FIG. 11 is, according to one set of embodiments, an exemplary plot of collector current per protrusion as a function of emitter-to extractor bias voltage for five different emitter arrays;

FIGS. 12A-12B are, according to one set of embodiments, exemplary electrospray imprints on a 2 cm by 2 cm silicon collector electrode for (A) an emitter comprising a 2 by 2 array of protrusions and (B) an emitter comprising a 7 by 7 array of emitter protrusions;

FIGS. 13A-13C are SEM images of arrays of protrusions over which carbon nanotubes are arranged;

FIG. 14 is an exemplary plot, according to one set of embodiments, of collector current per protrusion as a function of emitter-to extractor bias voltage for an emitter comprising an array of 1900 protrusions per cm²;

FIGS. 15A-B are, according to one set of embodiments, images of: (A) an extractor grid die for an array of 1900 emitting protrusions; and (B) an emitter die for an array of 1900 emitting protrusions;

FIG. 16 is an SEM image illustrating the alignment of a protrusion tip with an extractor aperture, according to some embodiments;

FIG. 17 is a Raman spectrum of a CNT forest grown on an exemplary electrospraying device, according to some embodiments;

FIGS. 18A-B are images showing, according to some embodiments: (A) the spreading of an ionic liquid on the CNT-coated surface of an emitter die for an array of 25 emitting protrusions; and (B) the spreading of an ionic liquid on the CNT-coated surface of an emitter die for an array of 1900 emitting protrusions;

FIG. 19 is an exemplary plot of collector current as a function of emitter-to-extractor bias voltage for an array of 1900 emitting protrusions, according to some embodiments;

FIG. 20 is an exemplary plot of flow rate as a function of emitter-to-extractor bias voltage that illustrates the effect of hydraulic impedance, according to some embodiments;

FIGS. 21A-B are, according to one set of embodiments, exemplary mass spectra of electrospray emission for an array emitting: (A) positive ions and (B) negative ions;

FIGS. 22A-B are, according to one set of embodiments, exemplary electrospray imprints on a collector electrode for (A) an array of 25 emitting protrusions; and (B) an array of 1900 emitting protrusions; FIGS. 23A-B are, according to some embodiments: (A) an SEM image of deposits on a collector plate from the emission of an electrospray source; and (B) an edge view of the cross-section of a collector plate;

FIGS. 24A-B are, according to one set of embodiments, exemplary plots of calculated thrust per emitting protrusion as a function of emitter-to-extractor bias voltage for: (A) sparse emitter arrays; and (B) dense emitter arrays;

FIG. 25 shows TEM images of exemplary tungsten particles sputtered at 100 W into EMI-BF₄ on a TEM grid, according to one set of embodiments;

FIG. 26 shows TEM images of exemplary tungsten particles sputtered at 200 W into EMI-BF₄ on a TEM grid, according to one set of embodiments;

FIG. 27 shows an exemplary plot of collector current as a function of emitter-to-extractor bias voltage for EMI-BF₄ sputtered with tungsten at 100 W, according to certain embodiments;

FIG. 28A is a perspective-view schematic illustration of an emitter comprising an array of protrusions, according to certain embodiments;

FIG. 28B is, according to some embodiments, a perspective-view schematic illustration of a plurality of microstructures on the external surface of a protrusion;

FIG. 29 is an exemplary perspective view schematic illustration of a system for performing electrospinning and/or electrospraying, according to certain embodiments;

FIGS. 30A-30M are cross-sectional schematic diagrams illustrating a process for fabricating a protrusion substrate comprising a plurality of microstructures, according to one set of embodiments;

FIG. 30N is a top-view schematic illustration of the protrusion illustrated in FIG. 30M, according to one set of embodiments;

FIG. 30O is a top-view schematic illustration of a mask that can be used to fabricate a protrusion substrate, according to certain embodiments;

FIGS. 31A-31D are cross-sectional schematic diagrams illustrating a process for fabricating a plurality of microstructures on a protrusion, according to one set of embodiments;

FIG. 32 is a perspective view schematic illustration of an electrospinning system, according to certain embodiments;

FIG. 33A is a scanning electron microscope (SEM) image of a plurality of micropillars on an emitter protrusion, according to one set of embodiments;

FIG. 33B is an image illustrating the hemi-wicking spread of a droplet through microstructured features of an emitter protrusion, according to some embodiments;

FIGS. 34A-34B are, according to one set of embodiments, (A) a front view and (B) a side view of an electric field simulation in which 1 Volt has been applied across an emitter and extractor electrode spaced 3 cm apart;

FIGS. 35A-35B are, according to one set of embodiments, (A) side view and (B) top view SEM images of an emitter protrusion including microstructured features;

FIGS. 36A-36B are (A) a perspective view and (B) a top view of an experimental setup of an electrospinning system;

FIGS. 37A-37B are SEM images of an exemplary unwoven fiber mat produced using an exemplary electrospinning system;

FIGS. 38A-38D are photographs of (A) a 3×3 array of 5-millimeter tall emitters, (B) a Taylor cone emission, (C) a single stream emission, and (D) a multiple-stream emission during an exemplary electrospinning experiment; and

FIGS. 39A-39B are, according to one set of embodiments, photographs of emission from 5-millimeter tall emitting protrusions.

### DETAILED DESCRIPTION

Electrospraying systems and associated methods are generally described. Certain embodiments relate to the discovery that nanostructural features can be arranged on emitter protrusions to achieve desired performance in electrospraying systems. In certain embodiments, nanostructural features are arranged in an ordered fashion such that the flow of fluid to the tips of protrusions occurs at a consistent (and, in certain cases, controlled) rate. Transporting fluid to the tips of the protrusions at a consistent rate can allow one to, for example, produce a consistent discharge of fluid from a plurality of protrusions within an array while maintaining consistent (and, in certain instances, controllable) properties of the emitted fluid (e.g., size, shape, and the like). This can allow one to scale up electrospraying systems in which fluid is emitted from the tips of protrusions (e.g., by employing multiple emitter protrusions) such that the throughput of fluid through the system is increased while maintaining the ability to produce discharged fluid (e.g., in the form of threads, droplets, ions, and the like) with uniform properties.

According to certain embodiments, the systems and methods described herein can allow one to produce discharged fluid droplets and/or ions with consistent, relatively small dimensions simultaneously from multiple protrusions within an array. In certain such embodiments, discharged droplets and/or ions with relatively small dimensions can be produced while operating the electrospraying system at a relatively low voltage. Without wishing to be bound by any particular theory of operation, the ability to produce discharged fluid having small features at relatively small applied voltages might be explained as follows. In many protrusion-based electrospraying systems, discharge of fluid from the tips of the protrusions is achieved after a threshold voltage is applied across the emitter comprising the protrusions and a counter electrode (also sometimes referred to herein as the “extractor electrode”). It is believed that the application of a voltage above the threshold voltage triggers instability in the fluid at the protrusion tips, producing fluid discharge (e.g., in the form of droplets and/or ions of the fluid). It is believed that the use of protrusions with smaller tips can allow one to operate at smaller applied voltage. It is also believed that the dimensions of the discharged fluid depend on flow rate (rather than applied voltage), and that slower flow rates generally tend to produce smaller emitted fluid dimensions. Accordingly, restriction of the flow rate to the protrusion tip can allow for the emission of fluid having small features while also allowing for relatively low voltage operation. In some embodiments, the dimensions and layout of the nanostructures can be used to control (e.g., restrict) the flow of fluid to the tips of the protrusions in an emitter, which can be useful in producing droplets with relatively small cross-sectional dimensions. In certain such embodiments, the dimensions and/or arrangement of the nanostructures can be selected to produce a desired flow rate to the tips of the protrusions upon the application of a voltage, thereby allowing for the control, in certain instances, of the dimensions of the discharged fluid. In certain such embodiments, the dimensions of the protrusions can also be controlled to allow for low voltage operation, for example, at voltages very close to the fluid instability threshold voltage.

Certain embodiments relate to inventive fabrication techniques that can be used to produce emitters and extractor electrodes for use in electrospraying systems with advantageous properties. For example, certain of the fabrication techniques described herein can allow for the production of emitters comprising an array of protrusions with elongated nanostructures (such as, for example, nanotubes) in contact with the protrusions. Certain systems and methods involve the fabrication and/or use of emitters comprising an array of protrusions with nanostructures arranged on the external surfaces of the protrusions in an ordered fashion. Such ordered nanostructures can be formed on the protrusions, in some embodiments, without substantially affecting the consistency of the sizes and/or shapes of the protrusions themselves.

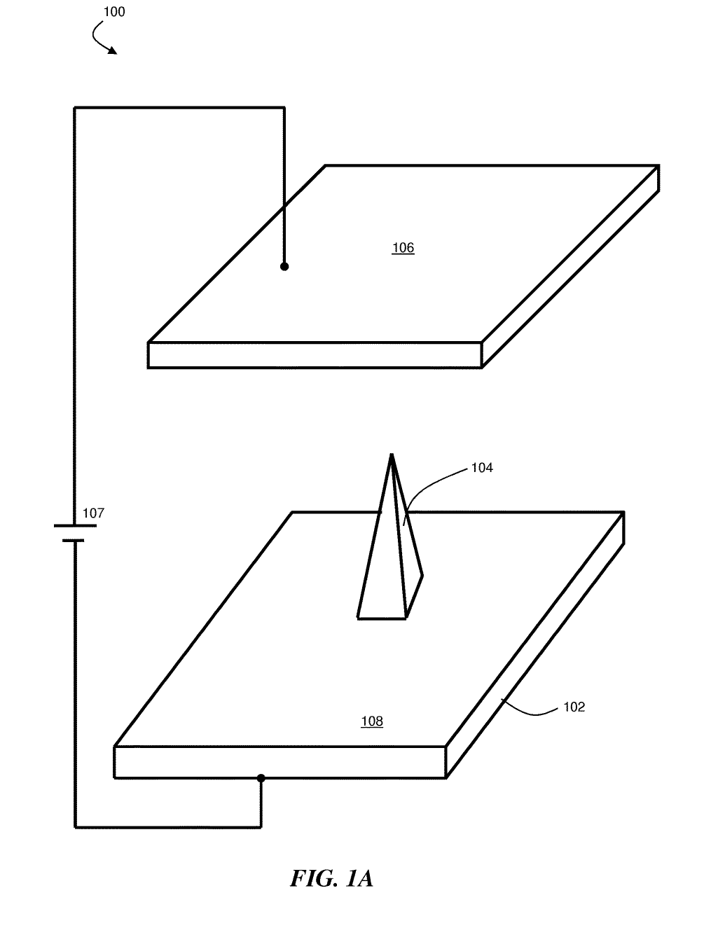

FIG. 1A is an exemplary schematic illustration of a conventional electrospraying system 100. Electrospraying system 100 comprises an emitter 102 comprising a protrusion 104 and an electrode 106. When a voltage is applied across emitter 102 and electrode 106 (e.g., via voltage source 107), fluid fed to protrusion 104 is discharged from the protrusion 104 in the direction of electrode 106. Many conventional electrospraying systems, such as system 100, include a single protrusion from which fluid is emitted. The amount of fluid flux in such systems is generally limited, due to the presence of only a single protrusion.

One way to increase the amount of fluid that is discharged in an electrospraying system is to include multiple protrusions from which liquid is emitted. This can allow, in certain embodiments, efficient emission through each protrusion while increasing the throughput by virtue of having a plurality of protrusions operating in parallel. Accordingly, in some embodiments, the electrospraying systems comprise an emitter and an electrode, where the emitter comprises a plurality of protrusions. For example, as illustrated in FIG. 1B, emitter 102 comprises a plurality of protrusions 104. The protrusions can be arranged such that they extend from an emitter substrate. For example, in FIG. 1B, protrusions 104 extend from emitter substrate 108.

In some embodiments, the emitter may be exposed to a fluid (e.g., an ionic liquid or any other suitable liquid) and a voltage may be applied across the emitter and electrode. Applying the voltage across the emitter and the electrode may result in the emission of fluid from the tips of at least a portion of the protrusions of the emitter toward the electrode. The fluid that is emitted from the emitter may comprise, for example, ions, solvated ions, and/or droplets. Referring to FIG. 1B, for example, system 120 may comprise electrode 106 (which is sometimes referred to herein as an extractor electrode) and voltage source 107. In certain embodiments, when emitter 102 is exposed to a fluid, and voltage is applied across emitter 102 and electrode 106, fluid 110 may be emitted from the tips of protrusions 104 toward electrode 106.

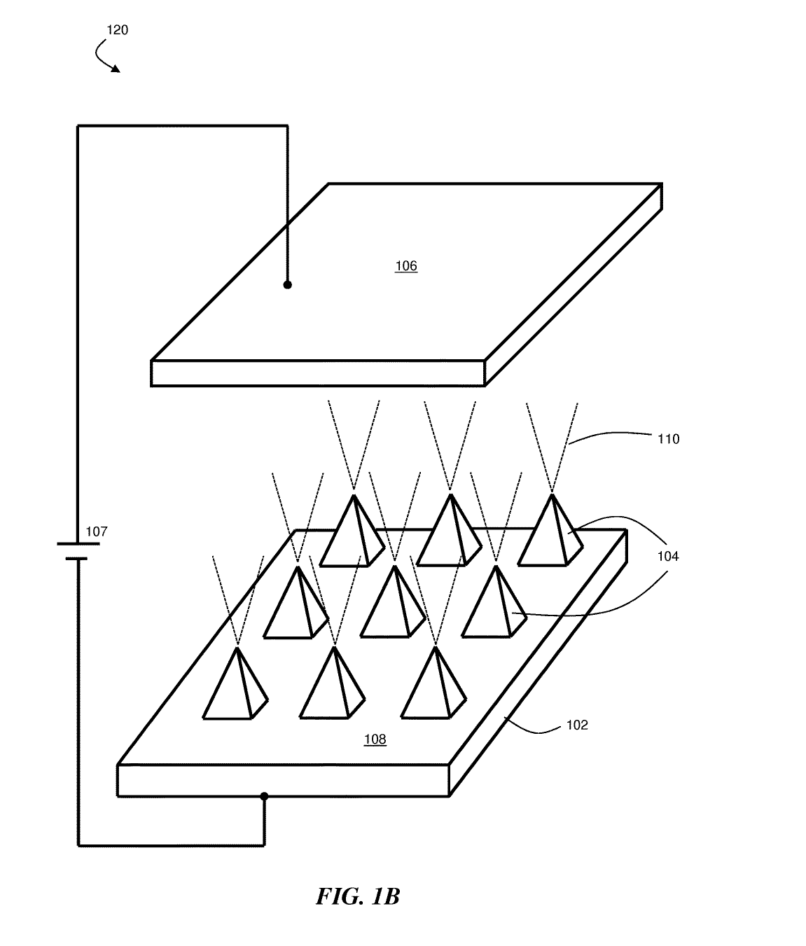

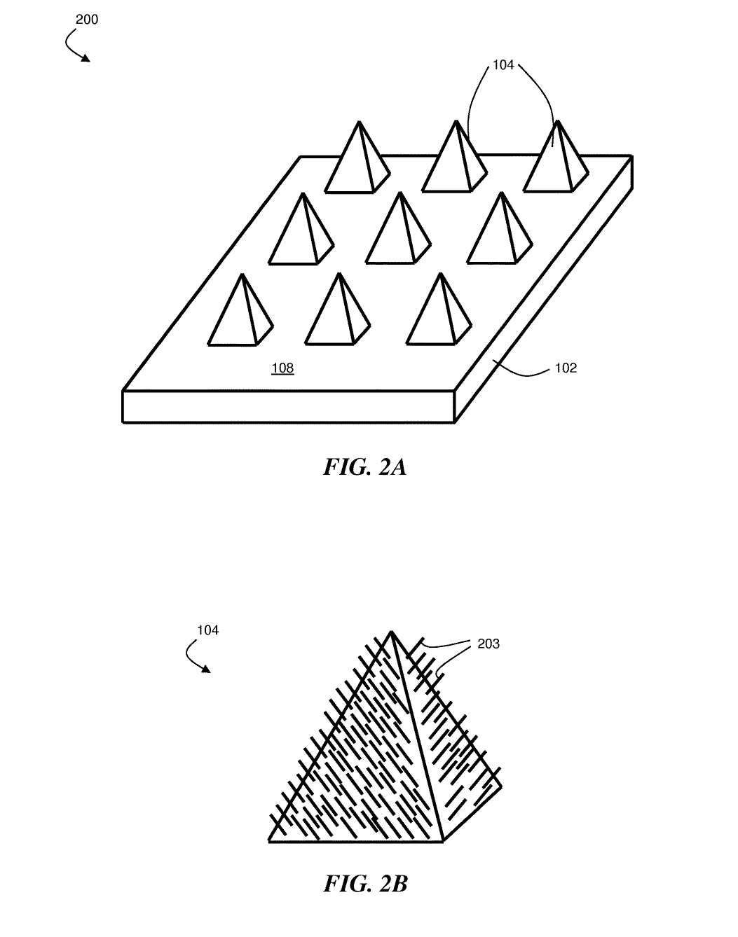

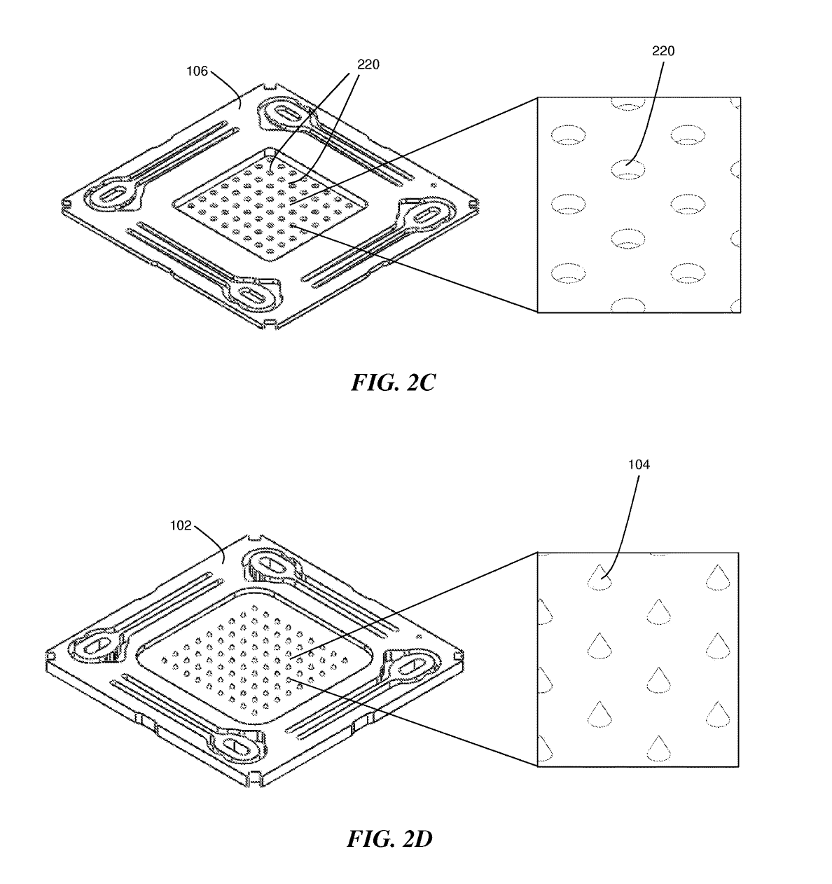

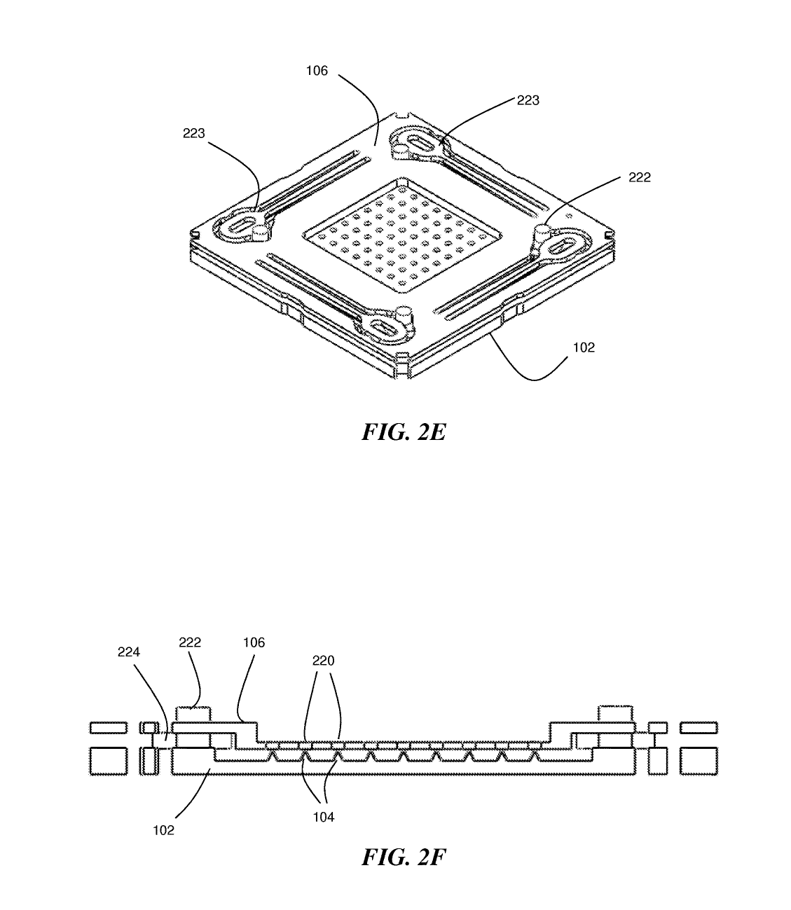

In certain embodiments, at least a portion of the protrusions in the array comprises a plurality of nanostructures extending from external surfaces of the protrusions. For example, FIG. 2A is an exemplary schematic illustration of emitter 102 comprising emitter substrate 108 and protrusions 104 extending from emitter substrate 108. The protrusions illustrated in FIG. 2A are arranged in a 3 by 3 array. However, arrays containing more or fewer protrusions are also possible, as described in more detail below. FIG. 2B is an exemplary schematic illustration of a protrusion 104 of emitter 102 in FIG. 2A. As illustrated in FIG. 2B, nanostructures 203 extend from the external surfaces of protrusions 104. In some embodiments, one or more (or all) protrusions may contain a relatively large number of nanostructures. For example, a protrusion may contain at least about 100, at least about 1,000, at least about 10,000, or at least about 100,000, or more nanostructures.

The presence of a plurality of nanostructures on external surfaces of at least a portion of the protrusions of an emitter array may result in enhanced properties, in certain embodiments. The nanostructures may, in some embodiments, be configured to transport fluid from the bases of the protrusions to the tips of the protrusions, where the electric field is generally the strongest, via capillary forces. Without wishing to be bound to a particular theory, the nanostructures may be advantageous because they provide a wetting structure on which fluid can spread. Additionally, the nanostructures may be advantageous because they provide hydraulic impedance to the fluid flow along the protrusion surface, allowing the flow rate fed to each protrusion to be controlled. The flow rate fed to a protrusion may determine whether the fluid emitted from the protrusion comprises ions, solvated ions, and/or droplets, as well as the size and shape of the emitted ions, solvated ions, and/or droplets. In some embodiments, the advantages provided by the nanostructures on the surface of the protrusions may allow high emitter current to be achieved at low voltages, while maintaining good array emission uniformity.

In certain embodiments, the nanostructures on the exterior surfaces of the emitter protrusions can be arranged in an ordered fashion. The ability to arrange the nanostructures in an ordered fashion can be important, in certain embodiments, because it can allow one to control the degree of hydraulic impedance provided by the nanostructures which, as mentioned above, can allow one to control the flow rate of the fluid provided to the tips of the emitter protrusions and allow for consistent performance of the electrospraying device.

In some embodiments, a plurality of nanostructures may extend from an ordered intermediate material between the nanostructures and the external surfaces of the protrusions. A variety of materials may be used for the intermediate material. In some cases, the intermediate material may comprise a catalyst used to form the nanostructures. Suitable catalysts include, for example, metal-based catalysts. Non-limiting examples of suitable metals include iron, gold, nickel, cobalt, tungsten, and/or aluminum. The intermediate material is not limited to catalyst materials, however, and other materials could be used. For example, the intermediate material could correspond to a material that non-catalytically enhances the formation of nanostructures over the intermediate material, relative to the substrate on which the intermediate material is formed. For example, the intermediate material may comprise silicon oxide formed over a silicon substrate, and nanostructures (e.g., carbon nanotubes) may be preferentially formed on the silicon oxide rather than the exposed silicon substrate. Other types of intermediate materials may also be used.

In some such embodiments, the intermediate material may be patterned or otherwise ordered such that nanostructures are formed only over the portions of the exterior surface of the protrusions over which the intermediate material is present. The ordering of the intermediate material may result in the formation of nanostructures positioned over the protrusions in an ordered manner.

As used herein, the term “ordered” means not random. Materials (e.g., nanostructures and/or intermediate materials positioned between nanostructures and protrusions) may be ordered, for example, by forming the materials into a predetermined pattern and/or by allowing the material to transform such that is ordered, such as via self-assembly methods.

In certain embodiments, the ordered material may be patterned over a protrusion, for example, by depositing a layer of the material over a protrusion and subsequently removing the material from at least one portion of the protrusion. As one example, in certain embodiments, the intermediate material may be formed over the protrusions and subsequently selectively removed from at least one portion of the external surfaces of the protrusions (e.g., using an etchant and a mask) such that the intermediate material is present only over desired portions of the protrusions. As another example, nanostructures may be formed (e.g., deposited, grown, or otherwise formed) over the protrusions (e.g., over an intermediate material, such as a catalyst, positioned over the protrusions) and subsequently selectively removed from at least a portion of the external surfaces of the protrusions (e.g., using an etchant and a mask) such that the nanostructures are present only over desired portions of the protrusions.

In some embodiments, the ordered material may be patterned over protrusions by selectively forming the ordered material over specific portions of the exposed surfaces of the protrusions. As one specific example, nanostructures may be patterned over protrusions by forming a catalyst only over certain portions of the external surfaces of the protrusions and subsequently catalytically growing the nanostructures such that the nanostructures are formed only over the portions of the external surfaces of the protrusions over which the catalyst is positioned.

In some embodiments, the nanostructures may be positioned such that the spacing between the nanostructures can be somewhat regular. For example, in certain embodiments, the nanostructures can each have a nearest neighbor distance, and the standard deviation of the nearest neighbor distances may be less than about 100%, less than about 50%, less than about 20%, or less than about 10% of the average of the nearest neighbor distances. As used herein, the term “nearest neighbor distance” is understood to be the distance from the center of a structure to the center of the structure's nearest neighbor. In some embodiments, the nanostructures may be arranged as a periodically repeating array of nanostructures.

The standard deviation (lower-case sigma) of a plurality of values is given its normal meaning in the art, and can be calculated as:

$$σ = \sqrt{\frac{{\sum }_{i = 1}^{n} {( {V}_{i} - {V}_{avg} )}^{2}}{n - 1}} \qquad [ 1 ]$$

wherein Vᵢ is the i^{th} value among n total values, V_{avg} is the average of the values, and n is the total number of values. The percentage comparisons between the standard deviation and the average of a plurality of values can be obtained by dividing the standard deviation by the average and multiplying by 100%. As an illustrative example, to calculate the percentage standard deviation of a plurality of nearest neighbor distances for 10 nanostructures, one would calculate the nearest neighbor distance for each nanostructure (V₁ through V₁₀), calculate V_{avg} as the number average of the nearest neighbor distances, calculate a using these values and Equation 1 (setting n=10), divide the result by V_{avg}, and multiply by 100%.

In certain embodiments, the intermediate material may be arranged as a plurality of islands of the intermediate material. In some such cases, each of the islands of intermediate material may have a nearest neighbor distance, and the standard deviation of the nearest neighbor distances may be less than about 100%, less than about 50%, less than about 20%, or less than about 10% of the average of the nearest neighbor distances. In some embodiments, the plurality of islands of intermediate material may be arranged as a periodically repeating array of islands of intermediate material.

A variety of nanostructures can be used in association with certain of the embodiments described herein. As used herein, the term “nanostructure” refers to any structure having at least one cross-sectional dimension, as measured between two opposed boundaries of the nanostructure, of less than about 1 micron. In certain embodiments, the nanostructures can be elongated nanostructures. For example, in some embodiments, the nanostructures can have aspect ratios greater than about 10, greater than about 100, greater than about 1,000, or greater than about 10,000 (and/or up to 100,000:1, up to 1,000,000:1, or greater).

In some embodiments, at least a portion of the nanostructures may comprise nanotubes (e.g., single-walled nanotubes, multi-walled nanotubes), nanofibers, nanowires, nanopillars, nanowhiskers, and the like. As used herein, the term “nanotube” is given its ordinary meaning in the art and refers to a substantially cylindrical nanostructure containing a different material in its interior than on its exterior. In certain embodiments, the nanotubes can be hollow. In some embodiments, the nanotube can be formed of a single molecule. In some embodiments, the nanotubes comprise a fused network of primarily six-membered atomic rings. It should be understood that the nanotube may also comprise rings or lattice structures other than six-membered rings. In some embodiments, the nanotubes may be metallic, semiconducting, or insulating. In some embodiments, at least a portion of the nanostructures are carbon nanotubes (e.g., single-walled carbon nanotubes and/or multi-walled carbon nanotubes). In some embodiments, at least a portion of the nanostructures are non-carbon nanotubes. In some embodiments, at least a portion of the nanostructures are inorganic nanotubes. The non-carbon nanotube material may be selected from polymer, ceramic, metal and other suitable materials. For example, the non-carbon nanotube may comprise a metal such as Co, Fe, Ni, Mo, Cu, Au, Ag, Pt, Pd, Al, Zn, or alloys of these metals, among others. In some instances, the non-carbon nanotube may be formed of a semi-conductor such as, for example, Si. In some cases, the non-carbon nanotubes may be Group II-VI nanotubes, wherein Group II elements are selected from Zn, Cd, and Hg, and Group VI elements are selected from O, S, Se, Te, and Po. In some embodiments, non-carbon nanotubes may comprise Group III-V nanotubes, wherein Group III elements are selected from B, Al, Ga, In, and Tl, and Group V elements are selected from N, P, As, Sb, and Bi. As a specific example, the non-carbon nanotubes may comprise boron-nitride nanotubes.

In some embodiments, at least a portion of the nanostructures are carbon-based nanostructures. As used herein, a “carbon-based nanostructure” comprises a fused network of aromatic rings wherein the nanostructure comprises primarily carbon atoms. In some embodiments, the carbon-based nanostructure comprises at least about 75 wt % carbon, at least about 90 wt % carbon, or at least about 99 wt % carbon. In some instances, the nanostructures have a cylindrical, pseudo-cylindrical, or horn shape. A carbon-based nanostructure can comprise a fused network of at least about 10, at least about 50, at least about 100, at least about 1,000, at least about 10,000, or, in some cases, at least about 100,000 aromatic rings.

In certain cases, at least some of the nanostructures may have a length of at least about 10 nm, at least about 100 nm, at least about 1 micrometer, or at least about 10 micrometers (and/or, in certain embodiments, up to about 50 microns, up to about 100 microns, up to about 1 millimeter, or greater). In some embodiments, at least some of the nanostructures can be substantially cylindrical and can have a diameter of less than about 1 micron, less than about 500 nm, less than about 200 nm, less than about 100 nm, less than about 50 nm, or less than about 10 nm (and/or, in certain embodiments, as little as 1 nm, or less).

The nanostructures may be formed from any suitable material. In some embodiments, at least a portion of the nanostructures may comprise carbon. In certain embodiments, at least a portion of the nanostructures comprise silicon. The nanostructures may comprise, in certain embodiments, both silicon and carbon (e.g., in the form of silicon carbide).

In some cases, a layer of material may be positioned over the nanostructures. For example, in some embodiments, a coating (e.g., a substantially conformal coating) may be positioned over the nanostructures. The coating can be used, in certain embodiments, to alter the wetting properties of the exposed surface of the nanostructures, which can be helpful in ensuring that the fluid that is to be discharged from the electrospraying emitter is substantially evenly-coated over the electrode. Non-limiting examples of suitable materials for use in layers positioned over the nanostructures (e.g., coatings) include metals (e.g., gold, platinum, tungsten, and the like), dielectric materials, and/or polymeric materials. In certain embodiments, the layer positioned over the nanostructures comprises at least one self-assembled monolayer.

Nanostructures may be deposited on the protrusions of an emitter using any of a variety of methods. In certain embodiments, depositing a plurality of nanostructures on an external surface of a protrusion involves an additive process in which new material is added to the protrusion (in contrast to methods by which nanostructures are formed on a protrusion by reacting a portion of the protrusion on or near the exposed surface of the protrusion). In some embodiments, depositing a plurality of nanostructures on an external surface of a protrusion comprises performing a chemical reaction to form a plurality of nanostructures on a substrate. For example, in some cases, nanostructures may be deposited on an external surface of a protrusion via chemical vapor deposition (CVD). In some such embodiments, nanostructures may be deposited on an external surface of a protrusion using plasma-enhanced chemical vapor deposition (PECVD). The use of CVD processes (including PECVD process) may, in certain cases, ensure that the nanostructures conformally coat the protrusions and/or that the nanostructures are firmly attached to the surfaces of the protrusions. In some embodiments, precursor gases for use in the PECVD technique may include, but are not limited to, ammonia, methane, hydrogen, and/or acetylene.

In some embodiments, depositing a plurality of nanostructures on an external surface of a protrusion comprises non-reactively accumulating material on the surface of a protrusion. For example, precursor material could be, in some embodiments, precipitated from a solution onto one or more protrusions to form nanostructures.

In some embodiments, the nanostructures positioned over the protrusions may be exposed to further surface treatment. The surface treatment may be used, for example, to modify the wetting properties of the nanostructures, which can be useful in ensuring that the liquid that is to be discharged from the protrusions is substantially evenly distributed across the external surfaces of the protrusions. In some embodiments, at least a portion of the protrusions may be exposed to plasma, such as an oxygen plasma. For example, in some embodiments, the nanostructures are exposed to a short, low-power O₂ plasma treatment. Such treatment may enhance the wetting characteristics of the nanostructures.

In some embodiments in which elongated nanostructures are employed, the nanostructures may be arranged such that the long axes of the nanostructures are substantially aligned relative to each other. The term “long axis” is used to refer to the imaginary line drawn parallel to the longest length of the nanostructure and intersecting the geometric center of the nanostructure. In some cases, the nanostructures may be fabricated by uniformly growing the nanostructures on the surface of a protrusion, such that the long axes are aligned and non-parallel to the protrusion surface (e.g., substantially perpendicular to the protrusion surface). In some cases, the long axes of the nanostructures are oriented in a substantially perpendicular direction with respect to the surface of a protrusion, forming a nanostructure “forest.” It should be understood that the use of aligned nanostructures is not necessary, and in some embodiments, at least a portion of the nanostructures may not be substantially aligned.

Generally the hydraulic impedance produced by a coating of nanostructures depends on the diameters of the nanostructures and their packing density. Thus, in some embodiments, the spacings and/or the dimensions of the nanostructures described herein may be tailored to achieve a flow rate needed for a desired fluid emission regime (e.g., a regime in which ions are emitted from the protrusions, a regime in which droplets are emitted from the protrusions, or a regime in which both droplets and ions are emitted from the protrusions). For example, emission in the ionic regime may be achieved with a low flow rate and high hydraulic impedance, while emission in the mixed ionic/droplet regime may be achieved with higher flow rate and lower hydraulic impedance. Hydraulic impedance may be increased by increasing the diameter of the nanostructures and the packing density of the nanostructures. Nanostructure diameter and packing density may be tuned by adjusting parameters of the growth process, including choice of catalyst material, anneal temperature, growth temperature, growth time, and choice of process gases. Those of ordinary skill in the art, given the present disclosure, would be capable of adjusting nanostructure growth conditions to produce nanostructures having suitable dimensions and packing densities for achieving a desired flow regime.

The emitters described herein can be formed of a variety of suitable materials. In some embodiments, the emitter substrate and the array of protrusions extending from the emitter substrate can be formed of the same material. In other embodiments, the emitter substrate and the array of protrusions are formed of different materials. In some embodiments, the emitter may be fabricated from an electrically conductive material. In other embodiments, the emitter may be fabricated from a material that is only slightly electronically conductive (or substantially not electronically conductive). In some such embodiments, transport of the electrosprayed fluid toward the extractor electrode can be achieved by applying an electrical voltage between the fluid and the extractor electrode.

In some embodiments, at least a portion of the emitter substrate and/or the protrusions may be formed of a semiconductor. Non-limiting examples of suitable semiconductor materials include silicon, germanium, silicon carbide, and/or III-V compounds (such as GaN, GaAs, GaP, and/or InP). In certain cases, at least a portion of the emitter substrate and/or the protrusions may comprise a dielectric material. The emitter could also be fabricated, in certain embodiments, from a metal.

In certain cases, the protrusions extending from the emitter substrate can be relatively small. The use of small protrusions can allow one to arrange a relatively large number of protrusions within a relatively small area, which can be useful in scaling up the electrospraying system. In some embodiments, at least a portion of (e.g., at least about 50% of, at least about 75% of, at least about 90% of, at least about 99% of, or substantially all of) the protrusions extending from the emitter substrate have maximum cross-sectional dimensions of less than about 1 millimeter. In some such embodiments, at least a portion of (e.g., at least about 50% of, at least about 75% of, at least about 90% of, at least about 99% of, or substantially all of) the protrusions extending from the emitter substrate have maximum cross-sectional dimensions of at least about 1 micron, at least about 10 microns, or at least about 50 microns. As used herein, the “maximum cross-sectional dimension” refers to the largest distance between two opposed boundaries of an individual structure that may be measured. In cases in which the protrusion is an integral part of the emitter substrate from which it extends, the lower boundary of the protrusion corresponds to a hypothetical extension of the external surface of the emitter substrate on which the protrusion is positioned. In some cases, at least a portion of the protrusions may have a height (measured relative to the external surface of the emitter substrate on which the protrusions are formed) of less than about 5 mm, less than about 1 mm, less than about 500 microns, less than about 400 microns, less than about 300 microns, less than about 200 microns, less than about 100 microns, or less than about 50 microns. In some embodiments, at least a portion of the protrusions are microstructures, having at least one cross-sectional dimension of less than about 1 mm, less than about 100 micrometers, or less than about 10 micrometers (and/or, in some embodiments, as little as 1 micrometer, or smaller).

In some embodiments, the protrusions may have tips with relatively sharp tips. The use of protrusions having sharp tips may, in certain embodiments, enhance the magnitude of the electric field near the protrusion tip, which can aid in creating instability in the fluid and, in turn, lead to discharge of the fluid from the protrusion tip. In some embodiments, at least a portion (e.g., at least about 50%, at least about 75%, at least about 90%, or at least about 99%) of the protrusions have a tip comprising a radius of curvature of less than about 5 microns, less than about 1 micron, less than about 500 nm, less than about 100 nm, less than about 50 nm, or less than about 10 nm.

In certain embodiments, the protrusions extending from the emitter substrate are arranged in an array. The array may, in some embodiments, comprise at least about 10 protrusions, at least about 20 protrusions, at least about 50 protrusions, at least about 100 protrusions, at least about 1,000 protrusions, at least about 1,900 protrusions (and/or, in certain embodiments, at least about 5,000 protrusions, at least about 10,000 protrusions, or more). The protrusions within the array may be arranged randomly or according to a pattern. In some embodiments, the protrusions within the array can be ordered in a substantially periodic pattern. In certain embodiments, the protrusions are arranged in an array such that the array extends in at least two orthogonal directions. Such arrays may be planar or non-planar (e.g., curved).

In some embodiments, a relatively large number of protrusions can be arranged within a relatively small area, which can be useful in scaling up the electrospraying system. In certain embodiments, the array includes at least about 10 protrusions/cm², at least about 100 protrusions/cm², at least about 1,000 protrusions/cm², at least about 1,900 protrusions/cm², or at least about 10,000 protrusions/cm² (and/or, in certain embodiments, up to about 100,000 protrusions/cm², or more).

In certain embodiments, at least a portion of (e.g., at least about 50% of, at least about 75% of, at least about 90% of, at least about 99% of, or substantially all of) the protrusions may be configured, in certain embodiments, such that a significant portion of (e.g., at least about 50% of, at least about 75% of, at least about 90% of, at least about 99% of, or substantially all of) the fluid expelled from the protrusions during operation of the system is externally surface directed from the protrusions toward the electrode. Generally, fluid is externally surface directed from a protrusion when the fluid travels along the external surface of the protrusion. Such protrusions can be said to be “externally fed.” The use of externally fed protrusions can be advantageous, in some embodiments, because clogging of passageways within the protrusions—which might be observed in internally fed protrusions, such as nozzles—can be avoided. In some embodiments, the externally fed protrusions do not contain internal fluid passageways. Generally, external fluid passageways are those that are open to the external environment along their lengths, while internal passageways are isolated from the external environment along their lengths. In some embodiments, the externally fed protrusions are non-porous.

In some embodiments, the protrusions may be similar in size and shape. In some cases, the standard deviation of the maximum cross-sectional dimensions of the protrusions may be less than about 100%, less than about 50%, less than about 20%, less than about 10%, less than about 5%, or less than about 1% of the average maximum cross-sectional dimensions of the protrusions. In certain cases, the standard deviation of the volume of the protrusions may be less than about 100%, less than about 50%, less than about 20%, less than about 10%, less than about 5%, or less than about 1% of the average volume of the protrusions. One advantage of using protrusions that are similar in size and shape, in certain instances, is that flow can be more easily controlled, which can result in the formation of electrosprayed droplets that are more uniform in size and shape.

Certain embodiments relate to methods of using certain of the electrospraying systems described herein. In some embodiments, an electrospraying method comprises exposing an emitter to a fluid and applying voltage across the emitter and an electrode. Applying the voltage results, in some embodiments, in emission of fluid (e.g., in the form of droplets and/or ions) from at least a portion of the tips of the protrusions of the emitter toward the electrode.

Any suitable fluid can be used as the electrosprayed fluid. In some embodiments, the electrosprayed liquid comprises a charged fluid. In some embodiments, the fluid used in the electrospraying system may be polar. In some embodiments, the electrosprayed fluid comprises a liquid. In some embodiments, the electrosprayed liquid comprises an ionic liquid. Ionic liquids can be used as the electrosprayed liquid, for example, when the production of ions is desired. Non-limiting examples of ionic liquids suitable for use in the electrospraying systems described herein include 1-ethyl-3-methylimidazolium tetrafluoroborate (EMI-BF₄), 1-ethyl-3-methylimidazolium bis(trifluoromethylsulfonyl)imide (EMI-Im), 1-butyl-3-methylimidazolium tetrachloroferrate (bmim[FeCl₄]), and 1-butyronitrile-3-methylimidazolium tetrachloroferrate (nbmim[FeCl₄]). Other ionic liquids could also be used.

In some embodiments, the fluid used in the electrospraying system comprises a plurality of particles suspended in the fluid. The plurality of particles suspended in the fluid may, for example, form a colloid (e.g., a nanocolloid). In some embodiments, the plurality of particles makes up at least about 0.01 vol % of the colloid, at least about 0.1 vol % of the colloid, at least about 1 vol % of the colloid, at least about 10 vol % of the colloid, or at least about 20 vol % of the colloid (and/or, in some embodiments, as much as about 50 vol % or more of the colloid). In some embodiments, the plurality of particles makes up about 50 vol % or less of the colloid, about 20 vol % or less of the colloid, about 10 vol % or less of the colloid, about 1 vol % or less of the colloid, or about 0.1 vol % or less of the colloid (and/or, in some embodiments, as little as 0.01 vol % or less of the colloid). In certain cases, at least a portion (e.g., at least about 50%, at least about 75%, at least about 90%, at least about 95%, at least about 99%, or all) of the particles suspended in the fluid used in the electrospraying system are nanoparticles (i.e., particles having a maximum cross-sectional dimensions of about 1 micron or less). In some embodiments, the nanoparticles have maximum cross-sectional dimensions of about 750 nm or less, about 500 nm or less, about 200 nm or less, about 100 nm or less, about 50 nm or less, about 20 nm or less, about 10 nm or less (and/or, in some embodiments, as little as about 1 nm or less). Generally, the maximum cross-sectional dimensions of nanoparticles used in a colloid can be determined by inspecting a magnified image of the nanoparticles. For example, the liquid portion of a colloid can be evaporated or otherwise removed, and the remaining particles can be inspected using transmission electron microscopy (TEM).

In some embodiments in which the electrospray fluid comprises particles (e.g., forming a colloid such as a nanocolloid), applying a voltage across the emitter and the electrode results in the expulsion of at least a portion of (e.g., at least about 10% of, at least about 25% of, at least about 50% of, at least about 75% of, at least about 90% of, at least about 95% of, at least about 99% of, or all of) the particles within the fluid from the emitter (e.g., from a protrusion of the emitter) toward the electrode. For example, referring to FIG. 1A, in some embodiments, a voltage is applied across emitter 102 and electrode 106 while a fluid containing particles is used (e.g., is in contact with emitter 102). In some such embodiments, when the voltage is applied across emitter 102 and electrode 106, the fluid (e.g., an ionic liquid) and the particles (e.g., nanoparticles) are emitted from emitter 104 and directed toward electrode 106.

The particles suspended in the fluid used in the electrospraying system (e.g., in a nanocolloid) may be formed of any suitable material. In some embodiments, at least a portion of the particles comprise one or more metals. Non-limiting examples of suitable metals include tungsten, cobalt, iron, nickel, molybdenum, copper, gold, silver, platinum, palladium, aluminum, zinc, tantalum, titanium, and any combination thereof. In certain cases, at least a portion of the particles comprise an alloy of one or more metals. In some embodiments, at least a portion of the particles comprise one or more non-metals. For example, in certain embodiments, at least a portion of the particles comprise one or more ceramic materials. Non-limiting examples of suitable ceramic materials include titanium dioxide (TiO₂) and titanium nitride (TiN). In some embodiments, at least a portion of the particles comprise one or more carbon-containing materials. A non-limiting example of a suitable carbon-containing material includes graphene. In some embodiments, at least a portion of the particles comprise one or more dielectric materials. Examples of suitable dielectric materials include, but are not limited to, include silicon dioxide (SiO₂), aluminum nitride (AlN), boron nitride (BN), aluminum oxide (Al₂O₃), silicon nitride (Si₃N₄), titanium diboride (TiB₂), neodymium oxide (NdO₃), and tungsten oxide (WO₃). In certain cases, at least a portion of the particles comprise one or more semiconductors. Examples of suitable semiconductors include, but are not limited to, silicon oxynitride, doped silicon, undoped silicon, molybdenum disulfide (MoS₂), doped silicon carbide, and undoped silicon carbide. In some cases, at least a portion of the particles comprise one or more piezoelectric materials. A non-limiting example of a suitable piezoelectric material includes zinc oxide (ZnO). In certain embodiments, at least a portion of the particles comprise one or more magnetic materials. A non-limiting example of a suitable magnetic material includes iron oxide.

The fluid of the colloid may be any fluid suitable for use in an electrospraying system. In certain cases, for example, the fluid is an ionic fluid. As noted above, suitable ionic fluids include, but are not limited to, EMI-BF₄, EMI-Im, bmim[FeCl₄], and nbmim[FeCl₄].

In some cases, the colloid may advantageously be used in an electrospraying system for nanomanufacturing purposes. For example, electrospraying a colloid may allow nanoparticles to selectively be deposited in specific locations (e.g., as opposed to spin coating a surface with nanoparticles). In some embodiments, the colloid may advantageously be used in an electrospraying system for propulsion (e.g., space propulsion). Electrospraying a colloid may, for example, increase thrust due to the increased mass of the colloid (e.g., compared to the fluid in the absence of particles).

The colloid may be formed according to any method known in the art. In certain embodiments, the colloid is formed using sputtering (e.g., DC sputtering, RF sputtering). For example, in some embodiments, energetic particles may be directed toward a source of nanoparticles (e.g., a metal, a ceramic, etc.). Upon interacting with the source, the energetic particles can cause the formation of nanoparticles of the source material. The nanoparticles of the source material may subsequently be deposited in a fluid (e.g., an ionic liquid) to form the colloid. One example of this method of formation is described in detail in Example 4 below. Additional methods of forming colloids suitable for use in the electrospray systems described herein could also be used.

The fluid emitted from protrusions within the electrospraying system may comprise ions, solvated ions, and/or droplets. In some embodiments in which droplets are emitted from protrusions of the electrospraying system, the droplets may have relatively consistent maximum cross-sectional dimensions and/or volumes. For example, in some embodiments, the droplets emitted from the protrusions of the electrospraying system can each have maximum cross-sectional dimension, and the standard deviation of the maximum cross-sectional dimensions of the droplets may be less than about 100%, less than about 50%, less than about 20%, or less than about 10% of the average of the maximum cross-sectional dimensions of the droplets. In some embodiments, the droplets emitted from the protrusions of the electrospraying system can each have a volume, and the standard deviation of the volumes of the droplets may be less than about 100%, less than about 50%, less than about 20%, or less than about 10% of the average of the volumes of the droplets. In certain embodiments, droplets emitted from protrusions are monodisperse.

The electrospraying systems described herein can be operated at relatively low voltages, in certain embodiments. In some embodiments, the voltage applied to the electrospraying system may be less than about 100 kV, less than about 50 kV, less than about 10 kV, less than about 5 kV, less than about 2.5 kV, less than about 1 kV, less than about 500 V, less than about 100 V, or less than about 50 V (and/or, in some embodiments, as little as about 10 V, or less) while fluid discharge having any of the properties described herein is generated. In certain embodiments, during operation of the electrospraying system, the current per protrusion tip may be greater than about 1 microamp, greater than about 3 microamps, or greater than about 5 microamps (and/or, in certain embodiments, up to about 10 microamps, or more).

In some embodiments, extractor electrode die may contain an array of apertures. For example, FIG. 2C is a schematic illustration of an extractor electrode 106 comprising a plurality of apertures 220. The apertures may be, in certain embodiments, substantially circular, substantially rectangular (e.g., substantially square), or any other shape. As illustrated in FIG. 2C, apertures 220 are substantially circular in cross-section. In certain embodiments, the use of substantially circular apertures can be advantageous, although such aperture shapes are not required. In some embodiments, the apertures may have maximum cross-sectional dimensions of less than about 1 mm, less than about 500 microns, less than about 400 microns, less than about 200 microns, less than about 100 microns, less than about 50 microns, or less than about 10 microns in diameter.

The emitter and the extractor electrode can be arranged such that the extractor electrode is positioned over the emitter. For example, FIG. 2E is a perspective view illustration of an electrospraying system in which extractor electrode 106 illustrated in FIG. 2C is positioned over emitter 102 illustrated in FIG. 2D. FIG. 2F is a cross-sectional schematic illustration of the arrangement shown in FIG. 2E. In some embodiments, the apertures within the array can be spatially arranged such that their positions substantially correspond to the positions of the protrusions on the emitter. For example, referring to FIG. 2F, apertures 220 of extractor electrode 106 are positioned such that they overlie protrusions 104 of emitter 102. In some embodiments, the gap between the emitter and extractor electrode may be less than about 500 microns, less than about 100 microns, less than about 50 microns, or less than about 10 microns. The emitter and the extractor electrode may be held together, in certain embodiments, via a pin, dowel, or other connector. For example, in FIG. 2F, dowel 222 (e.g., a ceramic dowel) is inserted through openings in the emitter and the extractor electrode, which maintains the alignment of the electrodes. In certain embodiments, the emitter and/or the extractor electrode comprise deflection springs that clamp onto the connector (e.g., dowel) pins to allow for precision alignment of the two components. For example, in FIG. 2E, extractor electrode 106 comprises deflection springs 223. In some embodiments, a spacer (e.g., a polyimide spacer) can also be included between the emitter and the extractor electrode, which can be used to maintain consistent spacing between the electrodes. For example, in FIG. 2F, spacer 224 is positioned between emitter 102 and extractor electrode 106. In some embodiments, when the two dies are assembled, each protrusion tip sits underneath an aperture.

Certain embodiments relate to methods of fabricating electrospraying systems and components for use therein. In some embodiments, a method of making an emitter is described. The method comprises, in some embodiments, etching a fabrication substrate to produce a plurality of protrusions extending from the fabrication substrate. In some such embodiments, the method further comprises depositing a plurality of nanostructures on external surfaces of the protrusions.

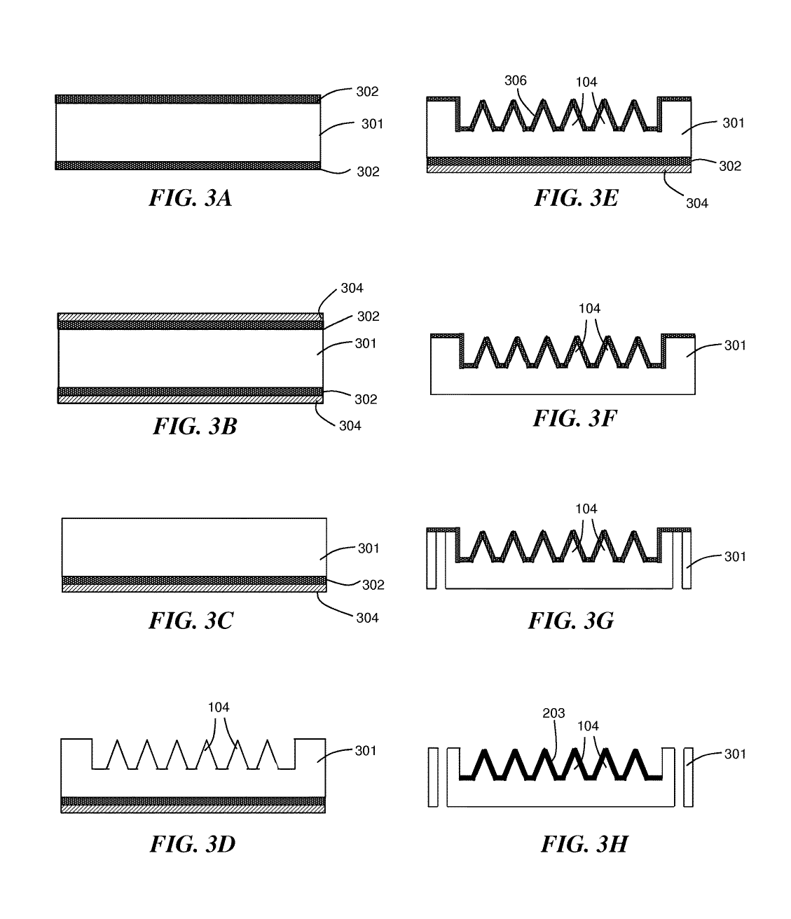

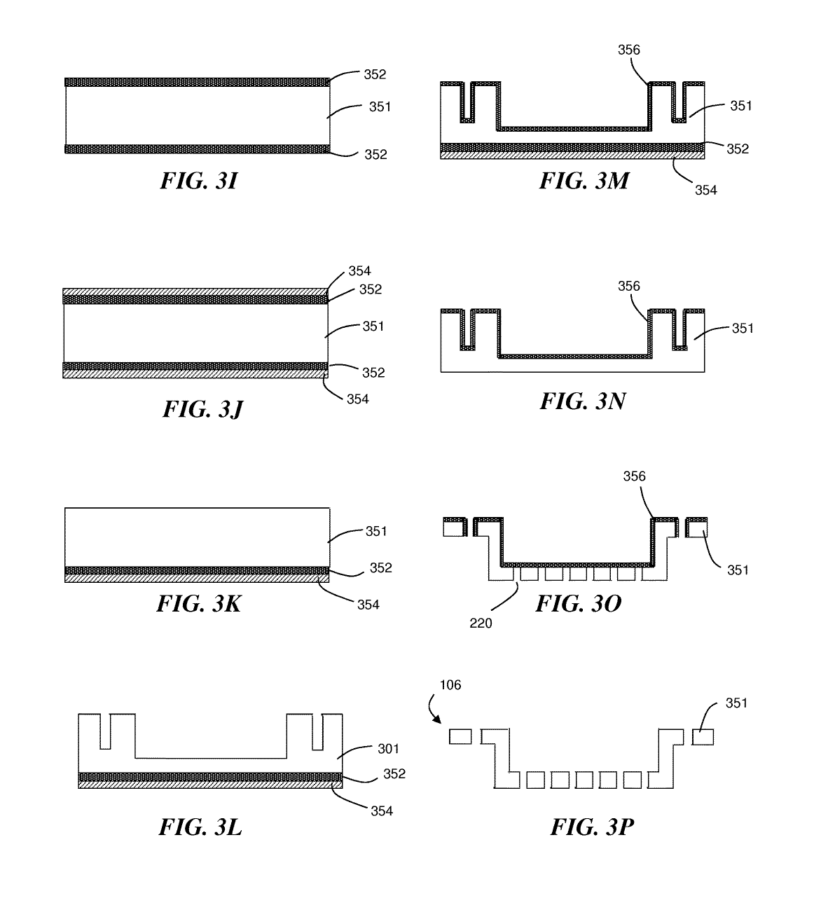

FIGS. 3A-3H are a series of cross-sectional schematic diagrams outlining an exemplary process for fabricating an emitter (e.g., for use in an electrospraying system). As shown in FIG. 3A, the process begins with fabrication substrate 301. Fabrication substrate 301 can correspond to, for example, any wafer suitable for use in a microfabrication process. For example, in some embodiments, fabrication substrate 301 corresponds to a silicon wafer.

In some embodiments, the fabrication substrate is etched to produce a plurality of protrusions (which can correspond to protrusions 104 in FIGS. 1B, 2A, 2B, 2D, and 2F) extending from the fabrication substrate. In some embodiments, etching the fabrication substrate comprises reactive ion etching (RIE). In certain cases, the reactive ion etching may comprise deep reactive ion etching (DRIE). Etching the fabrication substrate to produce the protrusions can be achieved, for example, using an etch mask. Referring to FIG. 3B, for example, etch masks 302 (e.g., a silicon oxide layer with, for example, a thickness of about 500 nm) can be formed on the front and back sides of fabrication substrate 301. In certain embodiments, additional masking materials (e.g., a silicon-rich silicon nitride layer 304 with a thickness of, for example, 250 nm) can be deposited. In some embodiments, deep reactive ion etching—using, for example, a photoresist mask (not illustrated)—is then used to create protrusions 104, as shown in FIG. 3D. In certain embodiments, and as illustrated in FIG. 3E, the protrusions on the front side of the fabrication substrate are oxidized, resulting in oxide layer 306. Optionally, and as shown in FIG. 3F, masking layers 302 and 304 can be removed from the back side of the fabrication substrate 301. In some embodiments, and as illustrated in FIG. 3G, additional features (e.g., alignment features) can be etched from the back side of the fabrication substrate (e.g., via deep reactive ion etching or any other suitable etching technique). Optionally, in some embodiments, oxide layer 306 is removed from the front side of the fabrication substrate.

As noted above, the method of making the emitter further comprises, in certain embodiments, depositing a plurality of nanostructures on external surfaces of the protrusions. For example, referring to FIG. 3H, nanostructures 203 can be deposited on the exposed surface of protrusions 104.

As noted elsewhere, deposition of the nanostructures can comprise performing a chemical reaction to form the nanostructures, precipitating a material to form the nanostructures, or otherwise adding material to the protrusions to form the nanostructures. In some embodiments, nanostructures are formed over the protrusions via catalytic growth. For example, the fabrication process may comprise depositing a catalyst over the fabrication substrate after etching the fabrication substrate to produce the plurality of protrusions and prior to depositing the plurality of nanostructures on the external surfaces of the protrusions. Subsequently, after the catalyst has been deposited, the nanostructures can be catalytically grown. As one specific example, in some embodiments, nanostructures 203 can correspond to carbon nanotubes, which can be catalytically grown after depositing a metal film (e.g., a Ni/TiN film) over protrusions 104.

In some embodiments, the process of forming the emitter may comprise removing at least a portion of the catalyst after depositing the catalyst over the fabrication substrate. In some such embodiments, the catalyst can be removed in order to form an ordered catalyst layer. The ordered catalyst layer can be used to produce nanostructures that are positioned over the protrusions in an ordered fashion, as described in more detail above. In some embodiments, removing at least a portion of the catalyst results in the formation of catalyst nanoparticles over the fabrication substrate. In other embodiments, substantially no portions of the catalyst are removed prior to deposition of the nanostructures, and order can be introduced to the nanostructures by removing at least a portion of the deposited nanostructures.

FIGS. 3I-3P are a series of cross-sectional schematic diagrams outlining an exemplary process for fabricating an extractor electrode, such as extractor electrode 106 illustrated in FIGS. 2C, 2E, and 2F. As shown in FIG. 3I, the exemplary process begins with substrate 351. Substrate 351 can correspond to, for example, any wafer suitable for use in a microfabrication process. For example, in some embodiments, substrate 351 corresponds to a silicon wafer. One or more masks can be formed on substrate 351. For example, in FIG. 3I, a silicon oxide mask 352 (e.g., with a thickness of about 500 nm) is positioned over both sides of substrate 351. In FIG. 3J, a silicon nitride mask 354 is positioned over the silicon oxide mask 352. Next, as illustrated in FIG. 3K, the front side oxide and nitride masks can be removed. Subsequently, an etching step (e.g., a deep reactive ion etching step using, for example, a photoresist mask, which is not illustrated) can be used to create the front side features of the extractor electrode, as illustrated in FIG. 3L. As shown in FIG. 3M, the front side of substrate 351 can be oxidized (e.g., via the formation of silicon oxide mask 356) to protect the front side features. Subsequently, as illustrated in FIG. 3N, the back side silicon oxide and silicon nitride masks can be removed. A second etching step (e.g., a second deep reactive ion etching step using, for example, a photoresist mask, which is not illustrated) can then be performed to form the back side features, such as apertures 220, as shown in FIG. 3O. The front side silicon oxide mask 356 can then be removed, as illustrated in FIG. 3P. In certain embodiments, the exposed surfaces of the resulting electrode can be coated with an electronically conductive material (e.g., a metal such as gold).

Certain of the devices described herein can be used to perform electrospraying to produce droplets and/or ions for a variety of applications. For example, certain of the systems and methods can be used to produce nanoparticles (e.g., comprising a polymer, metal, ceramic, or combinations of these and/or other materials). Certain of the systems and methods described herein can be used for the efficient high-throughput generation of ions, which can be used, for example, for mass-efficient nanosatellite electric propulsion, multiplexed focused ion beam imaging, and/or high-throughput nanomanufacturing.

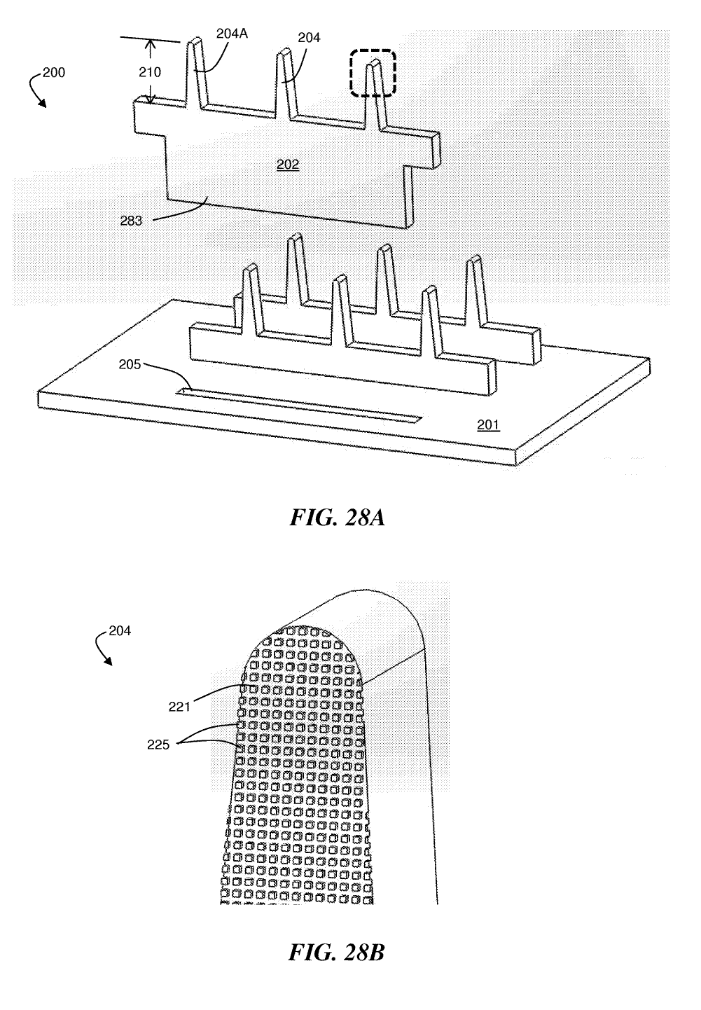

While electrospraying has primarily been described herein, certain embodiments relate to electrospinning systems and emitters that can be used in electrospinning systems. FIG. 28A is an exemplary schematic illustration of emitter 200, which can be used in certain of the systems described herein. While emitter 200 is described primarily for use in systems in which electrospinning is performed, it should be understood that emitter 200 could also be used in systems in which electrospraying is performed. In FIG. 28A, emitter 200 comprises emitter substrate 201. Emitter 200 also comprises protrusion substrate 202 comprising base 283 and a plurality of protrusions 204 extending from base 283.

In certain embodiments the protrusions can be in direct contact with the emitter substrate. In other embodiments, including the embodiment illustrated in FIG. 28A, the protrusions and emitter substrate are in indirect contact (e.g., via protrusion substrate base 283).

In certain embodiments, base 283 links to emitter substrate 201. For example, the emitter substrate may comprise a linking surface area and the protrusion substrate base may comprise a linking surface area configured to fasten to the linking surface area of the emitter substrate. The linking surface area of the emitter substrate and/or the protrusion substrate may correspond to, for example, an indentation into which a portion of the other of the base and the protrusion substrate can be positioned. For example, as illustrated in FIG. 28A, emitter substrate 201 comprises an indentation 205 into which protrusion substrate base 283 can be fitted. In other embodiments, the protrusion substrate base 283 can comprise an indentation into which a portion of the emitter substrate can be fitted. In some embodiments, the base of the protrusion substrate and the emitter substrate are linked via a tongue and groove fitting.

In some embodiments, the emitters described herein comprise a plurality of protrusion substrate bases linked to the emitter substrate. For example, as illustrated in FIG. 28A, emitter 200 comprises three protrusion substrates. In other embodiments, two, four, five, or more protrusion substrates can be linked to an emitter substrate. The protrusion substrates in FIG. 28A each include three protrusions to form a 3 by 3 array of protrusions. In other embodiments, the protrusion substrates comprise two, four, five, or more protrusions, and can be arranged to form an array including any desired number of protrusions. In some embodiments, the longitudinal axis of at least some of the protrusions is substantially perpendicular to the emitter substrate.

In some embodiments, the protrusion substrate may be formed of a semiconductor. Non-limiting examples of suitable semiconductor materials include silicon, germanium, silicon carbide, and/or III-V compounds (such as GaN, GaAs, GaP, and/or InP). In some cases, at least a portion of the protrusion substrate may comprise a dielectric material or a metal. The protrusion substrate may, in certain embodiments, be microfabricated.

In some cases, the protrusions extending from the protrusion substrate can be relatively narrow. The use of narrow protrusions can allow one to arrange a relatively large number of protrusions within a relatively small area, which can be useful in scaling up the electrospinning system. In some embodiments, at least a portion of (e.g., at least about 50% of, at least about 75% of, at least about 90% of, at least about 99% of, or substantially all of) the protrusions extending from the protrusion substrate have maximum cross-sectional widths (measured perpendicular to the longitudinal axes of the protrusions) of less than about 10 millimeters. In some such embodiments, at least a portion of (e.g., at least about 50% of, at least about 75% of, at least about 90% of, at least about 99% of, or substantially all of) the protrusions extending from the protrusion substrate have maximum cross-sectional widths (measured perpendicular to the longitudinal axes of the protrusions) of at least about 100 microns.

In certain embodiments, the protrusions may be relatively tall. Generally, the height of a protrusion corresponds to the distance between the portion of the protrusion in contact with the protrusion substrate base and the tip of the protrusion, and is measured parallel to the longitudinal axis of the protrusion. For example, in FIG. 28A, the height of protrusion 204A corresponds to dimension 210. Taller protrusions may be more effective at anchoring emission jets to emitter tips. Accordingly, in certain embodiments, at least a portion of (e.g., at least about 50% of, at least about 75% of, at least about 90% of, at least about 99% of, or substantially all of) the protrusions extending from the protrusion substrate have a height of at least about 5 microns, at least about 10 microns, at least about 20 microns, at least about 50 microns, at least about 100 microns, at least about 1 millimeter, at least about 2 millimeters, or at least about 5 millimeters (and/or, in certain embodiments, up to about 50 millimeters, or taller).

In some embodiments, a sharp tip may provide electric field enhancement, allowing the fluid to ionize at low voltage. In some embodiments, flow rate to emitter tip may be maximized by optimizing microstructure height and microstructure diameter-to-pitch.

In some embodiments, a relatively large number of protrusions can be arranged within a relatively small area, which can be useful in scaling up the electrospinning system. In certain embodiments, the array includes at least about 9 protrusions, at least about 10 protrusions, at least about 20 protrusions, at least about 50 protrusions, at least about 100 protrusions, at least about 1,000 protrusions, at least about 5,000 protrusions, at least about 10,000 protrusions, or at least about 100,000 protrusions. In certain embodiments, the array includes at least about 9 protrusions/cm², at least about 10 protrusions/cm², at least about 100 protrusions/cm², at least about 1,000 protrusions/cm², or at least about 10,000 protrusions/cm² (and/or, in certain embodiments, up to about 100,000 protrusions/cm², or more).

In some embodiments, a plurality of microstructures may be present on external surfaces of at least a portion of the protrusions. A variety of microstructures can be used in association with certain of the embodiments described herein. As used herein, the term “microstructure” refers to any structure having at least one cross-sectional dimension, as measured between two opposed boundaries of the microstructure, of less than about 1 mm. In some embodiments, at least a portion of the microstructures may have at least one cross-sectional dimension of less than about 500 microns, less than about 100 microns, or less than about 10 microns. In some embodiments, the microstructures can have a minimum cross-sectional dimension of at least about 1 micron.

In certain embodiments, the microstructures can be elongated microstructures. For example, in some embodiments, the microstructures can have aspect ratios greater than about 10, greater than about 100, greater than about 1,000, or greater than about 10,000 (and/or up to 100,000:1, up to 1,000,000:1, or greater).

In some embodiments, a protrusion may contain a relatively large number of nanostructures. For example, a protrusion may contain at least about 100, at least about 1,000, at least about 10,000, or at least about 100,000, or more nanostructures.

FIG. 28B is an exemplary perspective view schematic illustration of a portion of the external surface of a protrusion 204 of FIG. 28A. In FIG. 28B, surface 221 of protrusion 204 includes a plurality of microstructures 225. Surface 221 of protrusion 204 in FIG. 28B includes a plurality of micropillars arranged in an array. The invention is not limited to such microstructures, however, and in other embodiments, the microstructures could correspond to microtubes, microfibers, microwires, microwhiskers, microchannels, or any other suitable microstructures. The microstructures may, in some cases, comprise hexagonally-packed micropillars. In some embodiments, microstructures may comprise nanostructures.

In some cases, a layer of material may be positioned over the microstructures. For example, in some embodiments, a coating (e.g., a substantially conformal coating) may be positioned over the microstructures. Non-limiting examples of suitable materials for use in layers positioned over the microstructures (e.g., coatings) include silicon carbide, nitride, oxide, or polysilicon. In certain embodiments, the coating may affect spreading behavior. For example, different behaviors of spreading, such as Cassie-Baxter, Wenzel, and hemi-wicking may be obtained by varying microstructure geometry and surface coating. In certain embodiments, the coating may contribute to fluid replenishment rate and may be advantageous in allowing steady operation of the emitters.

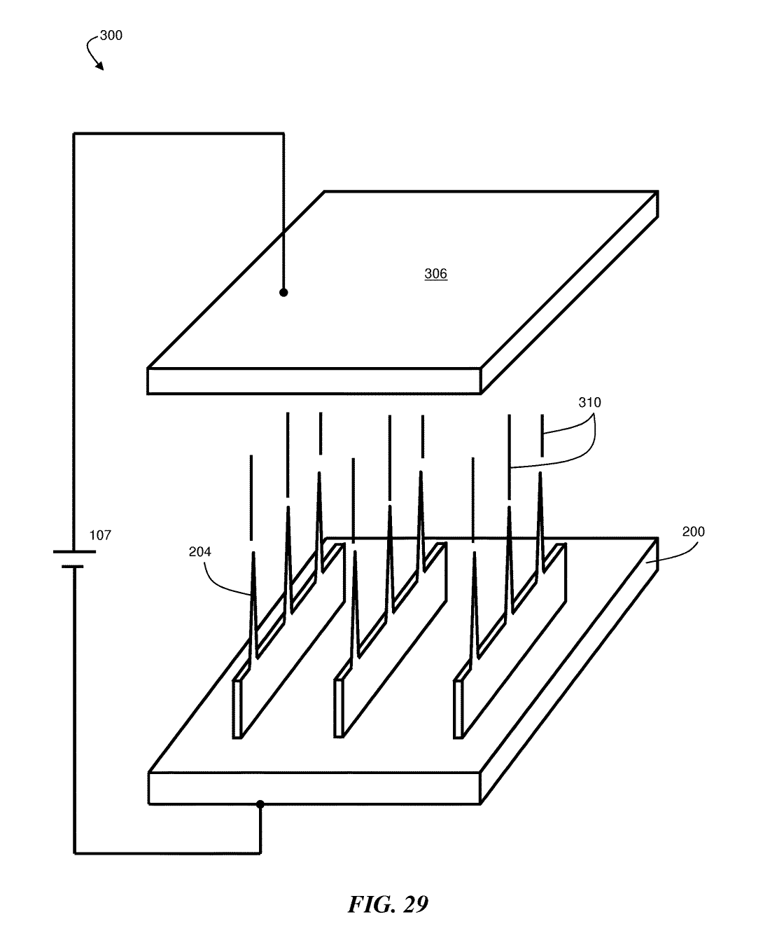

Some embodiments relate to methods of performing electrospinning using certain of the emitter and systems described herein. FIG. 29 is a perspective view schematic illustration of a system 300 in which emitter 200 of FIG. 28A is used to perform an electrospinning operation. In some embodiments, the electrospinning method comprises exposing an emitter to a fluid and applying voltage across the emitter and an electrode. Referring to FIG. 29, for example, system 300 comprises emitter 200 (which can correspond to, for example, emitter 200 of FIG. 28A), electrode 306, and voltage source 107. In certain embodiments, emitter 200 is exposed to a fluid, and voltage is applied across emitter 200 and electrode 306. In some embodiments, the voltage is applied such that fluid positioned between the emitter and the electrode is emitted in substantially continuous streams from at least some of the protrusions in the emitter toward the second electrode. For example, referring to FIG. 29, in some embodiments, when voltage source 107 is used to apply a voltage between emitter 200 and electrode 306, fluid streams 310 may be emitted from the tips of protrusions 204 toward electrode 306.

In some embodiments, fluid may be emitted from a relatively large percentage of the protrusions of the emitter. In some such embodiments, the fluid is emitted substantially simultaneously from a relatively large percentage of the protrusions of the emitter. Not wishing to be bound by any particular theory, it is believed that the ability to tailor the shape, size, and packing density of the microstructures on the external surfaces of the protrusions can allow one to control the flow of fluid from the bases of the protrusions to the tips of the protrusions such that stable fluid flow can be achieved simultaneously from multiple (and, in certain cases, all) protrusions simultaneously. In some embodiments, fluid may be essentially simultaneously emitted from at least about 10%, at least about 20%, at least about 30%, at least about 40%, at least about 50%, at least about 60%, at least about 70%, at least about 80%, at least about 90%, at least about 99%, or about 100% of the protrusions. In some embodiments, fluid may be emitted in a substantially continuous stream from at least about 10%, at least about 20%, at least about 30%, at least about 40%, at least about 50%, at least about 60%, at least about 70%, at least about 80%, at least about 90%, or about 100% of the protrusions. In some embodiments, fluid may be emitted substantially simultaneously in substantially continuous streams from at least about 10%, at least about 20%, at least about 30%, at least about 40%, at least about 50%, at least about 60%, at least about 70%, at least about 80%, at least about 90%, or about 100% of the protrusions.

In some embodiments, fluid can be emitted in a substantially continuous stream from a relatively large number of protrusions in a stable and controlled manner. In some embodiments, fluid may be emitted in a substantially continuous stream simultaneously from at least about 10%, at least about 20%, at least about 30%, at least about 40%, at least about 50%, at least about 60%, at least about 70%, at least about 80%, at least about 90%, or about 100% of the protrusions for a continuous period of at least about 30 seconds, a period of at least about 1 minute, at least about 5 minutes, at least about 1 hour, or at least about 1 day (and/or, in certain embodiments, up to 1 month, up to 1 year, or substantially indefinitely). In some embodiments, fluid may be emitted in a direction that is substantially perpendicular to the emitter substrate. In some embodiments, fluid may be emitted in a substantially continuous stream in a direction that is substantially perpendicular to the emitter substrate. In certain cases, fluid may be emitted in a direction that is substantially parallel to the longitudinal axes of the protrusions. In some embodiments, fluid may be emitted in a substantially continuous stream from at least about 10%, at least about 20%, at least about 30%, at least about 40%, at least about 50%, at least about 60%, at least about 70%, at least about 80%, at least about 90%, or about 100% of the protrusions in a direction that is substantially perpendicular to the emitter substrate. In certain embodiments, fluid may be emitted in a substantially continuous stream from at least about 10%, at least about 20%, at least about 30%, at least about 40%, at least about 50%, at least about 60%, at least about 70%, at least about 80%, at least about 90%, or about 100% of the protrusions in a direction that is substantially parallel to the longitudinal axes of the protrusions.

In some embodiments, the emitters described herein can be used to produce emissions of fluid in a substantially continuous stream with relatively small cross-sectional dimensions. Not wishing to be bound by any particular theory, it is believed that the ability to tailor the shape, size, and packing density of the microstructures on the external surfaces of the protrusions can allow one to control the flow of fluid from the bases of the protrusions to the tips of the protrusions such that fluid can be emitted in very thin streams. In some embodiments, substantially continuous streams having maximum cross-sectional diameters of less than about 1 micron, less than about 500 nm, less than about 200 nm, less than about 100 nm, less than about 50 nm, or less than about 10 nm (and/or, in certain embodiments, down to about 1 nm or less) can be emitted from at least about 10%, at least about 20%, at least about 30%, at least about 40%, at least about 50%, at least about 60%, at least about 70%, at least about 80%, at least about 90%, or about 100% of the protrusions (in some embodiments, simultaneously). The thin emitted streams may also have relatively consistent sizes. In certain embodiments, the standard deviation of the cross-sectional diameters of the continuous streams may be less than about 100%, less than about 50%, less than about 20%, less than about 10%, or less than about 1% of the average of the cross-sectional diameters of the continuous streams. Nanofibers produced using the electrospinning systems described herein may have any of the properties described herein of the streams of fluid emitted from the protrusions.

In some embodiments, fluid comprising a polymer may be emitted from the protrusions. Any suitable fluid can be used for electrospinning. In some embodiments, the fluid comprises a liquid. In some embodiments, the liquid comprises a polymer suspension or solution. Polymer suspensions or solutions can be used, for example, when production of nanofibers is desired. In one non-limiting illustration of how nanofibers can be formed using such fluid, a polymer may be suspended in a carrier fluid to form a polymer suspension. The polymer suspension may be used as the fluid in the electrospinning system such that the polymer suspension is emitted from the protrusions of the emitter. Upon being emitted from the emitter, the carrier fluid of the polymer suspension may evaporate, leaving behind a hardened polymer. In some such embodiments, the polymer may polymerize and/or cross-link before, during, and/or after the carrier fluid leaves the polymer suspension. Any suitable polymer can be used in the electrospinning polymer suspensions and solutions described herein. Non-limiting examples of suitable polymers include polyethylene oxide, polyacrylonitrile, polyethylene terephthalate, polystyrene, polyvinyl chloride, Nylon-6, polyvinyl alcohol, Kevlar, polyvinylidene fluoride, polybenzimidazole, polyurethanes, polycarbonates, polysulfones, and polyvinyl phenol. In some embodiments, the polymer within the polymer suspension or polymer solution may have a relatively high molecular weight. For example, in some embodiments, the polymer within the polymer suspension or polymer solution may have a molecular weight of more than about 10,000 g/mol, more than about 100,000 g/mol, more than about 200,000 g/mol, or more than about 500,000 g/mol (and/or, in certain embodiments, up to about 1,000,000 g/mol, or higher).

In some embodiments, the fluid used in the electrospinning system may be polar.

One advantage of the electrospinning systems and methods described herein is that they can be used to controllably emit fluids having relatively high viscosities from a plurality of emitter protrusions simultaneously. Not wishing to be bound by any theory, it is believed that the use of protrusions with relatively large heights and the ability to tailor the layout of the microstructures can assist in the emission of relatively viscous fluids. In certain embodiments, the viscosity of the fluid used in the electrospinning system at 25° C. can be at least about 1 Pa-s, at least about 10 Pa-s, at least about 50 Pa-s, at least about 100 Pa-s, or at least about 1,000 Pa-s (and/or, in certain embodiments, up to about 10,000 Pa-s, or greater).

The electrospinning systems described herein can be operated at relatively low voltages, in certain embodiments. Some embodiments may comprise a voltage source configured to apply voltage across the emitter and the electrode. In some embodiments, the voltage applied between the emitter and the electrode of the electrospinning system may be less than about 100 kV, less than about 50 kV, less than about 20 kV, less than about 10 kV, less than about 5 kV, less than about 2.5 kV, less than about 1 kV, or less than about 500 V (and/or, in certain embodiments, as little as about 100 V, or less) while fluid discharge having any of the properties described herein is generated. In some embodiments, when any of the above voltages are applied across the emitter and the electrode, fluid may be essentially simultaneously emitted from at least about 10%, at least about 20%, at least about 30%, at least about 40%, at least about 50%, at least about 60%, at least about 70%, at least about 80%, at least about 90%, or about 100% of the protrusions. In certain embodiments, during operation of the electrospinning system, the current per protrusion tip may be greater than about 1 microamp, greater than about 3 microamps, or greater than about 5 microamps (and/or, in certain embodiments, up to about 10 microamps, or more).

In some embodiments, the flow rate of the fluid at a plurality of protrusions is at least about 5×10⁻¹³ m³/s per protrusion, at least about 5×10⁻¹¹ m³/s per protrusion, or at least about 5×10⁻⁹ m³/s per protrusion (and/or, in certain embodiments, up to about 5×10⁻⁷ m³/s per protrusion, or greater).

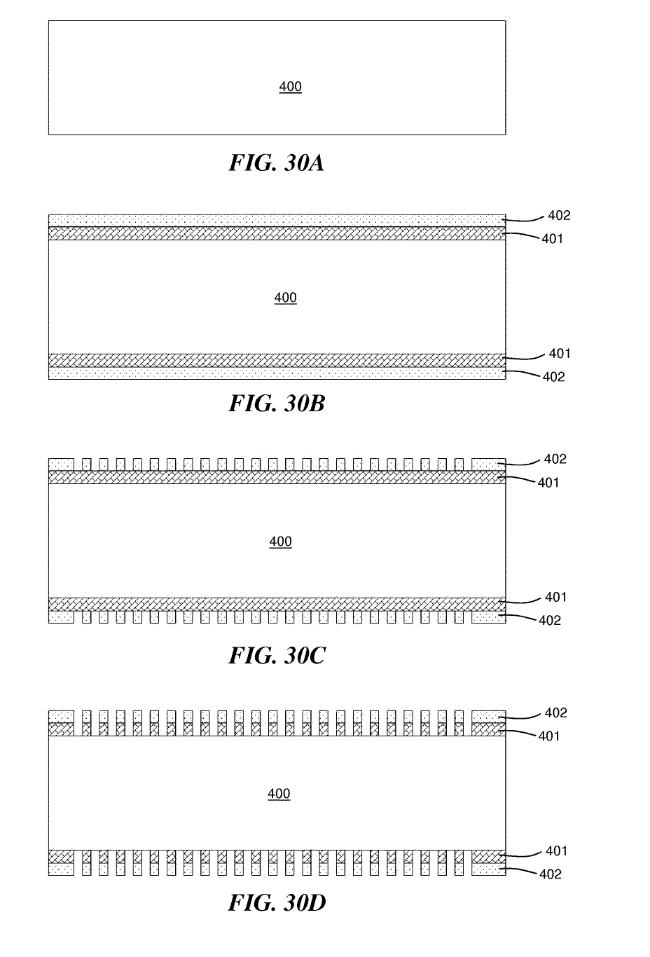

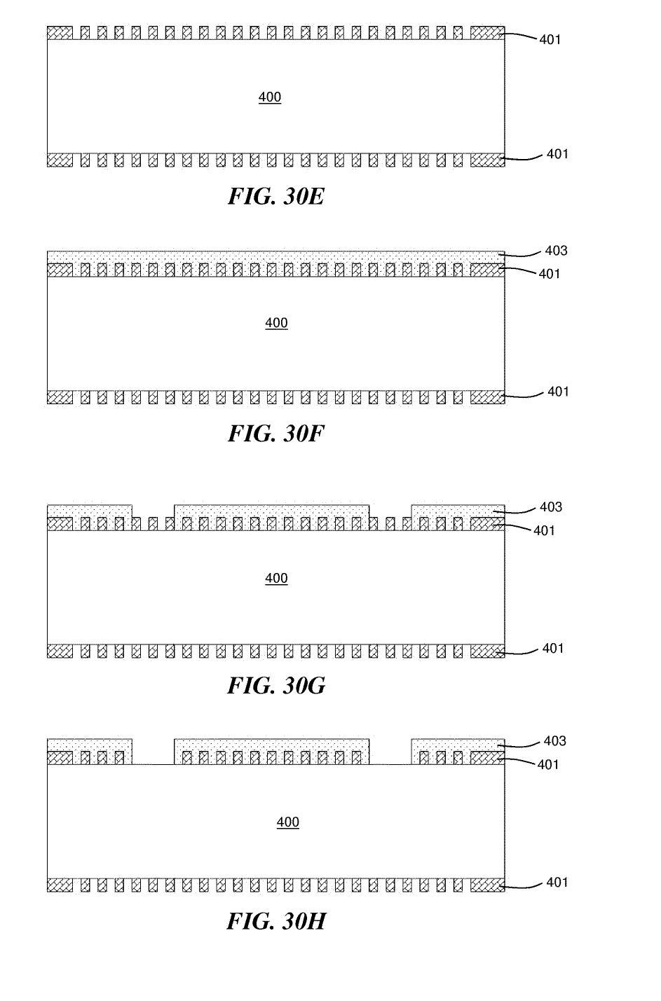

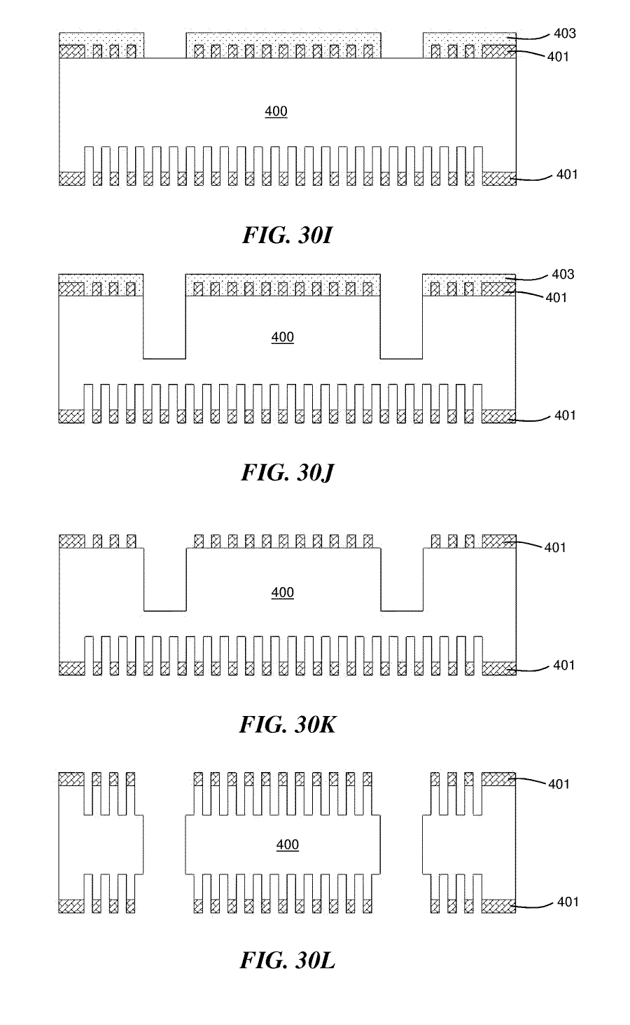

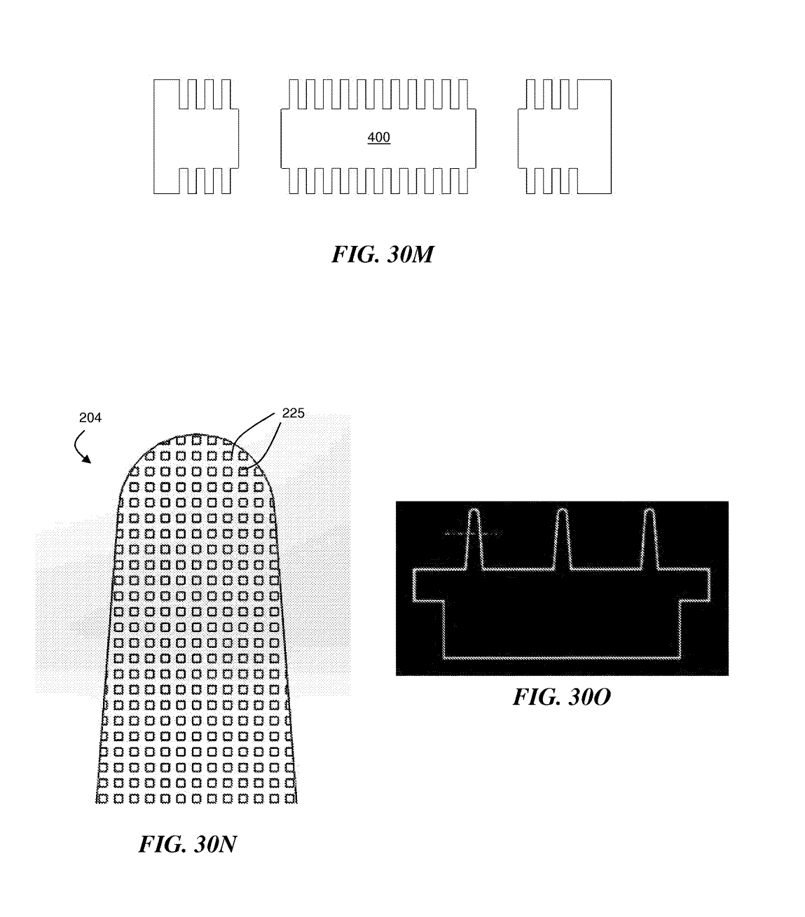

Methods of fabricating emitters configured for use in, for example, electrospinning systems are also provided herein. FIGS. 30A-30M are a series of cross-sectional schematic diagrams outlining an exemplary process for fabricating an emitter (e.g., for use in an electrospinning system), such as emitter 200 illustrated in FIG. 28A. In some embodiments, the method comprises etching a fabrication substrate to produce a structure comprising a base, a first set of protrusions extending from the base, and a second set of protrusions extending from external surfaces of the first protrusions. In some embodiments, the first set of protrusions corresponds to the emitter protrusions (e.g., protrusions 204 in FIG. 28A). In certain embodiments, the second set of protrusions comprises the microstructural features formed on the external surfaces of the emitter protrusions (e.g., microstructural features 225 in FIG. 28B). In some embodiments, etching the fabrication substrate may comprise performing reactive ion etching. In certain cases, etching the fabrication substrate may comprise performing deep reactive ion etching.

In some embodiments, the method may comprise first etching the fabrication substrate to produce the second set of protrusions (e.g., the microstructural features), and subsequently etching the fabrication substrate to produce the structure comprising the base and the first set of protrusions (e.g., the emitter protrusions) extending from the base such that the first set of protrusions includes the second set of protrusions extending from the external surfaces of the first set of protrusions. In other embodiments, the method may comprise first etching the fabrication substrate to produce the structure comprising the base and the first set of protrusions extending from the base, and subsequently etching the structure comprising the base and the first set of protrusions to produce a second set of protrusions extending from the external surfaces of the first set of protrusions. For example, the structure comprising the base and the first set of protrusions can be etched and released from the fabrication substrate (e.g., while held in place by a backing substrate attached to the fabrication substrate). Subsequently, the released structures comprising the base and the first set of protrusions can be etched to produce the microstructures. In certain embodiments, including the embodiment illustrated below in FIGS. 30A-30M, the first and second sets of protrusions can be etched at the same time.

In some embodiments, the first and second etching steps may be performed using the same type of etching procedure. For example, the first and second etching steps may be performed using reactive ion etching (e.g., deep reactive ion etching). In some embodiments, the first and second etching steps may be performed using different types of etching procedures.

FIGS. 30A-30M are cross-sectional schematic diagrams illustrating an exemplary fabrication process for forming an emitter, such as emitter 200 in FIG. 28A. As illustrated in FIG. 30A, a fabrication substrate 400 is provided. Fabrication substrate 400 can correspond to, for example, any wafer suitable for use in a microfabrication process. For example, in some embodiments, fabrication substrate 400 corresponds to a silicon wafer. Substrate etching mask 401 (e.g., silicon oxide) can be formed on both sides of the fabrication substrate and patterned, for example, using first photoresist layer 402, as illustrated in FIGS. 30B-30D. The pattern in first photoresist layer 402 can correspond to the desired pattern of microstructures on the emitter protrusions. Once the substrate etching mask has been patterned, first photoresist layer 402 can be removed, as illustrated in FIG. 30E. Subsequently, second photoresist layer 403 can be formed over substrate etching mask 401, as illustrated in FIG. 30F. Second photoresist layer 403 can be patterned, as illustrated in FIG. 30G. The pattern in the second photoresist layer can correspond to an outline of the protrusion substrate, including the protrusion substrate base and the emitter protrusions. An exemplary mask that can be used to form this pattern is shown in FIG. 30O.

Referring to FIG. 30I, the back side of the fabrication substrate can be etched (for example, using a deep reactive ion etch) to form a plurality of microstructures on the back side of the fabrication substrate. Subsequently, as illustrated in FIG. 30J, the front side of the fabrication substrate can be etched (for example, using a deep reactive ion etch) to a depth such that the remaining thickness of the fabrication substrate is essentially the same as the desired height of the front side microstructures. Next, as illustrated in FIG. 30K, second photoresist layer 403 can be removed, as illustrated in FIG. 30K. Subsequently, another etching step (e.g., a deep reactive ion etching step) can be performed to form the front side microstructures and to release the protrusion substrate, as illustrated in FIG. 30L. Finally, first mask layer 401 can be removed to form the structure in FIG. 30M. FIG. 30N is a top side schematic illustration of the structure illustrated in FIG. 30M.

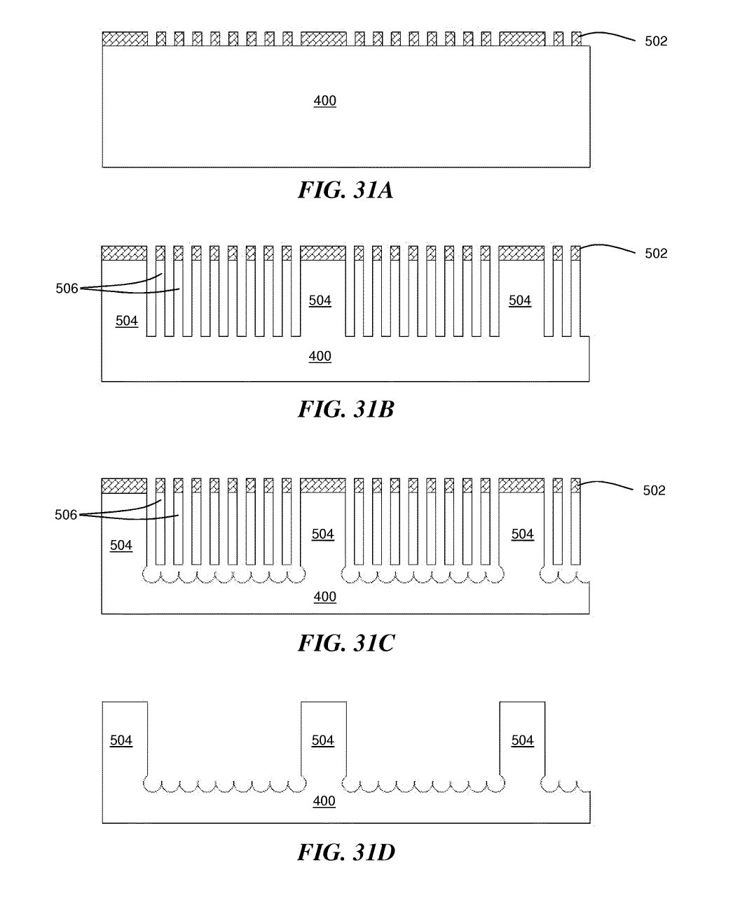

While the microstructures illustrated in FIGS. 30A-30M have nearest neighbor distances that are relatively close to the cross-sectional dimensions of the nanostructures, other spacings can be achieved, including nearest neighbor distances that are smaller than or larger than the cross-sectional dimensions of the nanostructures. FIGS. 31A-31D are cross-sectional schematic illustrations outlining an exemplary process for producing relatively widely spaced microstructures. In FIG. 31A, nested mask 502 (e.g., a silicon oxide mask) has been formed over fabrication substrate 400 (e.g., a silicon wafer). In FIG. 31B, an anisotropic etching step (e.g., a deep reactive ion etching step) has been performed to form microstructures 504 and sacrificial features 506. In FIG. 31C, an isotropic etch is used to undercut sacrificial features 506, leaving behind microstructures 504. Nested mask 502 can then be removed to form the structure illustrated in FIG. 31D.

In certain embodiments, at least a portion of the protrusions in the electrospinning or electrospraying array comprises a plurality of microstructures extending from external surfaces of the protrusions. In embodiments in which microstructures are employed, the microstructures can result in enhanced properties. For example, the microstructures may, in some embodiments, be configured to transport fluid from the bases of the protrusions to the tips of the protrusions. The microstructures on the exterior surfaces of the emitter protrusions can be arranged in an ordered fashion, in some embodiments. In certain embodiments, ordered microstructures may be produced over a protrusion, for example, by etching a portion of the material from which the protrusion is produced to form an ordered set of microstructural features. For example, in certain embodiments, the microstructures illustrated in FIG. 28B can be formed by etching the material from which the protrusion is formed, as described in more detail below. The etching can be performed, for example, via microfabrication. In some embodiments, ordered microstructures can be formed over a protrusion by depositing a layer of the microstructures over a protrusion and subsequently removing the microstructures from at least one portion of the protrusion. As one example, in certain embodiments, microstructures may be formed (e.g., deposited, grown, or otherwise formed) over the protrusions (e.g., over an intermediate material, such as a catalyst, positioned over the protrusions) and subsequently selectively removed from at least a portion of the external surfaces of the protrusions (e.g., using an etchant and a mask) such that the microstructures are present only over desired portions of the protrusions. In still other embodiments, a catalyst material used to grow the microstructures may be formed over the protrusions and subsequently selectively removed from at least one portion of the external surfaces of the protrusions (e.g., using an etchant and a mask) such that the catalyst material is present only over desired portions of the protrusions. The microstructures can subsequently be grown over the ordered catalyst material to produce an ordered set of microstructures.

In some embodiments, the ordered microstructures may be patterned over protrusions. This can be achieved, for example, by selectively forming the ordered microstructures over a first portion of exposed surfaces of the protrusions while not forming microstructures over a second portion of the exposed surfaces of the protrusions.

In some embodiments, the microstructures may be positioned such that the spacing between the microstructures can be somewhat regular. For example, in certain embodiments, the microstructures can each have a nearest neighbor distance, and the standard deviation of the nearest neighbor distances may be less than about 100%, less than about 50%, less than about 20%, or less than about 10% of the average of the nearest neighbor distances. In some embodiments, the microstructures may be arranged substantially periodically.

A variety of microstructures can be used in association with certain of the embodiments described herein. As used herein, the term “microstructure” refers to any structure having at least one cross-sectional dimension, as measured between two opposed boundaries of the nanostructure, of less than about 1 millimeter. In some embodiments, the microstructures comprise nanostructures.

At least a portion of the protrusions in the electrospinning system, as described above with respect to the electrospraying system, may be configured, in certain embodiments, such that a significant portion of the fluid expelled from the protrusions during operation of the system is externally surface directed from the protrusions toward the electrode.

As noted above with respect to the electrospraying systems, in some embodiments, the protrusions may be substantially uniform in shape. In some cases, the protrusions may be substantially uniform in size. In cases in which the protrusion is an integral part of the emitter substrate from which it extends, the lower boundary of the protrusion (used to calculate the volume of the protrusion) corresponds to a hypothetical extension of the external surface of the substrate on which the protrusion is positioned. One advantage of using protrusions that are similar in size and shape, in certain instances, is that flow can be more easily controlled. This can result in the formation of continuous threads (for electrospinning systems) and/or droplets (for electrospraying systems) that are more uniform in size and shape.

In some embodiments, the protrusions may have tips with relatively sharp tips. The use of protrusions having sharp tips may, in certain embodiments, enhance the magnitude of the electric field near the protrusion tip, which can aid in creating instability in the fluid and, in turn, lead to discharge of the fluid from the protrusion tip. In some embodiments, at least a portion (e.g., at least about 50%, at least about 75%, at least about 90%, or at least about 99%) of the protrusions have a tip comprising a radius of curvature of less than about 5 microns, less than about 1 micron, less than about 500 nm, less than about 100 nm, less than about 50 nm, or less than about 10 nm. In certain cases, the standard deviation of the radii of curvature of the protrusion tips may be less than about 100%, less than about 50%, less than about 20%, less than about 10%, less than about 5%, or less than about 1% of the average of the radii of curvature of the protrusion tips.

In certain embodiments, the emitter protrusions are arranged in an array. The array may, in some embodiments, comprise at least about 9 protrusions, at least about 10 protrusions, at least about 20 protrusions, at least about 50 protrusions, at least about 100 protrusions, at least about 1,000 protrusions (and/or, in certain embodiments, at least about 5,000 protrusions, at least about 10,000 protrusions, or more). The protrusions within the array may be arranged randomly or according to a pattern. In some embodiments, the protrusions within the array can be ordered in a substantially periodic pattern. In certain embodiments, the protrusions are arranged in an array such that the array extends in at least two orthogonal directions. Such arrays may be substantially planar or substantially non-planar (e.g., curved). In some embodiments, the protrusions may be perpendicular to the emitter substrate to within about 10°, within about 5°, or within about 1°.

The emitters described herein can be formed of a variety of suitable materials. In some embodiments, the emitter substrate and the array of protrusions extending from the emitter substrate can be formed of the same material. In other embodiments, the emitter substrate and the array of protrusions are formed of different materials.

In some embodiments, the emitter itself can be capable of transporting current, and can therefore itself be an electrode. In certain embodiments, the emitter can be fabricated from a material that is only slightly electronically conductive (or substantially not electronically conductive). In some such embodiments, transport of the electrosprayed fluid toward the collector electrode can be achieved by applying an electrical voltage between the fluid and the collector electrode.

The electrospinning systems and methods described herein have a variety of uses. For example, certain of the devices described herein can be used to produce fibers (e.g., nanofibers) made of a variety of suitable materials including, but not limited to, polymer, ceramic, semiconductor, and/or metallic materials, and/or combinations of these. Such fibers can be useful in, for example, advanced energy storage and power conversion systems. Nanofibers can be especially attractive for energy applications because their low dimensionality gives them unique properties. As one particular example, dye-sensitized solar cells can benefit from the reduction of grain boundaries within 1-dimensional structures, which can improve charge conduction. Porous nanofibers mats can allow for better infiltration of viscous polymer gels containing dye sensitizers. Also, the high surface-to-volume ratio of nanofibers can make nanofiber mats particularly useful as scaffolds for catalyst dispersion in fuel cells. The electrospinning devices described herein can also be used to conformally coat three-dimensional complex shapes with thin layers to produce, for example, complex multi-layered structures and/or structures including thin layers with variations in thickness across the surface. Electrospun fibers can also be used to produce a broad range of other devices including, but not limited to, flexible electronics, filtration systems, tissue (e.g., in tissue engineering applications), ultracapacitors, and nano-reinforced composite materials.

The following examples are intended to illustrate certain embodiments of the present invention, but do not exemplify the full scope of the invention.

### Example 1

This example describes the design, fabrication, and experimental characterization of an externally-fed, batch-microfabricated electrospray emitter array including an integrated extractor grid and carbon nanotube flow control structures. In this example, the electrospray emitter is used for low voltage and high-throughput electrospray of the ionic liquid 1-ethyl-3-methylimidazolium tetrafluoroborate (EMI-BF₄) in vacuum. The conformal carbon nanotube forest on the emitters provided a highly effective wicking structure to transport liquid up the protrusion surfaces to the emission site at the tips of the protrusions. Arrays containing as many as 81 emitting protrusions in 1 cm² were tested, and emission currents as high as 5 microamps per emitting protrusion in both polarities were measured, with a start-up bias voltage as low as 520 V. Imprints formed on the collector electrode and per-protrusion IV characteristics showed excellent emission uniformity.

The design described in this example features a hierarchical structure that brings together structures with associated characteristic lengths that span five orders of magnitude: mesoscale deflection springs for precision assembly of an extractor electrode die to an emitter array die to attain low beam interception, micro-sharp emitting protrusion tips for low voltage electrospray emission, and a nanostructured conformal CNT wicking structure that controls the flow rate fed to each emitting protrusion to attain high protrusion current while maintaining good array emission uniformity.

The emitter die and extractor die were fabricated separately and were assembled together using deflection springs that clamped onto dowel pins and provided precise alignment of the two components. The electrode separation distance was tuned using insulating spacers. In general, this distance should be small for a low start-up voltage, which is given by

$${V}_{start} = \sqrt{\frac{γ \cdot R}{{ɛ}_{o}}} ln [ \frac{2 G}{R} ] \qquad [ 2 ]$$

where γ is the surface tension, R is the protrusion tip radius, ∈ₒ is the permittivity of free space, and G is the distance from the protrusion tip to the edge of the extractor aperture. After operation, the two electrodes were easily disassembled, cleaned and replenished with liquid.

Internally-fed emitting protrusions supplied liquid to the emission site through a capillary channel; this implementation was not ideal for ion emission because capillary channels typically provide low hydraulic impedance and internally fed emitting protrusions can be prone to clogging, which causes device failure. The electrospray emitting protrusions described in this example were instead externally-fed, using a dense plasma-enhanced chemical vapor deposited (PECVD) CNT forest conformally grown on the surface of the protrusions. The CNT forest acted as a wicking material to transport the ionic liquid from the base of the protrusions to the protrusion tips, where it was ionized due to the strong electric fields present there. The ionic liquid tested in this example (EMI-BF₄), did not generally spread well onto the surface of an uncoated silicon protrusion array; the contact angle of EMI-BF₄ on silicon is about 38°. However, EMI-BF₄ was found to be highly wetting on a CNT-coated silicon protrusion surface. A drop of EMI-BF₄ was found to spontaneously spread across the protrusion array, impregnating the surface and coating the protrusion tips.

In addition to its useful wetting properties, the CNT forests were found to provide hydraulic impedance to the ionic liquid as it flowed up the surface of the protrusions. Electrospray emission can occur in the ionic regime rather than a mixed ionic/droplet regime if the flow rate to the emission site is sufficiently low. A porous medium can limit the flow across the protrusion surface in order to match the low flow rate for ionic emission. CNT films have been found to be particularly useful, in certain cases, because their porosity (determined by CNT diameter and packing density) is highly tunable by changing the growth parameters. The flow rate in the ionic regime is related to the measured current I by

$$Q = \frac{I 〈 M 〉}{Ne ρ} \qquad [ 3 ]$$

where (M) is the average molar mass of the emitted particles, N is Avogadro's number, e is the elementary charge, and ρ is the density of the liquid. For EMI-BF₄ ((M) of about 0.2 kg/mol, p=1300 kg/m³), about 5 microamps of current per protrusion corresponds to Q=8×10⁻¹⁵ m³/s. Flow through a porous medium is governed by Darcy's law:

$$\vec{{q}_{s}} = - \frac{{K}_{ps}}{μ} ∇ P \qquad [ 4 ]$$

where \vec{q}ₛ is the volumetric flow rate per unit area, ∇P is the fluid pressure gradient from the base to the tip of the protrusion, Kₚₛ is the permeability of the medium, and μ is the fluid viscosity. The CNT film was modeled as an array of pillars in order to calculate its permeability, which is a function of the CNT diameter distribution and the packing density. The CNT growth conditions were selected to obtain a permeability of about 10⁻¹³ m², which provided sufficient impedance for the flow rate to meet the conditions for the ionic regime.

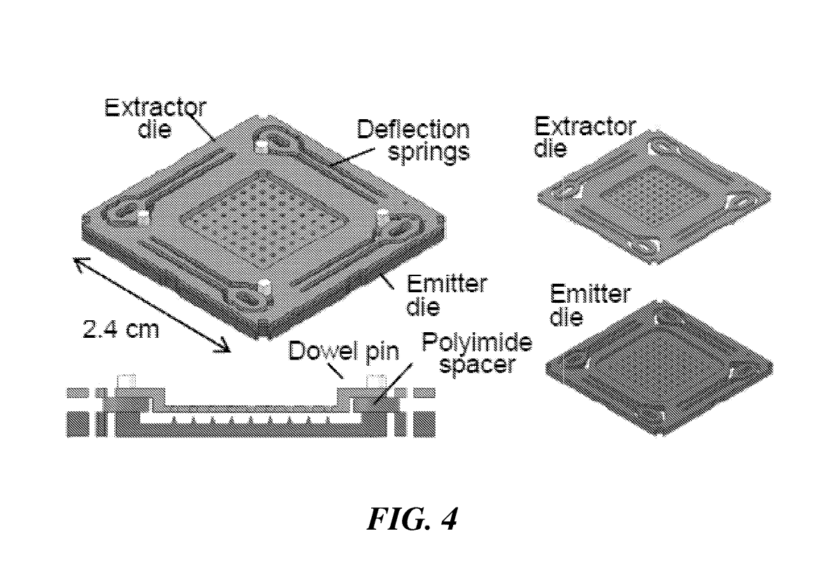

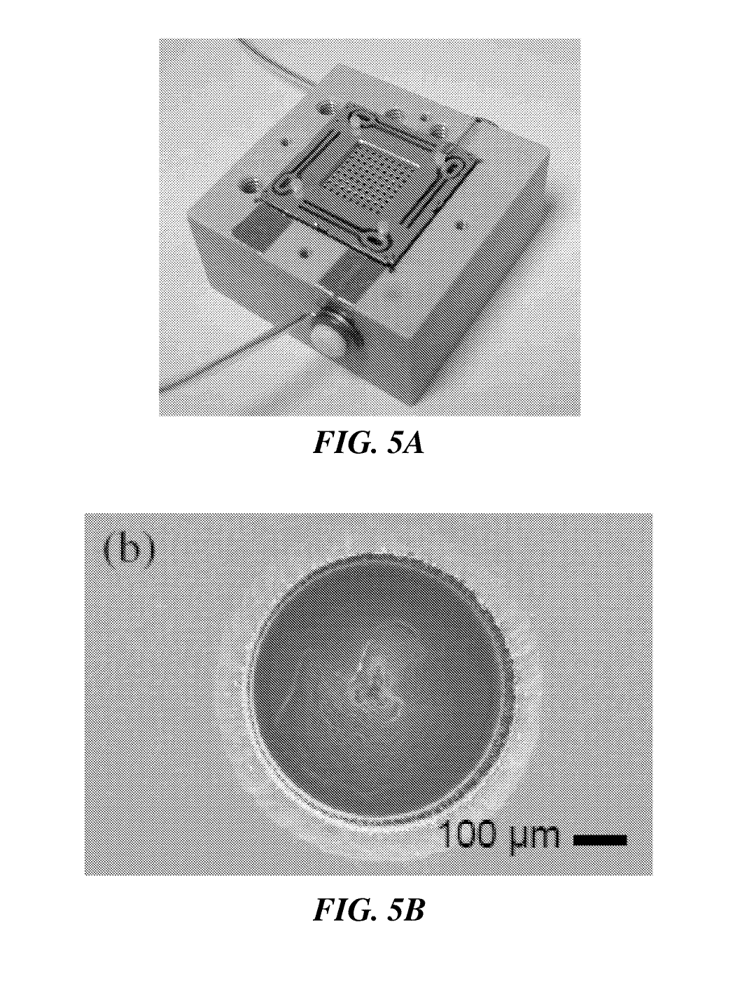

The electrospray source included two dies, an emitter die and an extractor grid die (FIG. 4). Each die was 2.4 cm by 2.4 cm and 1 mm thick. The emitter dies contained arrays of 4, 9, 25, 49, and 81 emitting protrusions in a 1 cm² area. The protrusions were 300-350 micrometers tall. The extractor grid die contained a matching array of 500 micrometer diameter circular apertures that were 250 micrometers thick. Both dies contained four deflection springs that were clamped onto dowel pins to obtain precise alignment of the two components. When the two dies were assembled (FIG. 5A), each protrusion tip was aligned precisely underneath a grid aperture (FIG. 5B). Four thin polyimide spacers electrically insulated the two dies and set the emitter-to-extractor separation distance.

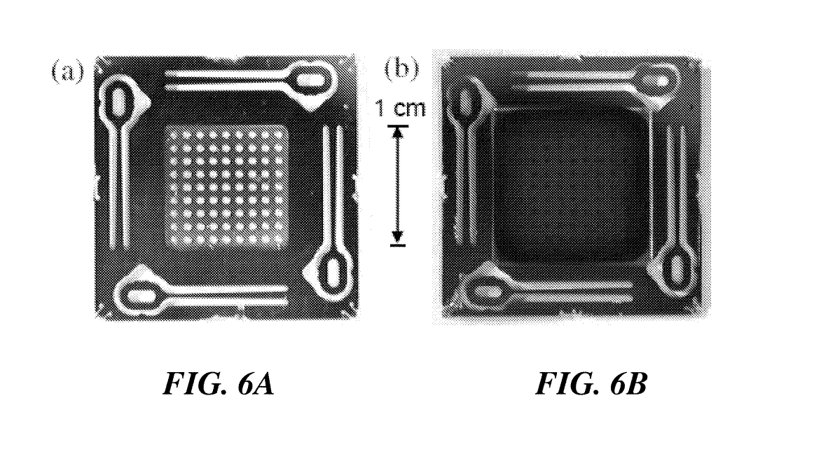

The extractor grid (FIG. 6A) and emitter (FIG. 6B) dies were fabricated using contact lithography starting with 1 mm thick, double-side polished doped silicon wafers. The extractor grid dies were fabricated using two (2) deep reactive-ion etching (DRIE) steps. First, the springs and a 750 micrometer-deep recess for the apertures were etched on the front side of the wafer; then, a second, back-side DRIE step was used to create 600 micrometer-deep recesses around the springs and the array of apertures. A thin film of titanium/gold was sputtered onto the grid dies to increase their electrical conductivity.

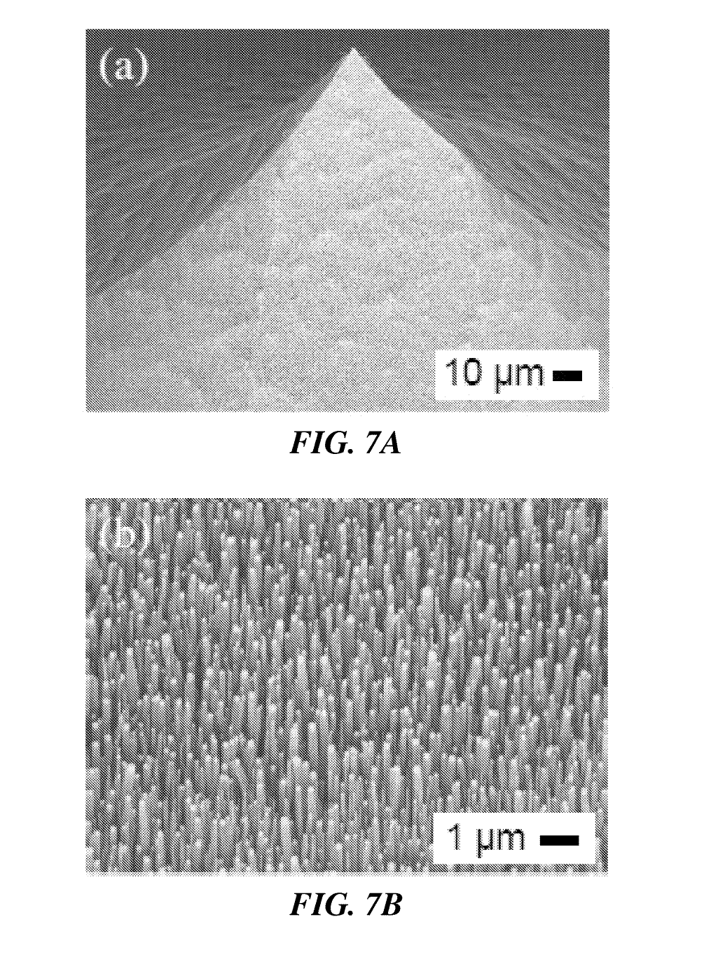

The emitter dies were fabricated by first etching the array of protrusion tips on the front side of the wafer using isotropic SF₆ reactive-ion etching (RIE). An array of three-notched dots, 292 micrometers in diameter, patterned in photoresist was used as the masking material. The silicon underneath the notched dots was gradually undercut during the RIE step until sharp tips were formed. Next, a DRIE step was used to etch the springs on the back side of the wafer. To complete the emitter die, a CNT film was grown on the surface of the protrusions. Titanium nitride and nickel films were sputtered onto the 1 cm by 1 cm active area of the protrusions using a shadow mask. CNTs were grown using plasma-enhanced chemical vapor deposition (PECVD), with ammonia and acetylene as precursors. The CNTs were about 2 micrometers tall and averaged 115 nm in diameter. The CNTs conformally coated the surface of the protrusions and the entire active area of the emitter dies, as shown in FIGS. 7A-7B. The PECVD process ensured that the CNTs were firmly attached to the surfaces of the protrusions; no detachment was observed after application of the ionic liquid or after repeated cleaning and reassembly of the electrospray sources.

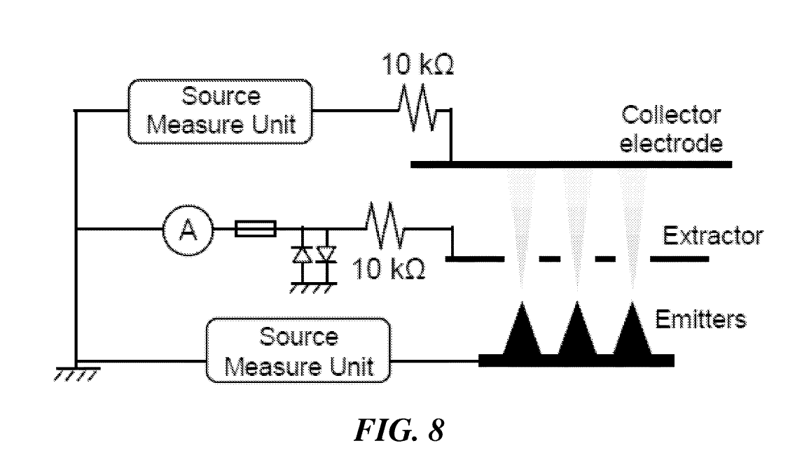

The electrospray sources were tested in a vacuum chamber at a pressure of about 10⁻⁶ Torr. For each test, a 0.5 microliter drop of EMI-BF₄ was deposited on the surface of the protrusions, which spread spontaneously to coat the surface of the protrusion arrays. The liquid stopped spreading once it reached the outer edge of the CNT-coated emitter active area and did not wet the surrounding silicon, thereby avoiding a potential electrical short due to liquid bridges forming between the electrodes at the dowel pins. The emitter and extractor dies were assembled together by clamping the deflection springs onto four acetal dowel pins, with polyimide spacers separating the two electrodes. A triode configuration was used to characterize the performance of the electrospray sources, in which a silicon collector electrode, placed 3.5 mm from the emitter die, was used to measure the emission current and also to collect imprints of the emission. The circuit used to test the devices is shown in FIG. 8. A Bertan 225-10R source-measure unit (SMU) was used to bias the emitter electrode up to ±2000 V, alternating the polarity to avoid a build-up of ions of either polarity. A Keithley 6485 picoammeter was used to measure the current intercepted by the extractor grid, and a Keithley 237 SMU was used to measure the collector current. A pair of diodes and a fuse were used to protect the picoammeter from current surges. The extractor electrode was held at 0 V and the collector electrode was biased up to 1000 V with opposite polarity relative to the polarity of the emitted beam (e.g., a positively biased emitter die would face a negatively biased collector). Data were collected using LabView run on a personal computer.

The performance of the electrospray sources with different array sizes was characterized. In all devices, three different phases of emission were observed: an initial overwet phase, a steady phase, and a depletion phase. With fresh liquid applied to the protrusion surface, emission was initially noisy and unstable, punctuated by current surges that were thought to be due to droplet emission. Subsequently, emission became more steady and was marked by output current as high as 5 microamps per protrusion. After more than five minutes of operation, the liquid on the surface of the protrusions began to deplete, and beyond a certain bias voltage the current stopped increasing. Once the liquid was replenished, the devices could be reused.

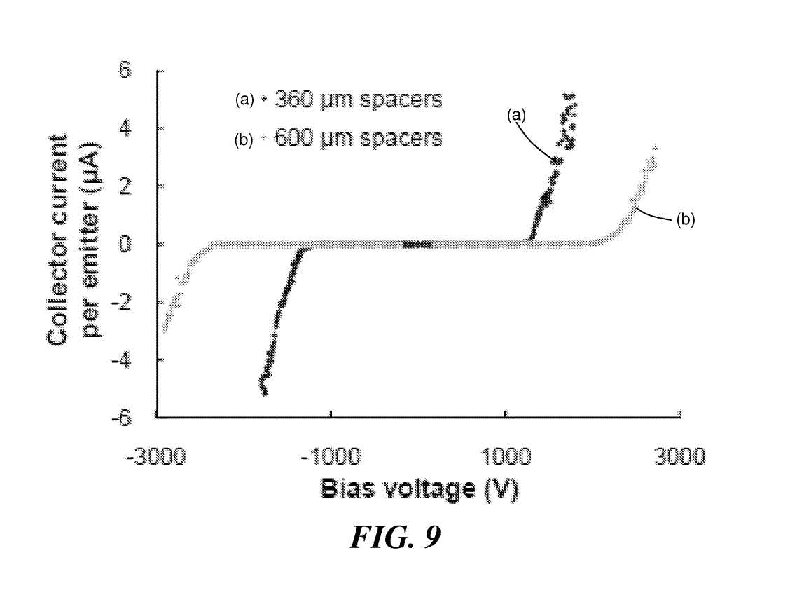

The current-voltage characteristics of a 7 by 7 protrusion array during the steady emission phase are shown in FIG. 9, with 600 micrometer (G=320 micrometer) and 360 micrometer (G=250 micrometer) separation between the emitter and extractor electrodes. Thinner spacers 240 micrometers thick were also tested, but these led to liquid shorts forming between the emitter and extractor electrodes shortly after emission began. The curves showed a strong non-linear dependence between the current and the bias voltage. The emission current increased exponentially for current below 0.5 μA, and then increased essentially linearly with a slope of 90 nA/V. Assuming the start-up voltage corresponds to the voltage at which the collector current per protrusion reaches 5×10⁻⁶ microamps, the start-up voltage was 520 V for the 360 micrometer spacers and 1200 V for 600 micrometer spacers. It was clear that reducing the gap between the electrodes reduced the operating voltage.

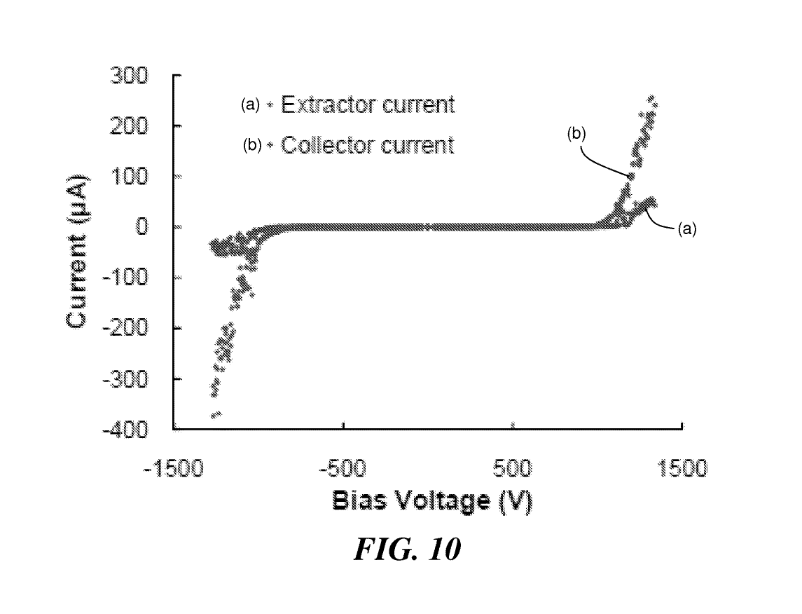

For currents above 50 nanoamps per protrusion, the devices typically exhibited about 80% transmission in both polarities. The extractor and emitter current for a 9 by 9 protrusion array are plotted in FIG. 10, showing an intercepted current on the extractor electrode consistently lower than 20%. This interception current could be reduced by increasing the aperture diameter (at the cost of having to increase the bias voltage), or by applying a larger bias voltage to the collector electrode.

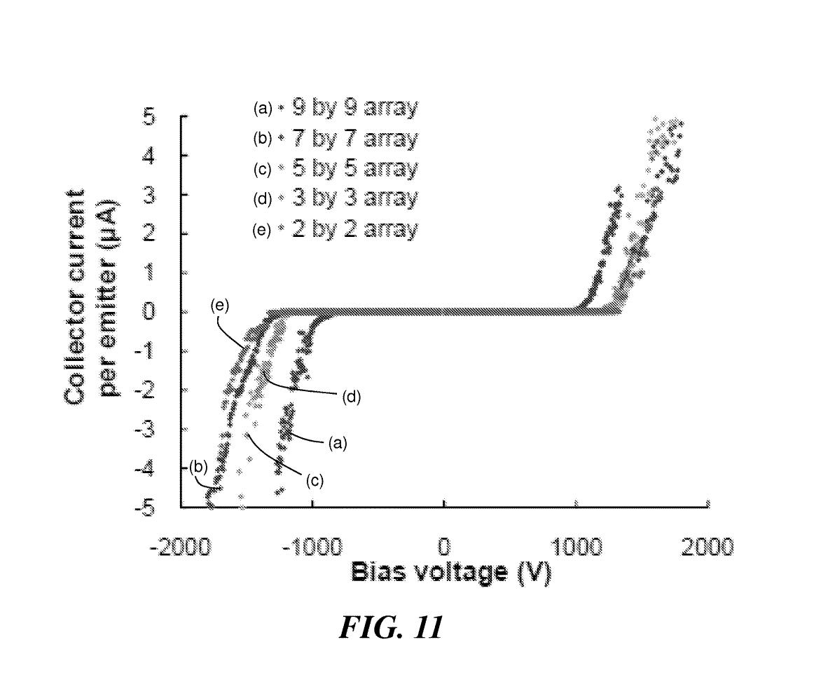

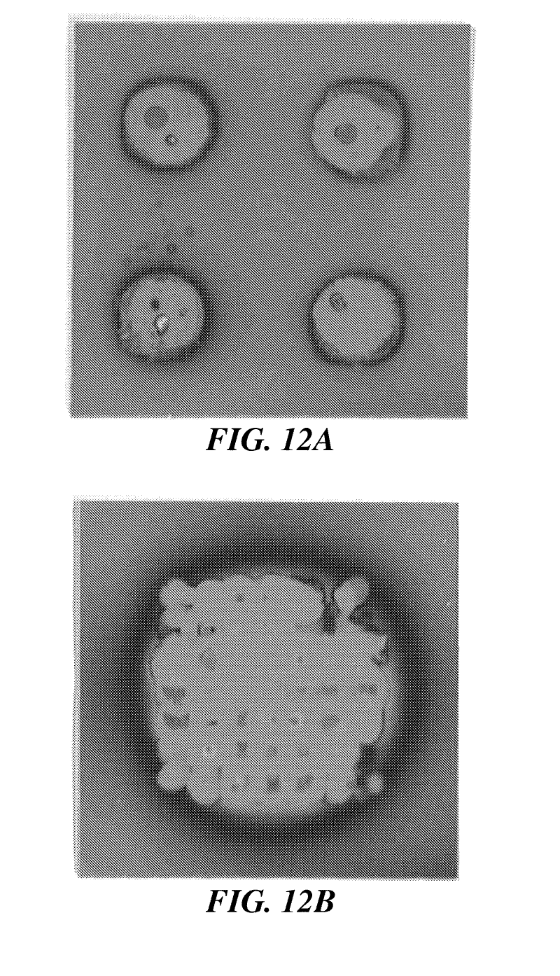

Current-voltage characteristics in the steady phase for all five emitting protrusion array sizes are shown in FIG. 11, using 360 micrometer-thick spacers between the emitter and extractor electrodes in all cases. Symmetric emission was obtained in both polarities with as much as 5 microamps per protrusion tip. Similar curve shapes and slopes indicated that the protrusion operated uniformly in each of the different-sized arrays. Lower start-up voltage was observed for the 9 by 9 emitting protrusion array because the etched protrusion were about 50 micrometers taller than in the other arrays. Imprints (FIGS. 12A-12B) on the collector electrode confirmed that the emitting protrusions turned on uniformly across the arrays, with patterns on the collector plates that matched the protrusion array layouts. To calculate the beam divergence angle, the imprints from the 2 by 2 protrusion array were used as a reference. The imprint from a single protrusion had a diameter of about 5.8 mm, and the collector was spaced 3.7 mm from the protrusion tips, corresponding to a beam divergence semi-angle of 38°.

### Example 2

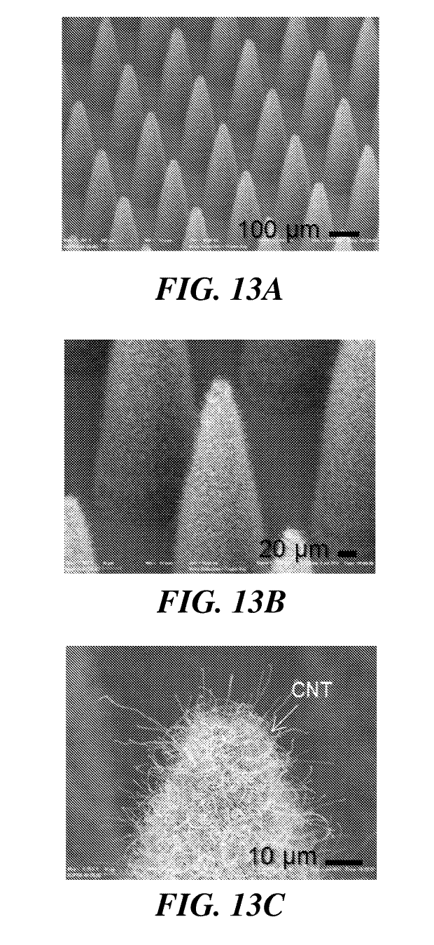

This example describes the fabrication of an emitter comprising a dense array of protrusions (1900 protrusions in 1 cm²) and an electrospraying system using the same. The emitter was fabricated using a similar process as outlined in Example 2, using alternating RIE and DRIE steps (rather than DRIE steps alone). The masking material included an array of three-notched dots, patterned in photoresist. The silicon underneath the notched dots was gradually undercut until sharp tips were formed. Next, a DRIE step was used to etch springs on the back side of the wafer. To complete the emitter dies, a CNT forest was grown on the surface of the emitters. A 50 nm thick titanium nitride film and a 20 nm thick nickel film were sputtered onto the 1 cm by 1 cm active area of the emitting protrusions using a shadow mask. CNTs were grown using a plasma enhanced chemical vapor deposition (PECVD) technique with ammonia and acetylene as precursor gases. The CNTs were 2 microns tall, averaged 115 nm in diameter, and conformally coated the surface of the protrusions and the entire active area of the emitter dies. SEM images of the resulting protrusion arrays are shown in FIGS. 13A-13C.

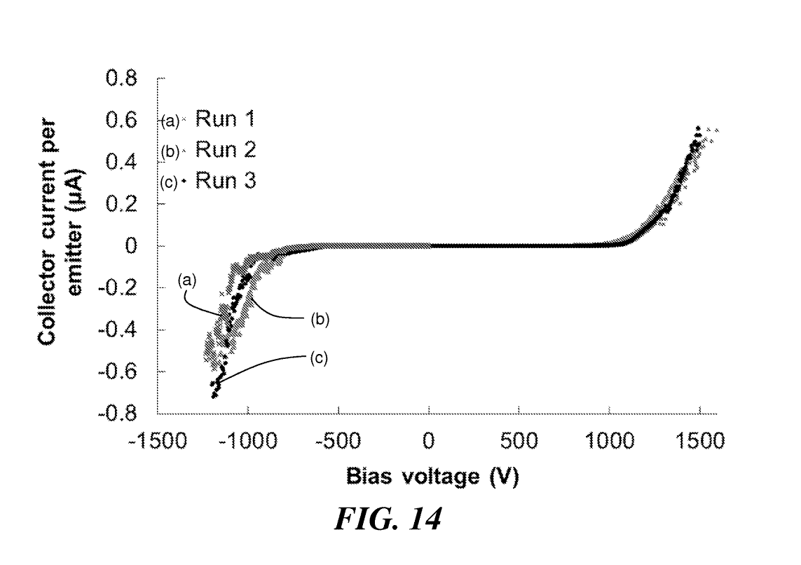

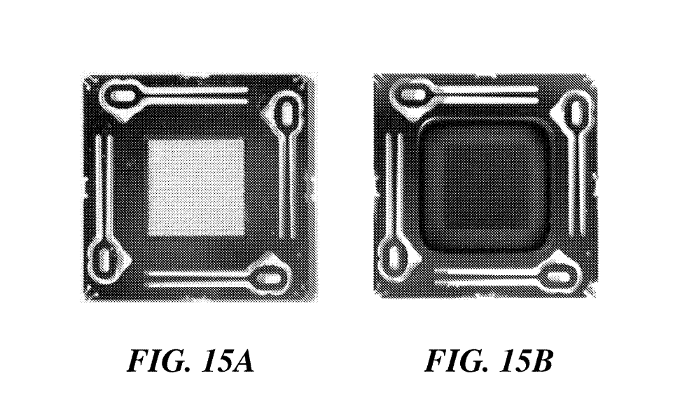

Current-voltage characteristics in the steady phase for the array of 1900 protrusions in 1 cm² are shown in FIG. 14, using 360 micrometer thick spacers between the emitter and extractor electrodes. Symmetric emission was obtained in both polarities with as much as 0.5 microamps per emitting protrusion tip. The average start-up voltage was 700 V. Maximum output current of 1 mA was measured, corresponding to an output current density of 1 mA/cm². The imprints on the collector electrodes indicated uniform emission across the emitting protrusion array.

### Example 3

This example describes the design, fabrication, and experimental characterization of dense, monolithic, planar arrays of externally-fed electrospray emitting protrusions with integrated extractor grid and carbon nanotube flow control structures for low-voltage and high-throughput electrospray of the ionic liquid EMI-BF₄ in vacuum. Microfabricated arrays with as many as 1900 emitting protrusions in 1 cm² were fabricated and tested. Per-protrusion currents as high as 5 μA in both polarities were measured, with start-up bias voltages as low as 470 V and extractor grid transmission as high as 80%. Maximum array emission currents of 1.35 mA (1.35 mA/cm²) were measured using arrays of 1900 protrusions in 1 cm². A conformal carbon nanotube forest grown on the surface of the protrusions acted as a wicking structure that transported liquid to the protrusion tips, providing hydraulic impedance to regulate and uniformize the emission across the array. Mass spectrometry of the electrospray beam confirmed that emission in both polarities was composed of solvated ions, and etching of the silicon collector electrode was observed. Collector imprints and per-protrusion current-voltage characteristics for different emitting protrusion array sizes spanning three orders of magnitude showed excellent emission uniformity across the array.

An electrospray source can generate droplets, ions, or a mixture of droplets and ions, depending on the physical properties of the liquid, the electric field, and the flow rate to the emission site. In the cone-jet mode, droplets are formed from the breakup of the jet ejected from the Taylor cone apex; in this regime, the range of stable volumetric flow rates, Q, depends on the properties of the liquid, according to:

$$Q = \frac{{η}^{2} {γɛ}_{r} {ɛ}_{o}}{ρ κ}$$

where η is a dimensionless parameter that ranges between 1 and 10, γ is the surface tension of the liquid, ∈ᵣ is the relative electrical permittivity of the liquid, ∈ₒ is the permittivity of free-space, ρ is the mass density of the liquid, and κ is the electrical conductivity of the liquid. The minimum volumetric flow rate, Qₘᵢₙ, at which stable cone-jet emission is observed, occurs when η is about 1. For flow rates below Qₘᵢₙ, it is possible to emit ions without any droplets if the liquid is sufficiently conductive and has a high surface tension.

The flow rate from an electrospray protrusion is set by either the flow rate drawn from the Taylor cone or the supply of liquid to the Taylor cone; the emission can therefore be barrier-limited, i.e., controlled by the ionization process, or supply-limited, i.e., controlled by the supply of liquid to the ionization site. With little or no limit on the supply of liquid to the emission site (e.g., electrospray from a free droplet, the free surface of a liquid pool, or a channel that provides little resistance to the flow), the flow rate is barrier-limited and set by the magnitude of the electric field at the surface of the liquid and the properties of the liquid. For an array of low-impedance capillary channels, variations in the local electric field across the array (e.g., due to edge effects, fabrication non-uniformities, or misalignment with the extractor electrode) can result in different flow rates being drawn at each emission site. Moreover, allowing the electric field to set the output flow rate could result in high flow rates that can lead to droplet emission rather than ionic emission.

One effective way to limit the flow rate in order to operate in the ionic regime is to place a large hydraulic impedance in series with an emission site. The viscous forces caused by the hydraulic impedance restrict the flow of the liquid and can limit the flow rate to a lower value than would otherwise be drawn by the electric field; in this case, the flow is supply-limited. For arrays of emitting protrusions, a large hydraulic resistor in series with each protrusion site can result in uniform array output because the effects of the spatial variations in the electric field are minimized. The objective of an optimized hydraulic impedance in an electrospray ion source is to set flow rates as close to Qₘᵢₙ as possible without exceeding that value, in order to maximize the ionic emission current from each emission site without producing droplets.

In externally-fed electrospray emitting protrusions, effective surface-fed electrospray of ions can require spontaneous spreading of the liquid over the surface of the protrusions, and viscous resistance to the flow, in order to limit the flow rate drawn at the tip to values below Qₘᵢₙ. These requirements can be met by coating the surface of the protrusions with a highly wetting, low-permeability porous medium through which the liquid will flow.

A forest of carbon nanotubes (CNTs) was used as a surface coating for arrays of externally-fed protrusions. CNT forests offer a number of advantages as a surface coating for externally-fed emitting protrusions: (i) CNT forests grown using plasma-enhanced chemical vapor deposition (PECVD) are highly wetting due to the combination of high surface energy and nanostructured roughness, (ii) CNTs can be grown conformally, (iii) the porosity of a CNT film, determined primarily by the CNT diameter and packing density, sets the hydraulic impedance of the film and is highly tunable by changing the growth parameters, and (iv) the height of the forest can be grown taller than the maximum height of black silicon to accommodate larger flow rates. The characteristics of a PECVD CNT forest, including the CNT diameter, packing density, height and vertical alignment, can be widely varied and finely tuned by changing the growth conditions.

The design of the batch-microfabricated MEMS multiplexed externally-fed electrospray array with integrated extractor grid and CNT flow control structures for high-throughput generation of ions from ionic liquids in vacuum had a hierarchical structure that brought together optimized features with associated characteristic lengths that spanned five orders of magnitude: mesoscale deflection springs for precision assembly of the emitter and extractor electrode dies to attain low beam interception, microsharp protrusion tips for low-voltage electrospray emission, and a nanostructured conformal CNT forest that acted as a wicking structure to control the flow rate fed to each protrusion and enforce array emission uniformity. To gain insight into the performance of dense arrays of externally-fed emitting protrusions with CNT flow control structures, the current-voltage characteristics of electrospray sources with a range of protrusion densities were measured, the emission plume was characterized using mass spectrometry, and imprints on a collector electrode were analyzed.

The multiplexed electrospray source was composed of an emitter die and an extractor grid die. Each die was 2.4 cm by 2.4 cm and 1 mm thick. The central 1 cm by 1 cm region of the emitter die was its active area, i.e., it contained the array of emitting protrusions. The central 1 cm by 1 cm region in the center of the extractor grid die contained a matching array of circular apertures. Four mesoscale deflection springs etched into each die were clamped onto 1/16″ outer diameter aluminum oxide dowel pins to align and electrically isolate the two parts. Polyimide spacers were fitted over the dowel pins to set the emitter-to-extractor separation. When the two dies were assembled, each protrusion tip sat centered underneath a grid aperture.

The extractor grid and emitter dies were fabricated using contact lithography starting with 1 mm thick, double-side polished, n-doped, 6″-diameter silicon wafers with a resistivity of 0.01-0.02 Ω·cm. To fabricate the extractor grid dies, a 500 nm thick thermal oxide was first grown on the wafer. Next, alignment marks were etched into the wafer front side, and both sides of the wafer were coated with a 250 nm thick silicon-rich silicon nitride film. Then, the nitride and oxide films on the front side were removed using plasma and buffered oxide etch (BOE), respectively. Twenty microns of photoresist were spun onto the front side of the wafer, and the features that created the aperture recess and the four springs were transferred; these features were etched to a depth of 750 μm using deep reactive-ion etching (DRIE), and the photoresist was removed. Next, a 1.5 μm-thick thermal oxide was grown on the wafer, and the backside nitride and oxide layers were removed using plasma. Twenty microns of photoresist were spun onto the backside of the wafer and the features that defined the array of apertures and a recess around the edge of the die were transferred. The front side of the wafer was mounted onto a quartz wafer. Subsequently, a backside DRIE step through-etched the apertures and created a 600 μm-deep recess around the edge of the die. The silicon wafer was released from the quartz wafer, the front side oxide was removed using diluted HF, and the dies were detached from the wafer by manually breaking thin tethers. Finally, a thin titanium nitride (10 nm) and gold (100 nm) film stack was sputtered onto the extractor grid dies.

To fabricate the emitter dies, alignment marks were etched into the wafer front side. Next, 20 μm of photoresist was spun onto both sides of the wafer, and arrays of three-notched dots were patterned in the front side photoresist to act as an etch mask to etch the protrusion arrays; the notched dots were 292 μm in diameter for the arrays of 4, 9, 25, 49 and 81 emitting protrusions in 1 cm², and 89 nm in diameter for the arrays of 1900 protrusions. In the case of the arrays of larger notched dots, the protrusions were etched using an isotropic SF₆ reactive-ion etch (RIE) recipe; this isotropic etch produced highly sharpened silicon protrusions with very smooth surface and average tip radii of 100 nm. In the case of the arrays of smaller notched dots, the protrusions were etched using a recipe that alternated isotropic SF₆ steps and DRIE steps; this etch roughened the sidewalls of the silicon and produced silicon protrusions with average tip radii of 4 nm. The front side of the wafer was mounted onto a quartz wafer and a backside DRIE step through-etched the springs. The wafer was released from the quartz wafer, and the emitter dies were detached from the wafer by manually breaking thin tethers. Using a shadow mask, 50 nm of titanium nitride and 20 nm of nickel were sputtered onto the active area of the emitter dies. Finally, PECVD CNTs were grown; the CNT forest conformally coated the entire active area, including the surface of the protrusions. FIGS. 15A and B show the extractor grid die (15A) and emitter die (15B) for an array of 1900 protrusions in 1 cm².

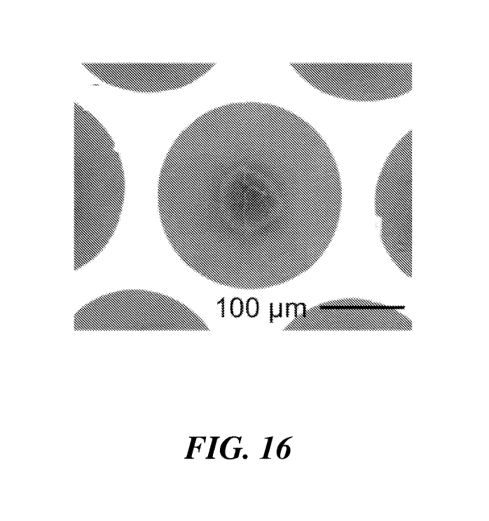

Emitter dies with different numbers of protrusions were fabricated. A first set of dies contained arrays of 4, 9, 25, 49, and 81 protrusions in 1 cm²; these devices were collectively referred to as the ‘sparse’ protrusion arrays. Their protrusions were 300 μm to 350 μm tall, had a sidewall taper angle of 55° from the horizontal, and were arranged with square packing. The corresponding extractor grid dies contained apertures that were 500 μm in diameter and 250 μm thick. A second set of emitter dies contained 1900 protrusions in 1 cm², and these were referred to in the text as the ‘dense’ protrusion arrays. Their protrusions were 450 μm tall with a sidewall taper angle of 80° from the horizontal and had hexagonal packing. The corresponding extractor grid dies contained circular apertures that were 200 μm in diameter and 250 μm thick. For electrical characterization, the assembled emitter and extractor dies were placed into a polyether ether ketone (PEEK) fixture, and electrical contact was made to the back side of the emitter die and to the front side of the extractor grid die. SEM images of the protrusion tip sitting centered below the extractor grid apertures are shown in FIG. 5B for a sparse array and FIG. 16 for a dense array. The thickness of the polyimide spacers set the distance G between the protrusion tip and the edge of the extractor grid aperture. The start-up voltage Vₛₜₐᵣₜ for emission from an externally-fed electrospray protrusion was:

$${V}_{start} = \sqrt{\frac{γ R}{{ɛ}_{o}}} ln ( \frac{2 G}{R} )$$

where R is the protrusion tip radius and G is greater than or equal to R. For low operating voltages, the distance G generally should be small. The thickness of the polyimide spacers should generally be chosen so that G is comparable to the radius of the grid apertures.

The CNTs were 2 μm tall and had an average outer diameter of 100 nm. The solid volume fraction of the CNTs in the CNT film was estimated from top-view SEM images to be 12%. The CNTs were oriented vertically in the case of the sparse protrusions, as is expected of PECVD CNTs because of the electric field, and oriented more randomly in the case of the dense protrusions. The difference in orientation may be due to the difference in the surface roughness of the two protrusions: the sparse protrusions had a visibly smoother surface than the dense protrusions. Alternatively, it is possible that the CNTs were not as well aligned to the direction of the electric field in the dense protrusion arrays due to the steep sidewalls of the protrusions. Nonetheless, both CNT films were highly wetting, and the difference in orientation of the CNTs was not observed to affect their performance as a wicking medium.

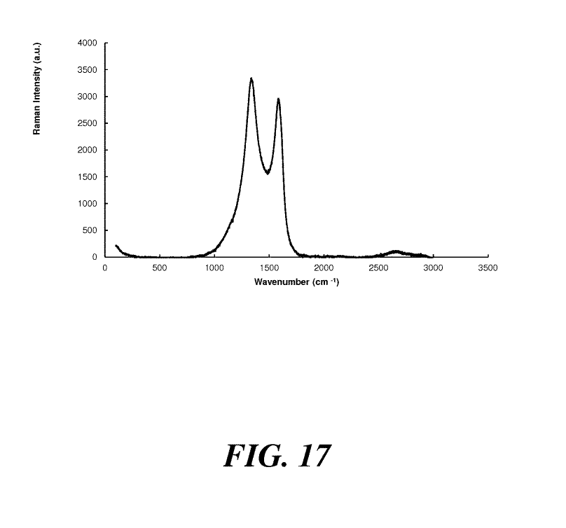

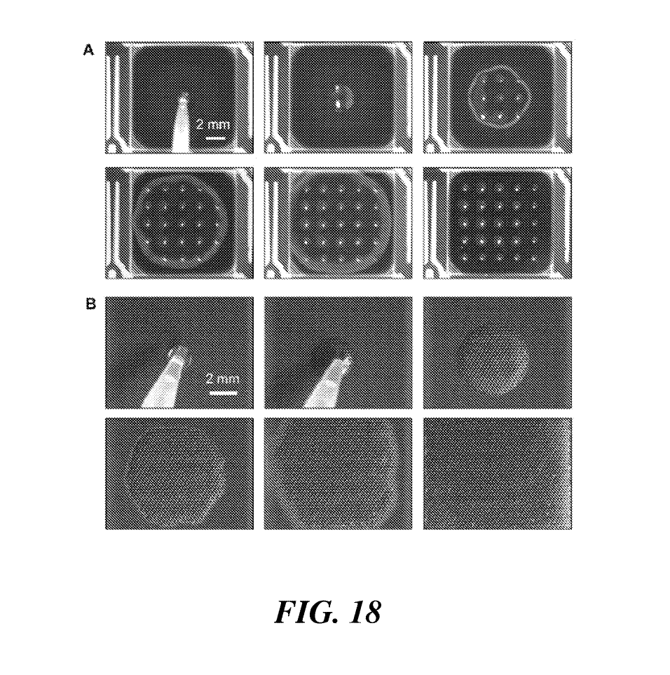

Pristine CNTs are poorly wetted by water and organic solvents and hence functionalization is generally needed to improve their wettability. However, PECVD CNT forests are highly wetting because they have a high defect density, which results in a high surface energy. Characterization of the PECVD CNT forest using Raman spectroscopy revealed that the ratio of the intensity of the D peak to the G peak was 1.1 (FIG. 17), consistent with CNTs with a high density of atomic defects. The high surface energy of the CNTs combined with the nanostructured roughness of the CNT forest created a highly wetting surface. A drop of EMI-BF₄ placed on the surface of a CNT forest spread spontaneously across the protrusion array, impregnating the surface and coating the protrusion tips, as shown in FIGS. 18A-B. The liquid stopped spreading once it reached the outer edge of the CNT-coated active area because of the difference in wetting properties of the CNT film and the surrounding silicon. SEM imaging of the protrusions after application of the ionic liquid revealed that a thin film of liquid coated the surface of the protrusions and the excess liquid pools at the emitter bases.

The wetting properties of the CNT film were time-dependent: the CNTs were most wetting immediately after growth, and a gradual drop in the spreading rate of EMI-BF₄ over the CNT film was observed several weeks after growth. Electrospray tests were typically conducted within several days of growth of the CNT forest on the surface of the protrusions, but devices tested up to one month after CNT growth showed no detectable difference in performance.

For each test, a drop of 0.5 μL (sparse arrays) or 5 μL (dense arrays) of EMI-BF₄ was deposited onto the active area of the emitter die. The liquid spread spontaneously to coat the surface of the protrusions. To assemble the electrode grid, the four dowel pins were inserted into the emitter die by drawing back each spring and sliding a dowel pin into the dowel slot, releasing the spring clamps the dowel pins in place. Polyimide spacers were placed over the dowel pins. The springs on the extractor grid die were drawn back, and the extractor grid die was slid into place over top of the emitter die. The assembled emitter and extractor dies were placed into a PEEK fixture that permitted electrical contact to the back side of the emitter die and to the top side of the extractor grid die. The devices were tested in vacuum at a pressure in the 1×10⁻⁶ Torr range.

A triode configuration was used to conduct quasi-static electrical characterization of the electrospray sources. A 2 cm by 2 cm mirror-polished silicon collector electrode was placed 3.5 mm in front of the device to measure the emission current and collect imprints of the emission. A Keithley 2657A source-measure unit (SMU) was used to bias the emitter electrode up to ±2000 V, applying a discretized triangular wave between the emitter and extractor electrodes with typical voltage step of 3 to 5 V, with a wave period in the 30 s range; the alternation of the polarity of the emission due to the triangular wave helped to slow down a build-up of ions that could trigger electrochemical effects on the protrusions. A Keithley 6485 picoammeter measured the current intercepted by the grounded extractor grid. A Keithley 2657A SMU applied a bias voltage up to ±1000 V to the collector electrode (with opposite polarity to the polarity of the emitted beam) using a square wave with period identical to the period of the triangular wave. A pair of diodes and a fuse protected the picoammeter from current surges. A LabVIEW script was used to control the SMUs and the picoammeter and to collect the experimental data. After a series of electrospray tests were conducted on a device, the liquid began to deplete. To replenish the liquid, the device was removed from vacuum, and the two electrodes were separated by removing the dowel pins. The extractor electrode was cleaned with acetone, rinsed with water and dried with an air gun. The emitter electrode was gently rinsed in a water bath and dried under a low vacuum (about 1 Torr). The collector electrode was replaced each time the liquid was replenished.

Across all devices, three different phases of emission were observed: an initial over-wet phase, a steady phase, and a depletion phase. With fresh liquid applied to the protrusion surface, emission was initially noisy and unstable, punctuated by current surges. One potential explanation of this behavior was thought to be emission of excessive liquid initially present at the surface of the protrusion tips. Subsequently, emission steadied and was marked by stable current emission that varied as a function of the applied emitter-to-extractor bias voltage. The length of time that the emission could operate in the steady phase depended on the initial applied volume of liquid deposited, the number of protrusions, and the level of the current output. Gradually, the current output at a given bias voltage was observed to decline as the liquid depleted.

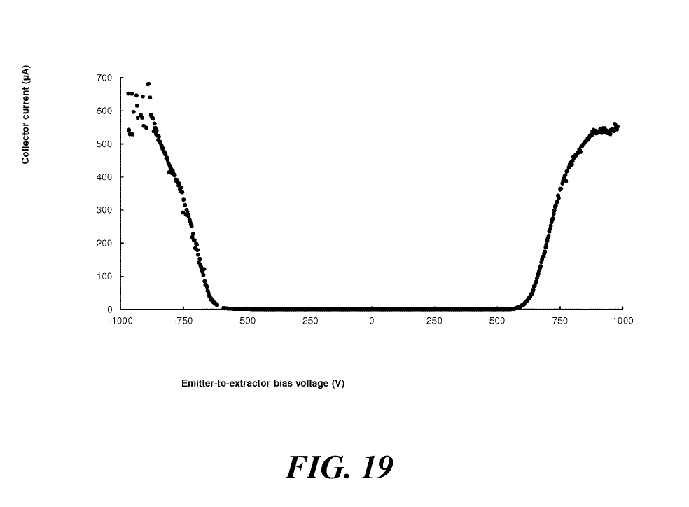

Typical current-voltage characteristics in the steady phase are shown in FIG. 19. The curves showed a strong non-linear dependence between the current and the bias voltage. Four general emission regions were identified: (i) no significant emission occurred below the start-up voltage, (ii) beyond the start-up voltage the current increased first exponentially and then (iii) linearly, and finally, (iv) there was a saturation region in which the current leveled off and becomes noisy, with little further increase in current with increased bias voltage. Below the start-up voltage, the electric field at the emission sites was low, and no measurable emission occurred. Beyond the start-up voltage, the exponential dependence of the current on the voltage indicates that ion emission occurred. For droplet emission, output currents are generally constant for voltages around the start-up voltage at a fixed flow rate. In contrast, ion emission is barrier limited and therefore, small changes in the voltage can produce large changes in the current, which was the behavior observed. At higher voltages, the transition to a linear dependence between the current and the applied voltage suggests that the flow became ballasted. As the emitter current increased, the large hydraulic impedance of the CNT forest limited the supply of liquid to the emission site, and emission became supply limited. The current continued to increase linearly until a maximum current was reached. At the saturation current, the current ceased to increase, the fraction of intercepted current at the extractor grid electrode rose, and the current at the collector electrode became noisy. Such behavior may have been the result of multiple Taylor cones forming, possibly leading to increased intercepted current.

Typical current-voltage characteristics showing the maximum measured emission current from both the sparse and dense protrusions are shown in FIGS. 11 and 14; the current was plotted up to the saturation current for clarity. For the sparse protrusions, symmetric emission was observed in both polarities with as much as 5 μA per protrusion tip, more than five times higher than the best values previously reported in the literature for a plurality of electrospray protrusions operating in parallel at the same time. The operating voltages were lower for the array of 81 protrusions than for the sparse emitting protrusion arrays, likely because the protrusions in the array of 81 protrusions were on average 50 μm taller than the protrusions in the smaller arrays. Defining the start-up voltage as the voltage at which the collector current per protrusion reached 5 pA, start-up voltages as low as 470 V were observed for the array of 81 protrusions, and 520 V for the smaller sparse emitting protrusion arrays. While there was some shift in the operating voltages due to differences in protrusion height and emitter-to-extractor aperture separation across the different devices, the similar curve shapes and slopes of the per-protrusion current-voltage curves for the different sparse emitting protrusion array sizes demonstrated that all of the protrusions operated uniformly. For the sparse emitting protrusion arrays, the current per protrusion increased exponentially up to a value of about 300 nA, and then increased more or less linearly with an average slope of 15 nA/V until the saturation current was reached. For the array of 81 protrusions, the maximum measured emission current was 650 μA (650 μA/cm²). The maximum current per protrusion was therefore 8 μA. This was significant, since 8 μA is generally at or about the largest ion current that can be emitted for EMI-BF₄ without emitting droplets. For the dense emitting protrusion arrays, start-up voltages consistently as low as 470 V were measured; the emission current increased exponentially for current below about 100 nA per protrusion, and then increased more or less linearly with an average slope of 2.3 nA/V until the saturation current was reached. The maximum measured emission current from these arrays was 1.35 mA (1.35 mA/cm²), and the maximum current per protrusion was 0.7 μA.

For the sparse emitting protrusion arrays, the devices typically had about 80% transmission in both polarities; for the dense emitting protrusion arrays, the transmitted current for the dense emitting protrusion arrays was as high as 60% in both polarities. The difference in aperture sizes between the dense and sparse emitting protrusion arrays is expected to account for the higher intercepted current for the dense emitting protrusion arrays. For both the sparse and dense protrusion arrays, the intercepted current was higher than previously reported for black silicon-coated devices, and could be reduced by increasing the diameter of the extractor grid apertures, though at the cost of increasing the operating voltage, or by reducing the thickness of the aperture grid.

Electrospray tests were conducted with different thickness spacers separating the emitter and extractor grid electrodes. For both the dense and sparse protrusions, the best performance was obtained using 360 μm thick spacers. Thicker spacers resulted in higher operating voltages. Using 240 μm thick spacers between the electrodes, liquid bridges occasionally formed between the protrusion tips and the extractor grid during operation, leading to a short circuit. Using 360 μm thick spacers, liquid bridges did not form between the electrodes, and the lowest operating voltages were observed. The current-voltage characteristics of an array of 49 protrusions during the steady emission phase are shown in FIG. 9 with both 600 μm thick (G=320 μm) and 360 μm thick (G=250 μm) spacers between the emitter and extractor grid electrodes. The start-up voltage was 520 V for the 360 μm spacers and 1300 V for the 600 μm spacers, demonstrating that reducing the distance between electrodes substantially reduced the operating voltages.

The current-voltage characteristics indicate that the emitted current increased exponentially at low voltages and depended on ionization at the liquid surface due to the electric field, while at high voltages the emission current from each protrusion was limited by the supply of liquid to the emission site due to the high hydraulic impedance. It was proposed to model the emission from the surface-fed electrospray sources by an electrical circuit with a voltage source in series with a diode and a resistor. The current I across a diode can be expressed as a function of the bias voltage V_{d}:

I=C₁(e^{c}^{₂}^{v}^{_{d}}−1)

where C₁ and C₂ are constants; the voltage drop Vᵣ across a linear resistor with resistance R is Vᵣ=IR. The applied voltage V can therefore be related to the emitted current I from the electrospray source according to:

$$V = \frac{1}{{C}_{2}} ln ( \frac{I}{{C}_{1}} + 1 ) + IR$$

The constants C₁ and C₂ depend on the parameters of the experimental setup, including the emitter-to-extractor separation distance, the protrusion height and tip radius, the temperature, and the physical properties of the liquid. For emission in the ionic regime, the volumetric flow rate Q can be expressed as a function of the output current I according to:

$$Q = \frac{I 〈 m / q 〉}{ρ}$$

where <m/q> is the average mass-to-charge ratio of the emitted particles and ρ is the density of the liquid. Therefore,

$$V = \frac{1}{{C}_{2}} ln ( \frac{Q ρ}{{C}_{1} 〈 m / q 〉} + 1 ) + \frac{Q ρ R}{〈 m / q 〉}$$

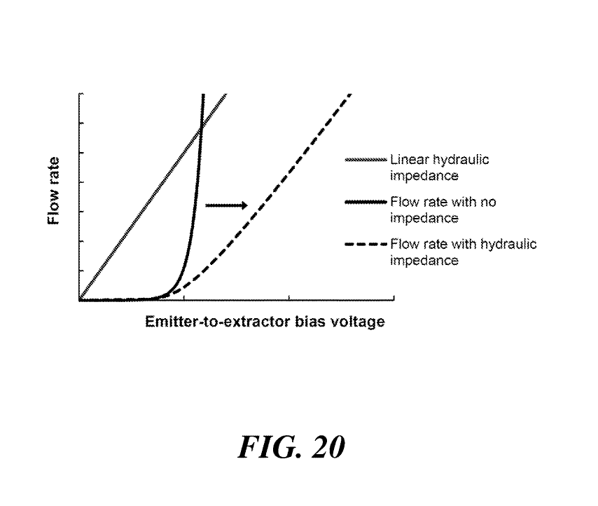

The effect of the hydraulic impedance in series with the ion emission site is shown schematically in FIG. 20. Without any hydraulic impedance, the output flow rate increased exponentially with the applied bias voltage; this flow was barrier-limited. With a linear hydraulic impedance in series with the emission site, the flow increased exponentially at low bias voltages (barrier-limited flow), and linearly at high bias voltages due to the ballasting effect (supply-limited flow). The value of the resistance R was expected to depend on the viscosity of the liquid and the permeability of the porous medium. The permeability of the forest was estimated to be K=3.3×10⁻¹⁵ m², considering a staggered arrangement of pillars with mean pillar diameter of 100 nm and a solid volume fraction of 12%. This model shows an excellent fit to the current-voltage data for both the sparse and dense protrusion arrays, with average calculated values for R of 30 MΩ (sparse protrusions) and 330 MΩ (dense protrusions).

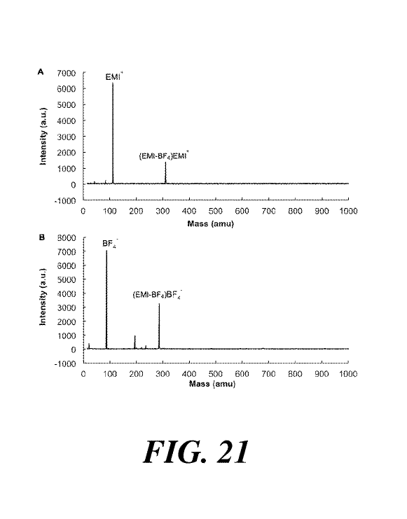

Mass spectrometry of the electrospray was conducted at a pressure in the range of 1×10⁻⁷ Torr using a commercial quadrupole mass spectrometer capable of measuring between 15 and 10,000 amu with up to 10,000:1 resolution (Ardara Technologies, Ardara Pa.). Spectra of the emission from a dense electrospray source in both the positive and negative polarities are shown in FIG. 21. In the positive polarity, the two main peaks observed in the mass spectrometry data corresponded closely to the masses of the monomer EMI⁺ (111.2 amu) and the dimer (EMI-BF₄)EMI⁺ (309.2 amu); no peaks for the trimer or larger ions were observed. In the negative polarity, peaks corresponding to the monomer BF4⁻ (86.8 amu) and the dimer (EMI-BF₄)BF₄⁻ (284.8 amu) were observed, along with minor but distinguishable peaks corresponding to the trimer (EMI-BF4)2BF4− (482.8 amu) and the tetramer (EMI-BF₄)₃BF₄⁻ (680.8 amu). These results demonstrated that the electrospray source operated in the ionic regime, with emission consisting mainly of monomers and dimers. On average, the output ion beam contained 85% monomers and 15% dimers for positive ions, and 72% monomers and 28% dimers for negative ions. In both cases, the average mass per unit charge

$$〈 \frac{m}{q} 〉$$

was 1.5×10⁻⁶ kg/C. Similar mass spectra were obtained using the sparse protrusion arrays. Other peaks, in particular a broad peak centered around 6258 amu that is associated with droplet emission, were not observed.

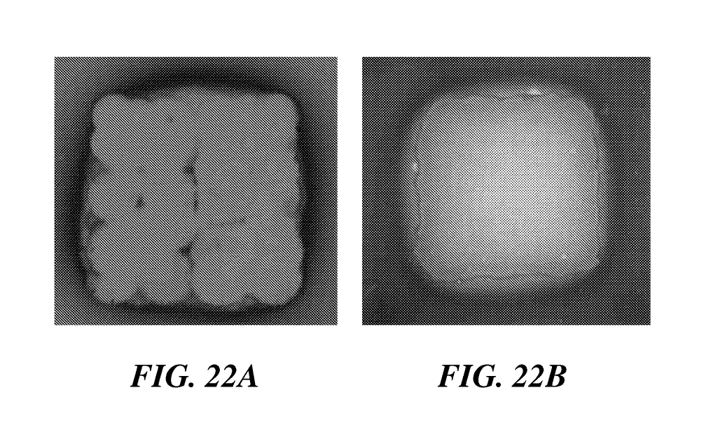

Imprints on the collector electrode were analyzed to study the deposition patterns and the array emission uniformity. Typical collector imprints are shown in FIGS. 12 and 22. The pattern of the imprints on the collector plates matched the protrusion layouts, indicating that all of the protrusions turned on. Additionally, the intensity of the imprints was uniform across the plate, indicating that the protrusions all emitted in a uniform manner. For the arrays of 4 and 9 protrusions, circular imprints were left on the collector plates; each imprint contained an inner circle of what appeared to be polished silicon with little additional coating, and a dark ring at the periphery. Based on the imprints of the array of 4 protrusions, a beam divergence semi-angle of 38° was estimated. Energy-dispersive X-ray spectroscopy (EDX) analysis showed barely detectable traces of carbon and fluorine within the inner circle, and stronger carbon and fluorine traces in the dark outer ring. One potential explanation is that material deposited in the area immediately above an protrusion tip was sputtered away, leaving an inner circular region with little deposited material. The deposits were darkest a short radial distance from the emission site where less sputtering occurred, and from there the deposits gradually faded further away from the emission site. For larger array sizes, the diameter of the lightly-coated inner circles decreased, possibly due to pinching of the individual beams due to charge repulsion. For the arrays of 81 and 1900 protrusions, imprints corresponding to individual protrusion tips were difficult to identify, leaving a 1 cm by 1 cm square region in the center of the collector plate that appeared to be polished silicon with little additional coating. For the larger protrusion array sizes (25, 49, 81, and 1900 protrusions), the darkest deposits were located in a ring surrounding the periphery of the center 1 cm by 1 cm square region, and the deposits gradually faded towards the edge of the collector plate; this area corresponded to the active area of the electrospray source. The intensity of the carbon and fluorine peaks in the EDX spectra was highest in the outer ring and weakest within the inner 1 cm by 1 cm area.

SEM images of the collector plates revealed that a small number of CNTs could be found deposited onto the collector plate within the 1 cm by 1 cm center region, as shown in FIG. 23A; a larger number of CNTs were deposited onto the collector plates in the case of the dense protrusion arrays. Small, round nanoparticles with diameters on the order of 400 nm and smaller were also observed on the collector plates. These nanoparticles were identified as silicon using EDX analysis, and were found in the 1 cm by 1 cm center on the collector plate and not in the surrounding area, indicating that they were a result of the electrospray process. No traces of nickel or titanium were measured on the collector plates.

To examine the collector plates for etching, collector plates were cleaved, and the cross-sections of the plates were examined in an SEM. Clear signs of etching were seen on the collector plates from emission from the dense protrusions, with as much as 110 nm of etched silicon (FIG. 23B).

One explanation for the presence of CNTs on the collector plate was that the CNTs were pulled from the surface of the protrusion electrode by the electric field, indicating that the base of a subset of the CNTs was not sufficiently well anchored to the surface of the protrusions. The higher number of CNTs on the collector plates from the dense protrusions may be an indication that adhesion is better in the case of the sparse protrusions. Adhesion of CNTs to a substrate can be correlated to the strength of the electric field during growth. Since the CNTs grown on the protrusions in the sparse protrusion arrays were much better aligned to the direction of the electric field than the CNTs grown on the dense protrusions, it is postulated that the CNTs on the protrusions in the dense arrays may have weaker adhesion to the underlying substrate. Nonetheless, the number of CNTs deposited on the collector plates was very small compared to the number of CNTs in the forests, so little overall degradation of the forest occurred. The CNT detachment seems not to be related to the magnitude of the flow rate per protrusion because the protrusions from the sparse protrusion arrays can deliver up to an order of magnitude more flow rate than the protrusions from the dense arrays. The mass spectrometry results showed emission of monomers and dimers, so if CNTs are emitted below these current levels then the CNTs must be emitted without accompanying droplets; it is plausible that CNT emission occurred only during the noisy, saturation period that was observed at the highest applied bias voltages, and that below the saturation current emission was ionic; the emission of CNTs could also have taken place during the over-wetting phase.

The origin of the silicon nanoparticles on the collector plates is also unknown. Their presence on the collector plates must be a result of the electrospray emission process because the nanoparticles were highly localized to the region on the collector electrode directly above the protrusion array. These nanoparticles may be the result of the etching of the silicon collector plate, or may be a product of a chemical reaction between the silicon and the ionic liquid.

The thrust from an electrospray source can be estimated based on the measured emission current and the mass spectrometry of the beam. An expression for thrust T is:

T=\sqrt{2\dot{m}ηₒPᵢₙ}

where \dot{m} is the total mass flow rate exiting the electrospray source, ηo is the overall thrust efficiency, and Pᵢₙ is the electric power supplied to the thruster, i.e., the applied voltage V times the total output current I. The mass flow rate can also be expressed in terms of the output current as

$$\dot{m} = I 〈 \frac{m}{q} 〉$$

The overall thrust efficiency is given by:

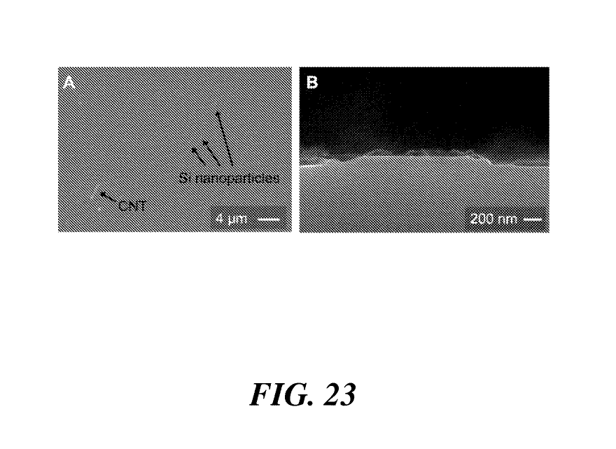

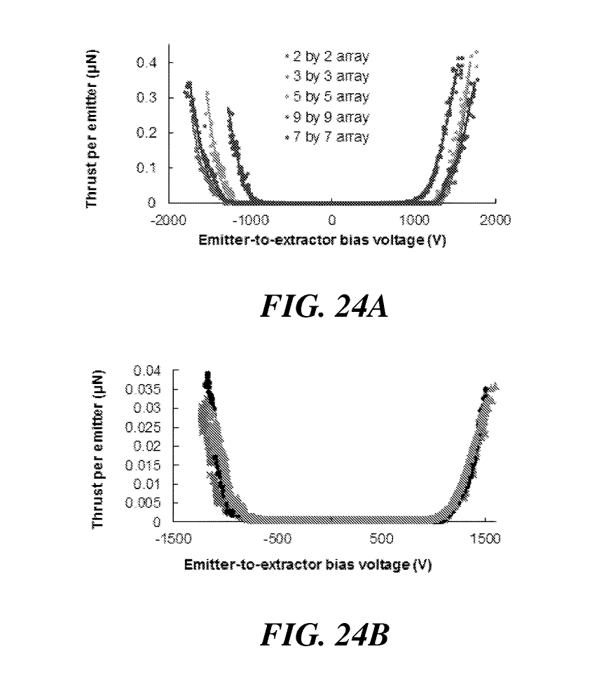

ηₒ=ηᵢ·ηₜᵣ²·η_{θ}·η_{E}·ηₚ

where ηᵢ is the ionization efficiency, ηₜᵣ is the transmission efficiency, η_{θ} is the angular efficiency, is the energy efficiency and ηₚ is the polydispersive efficiency. Both the ionization efficiency and the energy efficiency were taken to be close to 1 for the case of electrospray of EMI-BF₄ in the ionic regime. The angular efficiency was calculated to be 91.5% for an upper-bound beam divergence semi-angle of 38°. The polydispersive efficiency was calculated to be 91.9% for negative ions and 95.5% for positive ions. The expression for thrust can be rewritten in terms of the measured collector current as

$$T = {I}_{coll} \sqrt{2 V 〈 \frac{m}{q} 〉 {η}_{i} {η}_{θ} {η}_{E} {η}_{p}}$$

where I_{coll} is the current that reaches the collector electrode. Specific impulse is given by

$${I}_{sp} = \frac{T}{\dot{m} g}$$

where g is the gravitational constant. Calculated thrust as a function of the emitter-to-extractor bias voltage was plotted in FIG. 24 for both sparse (24A) and dense (24B) protrusion arrays assuming ionic emission in all cases up to the maximum current. The maximum calculated values of thrust and specific impulse are listed in Table 1. The highest calculated thrust was 75 μN for the array of 1900 protrusions, and the largest thrust per protrusion was 0.43 μN for the array of 25 protrusion tips. Higher thrust and specific impulse by as much as a factor of two could be obtained for the array of 1900 protrusions by reducing the intercepted current at the extractor grid electrode. The thrust per protrusion in the sparse protrusion arrays was about an order of magnitude larger than in the dense protrusion arrays; it is possible that an array of about 200 protrusions in 1 cm² could outperform the array of 1900 protrusions in 1 cm², suggesting perhaps an optimal limit in the miniaturization and protrusion area packing, using the current device architecture.

TABLE 1

| | | | |
|---|---|---|---|
| Array | Maximum | Maximum thrust | Specific impulse |
| Size | thrust | per protrusion | at max current |

| | | | | | |
|---|---|---|---|---|---|
| 4 | 0.9 | μN | 0.23 | μN | 4235 s |
| 9 | 1.2 | μN | 0.13 | μN | 4463 s |
| 25 | 10.8 | μN | 0.43 | μN | 4615 s |
| 49 | 17.1 | μN | 0.34 | μN | 4595 s |
| 81 | 33.6 | μN | 0.41 | μN | 4297 s |
| 1900 | 75 | μN | 0.039 | μN | 3691 s |

For EMI-BF₄, the minimum flow rate Qₘᵢₙ below which emission is expected to be ionic was 3.5×10⁻¹⁵ m³/s, considering a surface tension of 0.054 N/m, a relative electrical permittivity of 12.8, a mass density of 1285.3 kg/m³ and an electrical conductivity of 1.36 S/m. At the maximum measured currents, emission of 0.7 μA per protrusion for the dense protrusions corresponded to a flow rate per protrusion of 8.2×10⁻¹⁶ m³/s, and 5 μA per protrusion for the array of 81 protrusions corresponded to a flow rate per protrusion of 5.8×10⁻¹⁵ m³/s, assuming ionic emission up to the maximum emission current. In both case, the flow rates fell close to the value of Qₘᵢₙ.

With an initial application of 5 μL of ionic liquid, the array of 1900 protrusions could operate continually at the maximum current of 0.5 μA per protrusion for 53 minutes, while the array of 81 protrusions could operate at an output current of 5 μA per protrusion could operate continually for 18 minutes with an initial application of 0.5 μL of ionic liquid.

The CNT forest on the surface of the protrusions served as a highly effective porous medium to transport the ionic liquid to the emission sites on the surface-fed protrusions, resulting in stable, uniform electrospray emission; however, the results indicated that good adhesion between the porous medium and the protrusion surface is helpful. Deposition of a pore-free, conformal thin film coating over the CNT forest to improve adhesion to the underlying surface is an option to explore. Platinum would be a good candidate as a coating material because it can be conformally sputtered and has been shown to be highly resistant to the electrochemical effects from electrospraying EMI-BF₄. Nanostructured surface coatings on the silicon protrusions are not limited to CNT forests; for example, a forest of zinc oxide nanowires could be grown conformally on non-planar structures such as the silicon protrusions with a great deal of control over the morphology of the nanowire forest by tuning the growth conditions.

Cross-sections of the collector plates show that the silicon had been etched by as much as 110 nm; the silicon was likely to be etched through sputtering, due to collisions of highly energetic ions with the silicon surface. Etching using these sources is therefore a technology with great promise as a nanomanufacturing technique on par with etching using liquid metal ion sources, with the additional advantage of providing multiplexed high-throughput etching over broad areas.

The first demonstration of a MEMS multiplexed electrospray source with an integrated extractor grid and CNT flow control structures for low-voltage high-throughput electrospray ion emission from ionic liquids in vacuum has been reported. Using electrospray sources with 4, 9, 25, 49, 81 and 1900 protrusions in 1 cm², symmetric emission in both polarities with as much as 5 μA per protrusion tip was obtained, with start-up voltages as low as 470 V and transmission as high as 80% through the extractor grid. Maximum emission currents of 1.35 mA (1.35 mA/cm²) were measured using arrays of 1900 protrusions in 1 cm². Imprints on the collector electrodes and uniform slopes in the current-voltage curves for different protrusion array sizes demonstrated that emission was uniform across the protrusion arrays and that flow to the protrusions was ballasted. Mass spectrometry characterization confirmed that emission occurred in the ionic regime, and etching of the collector plate was observed. Future work should address adhesion of the CNT film to the protrusion surface, long-term operation of the electrospray source and focus on improving extractor grid transmission for the dense arrays of protrusions.

### Example 4

This example describes the preparation of nanocolloids and the use of nanocolloids in electrospraying systems.

To prepare the nanocolloids, 5 mL of EMI-BF₄ was poured into glass dishes. The dishes were 5 cm in diameter and 1.2 cm deep. Each dish was placed in a sputtering chamber, and a material was sputtered using a target of the material. The pressure was generally in the range of about 10⁻⁵ Torr. In one set of experiments, the sputtered material was tungsten (e.g., a tungsten target was used). DC sputtering was used with the tungsten target, and power was variable. In another set of experiments, the sputtered material was titanium dioxide (e.g., a titanium dioxide target was used). RF sputtering was used with the titanium dioxide target.

The first sample was prepared by sputtering a tungsten target using a power of 200 W for 30 minutes, with a measured deposition rate of 2.5 A/s. The second sample was prepared by sputtering a tungsten target using a power of 100 W for 30 minutes, with a measured deposition rate of 1.4 A/s. The third sample was prepared using a titanium oxide (TiO₂) target with a power of 150 W for 2 hours, with a measured deposition rate of 0.14 A/s.

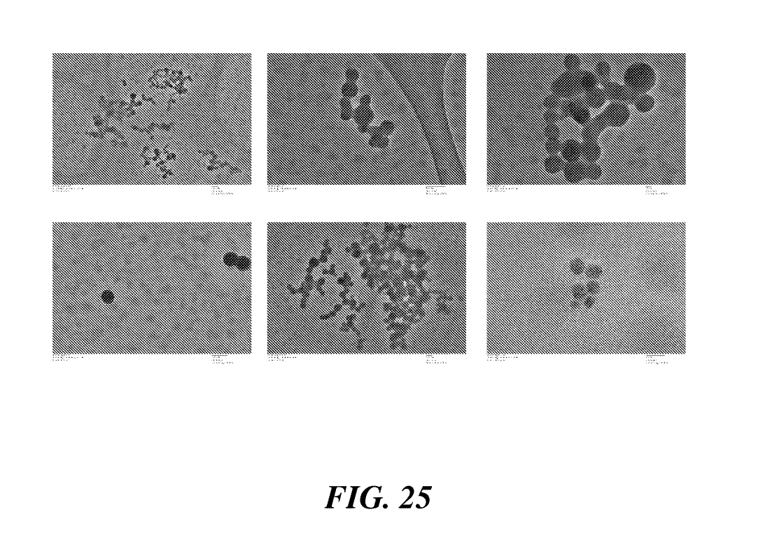

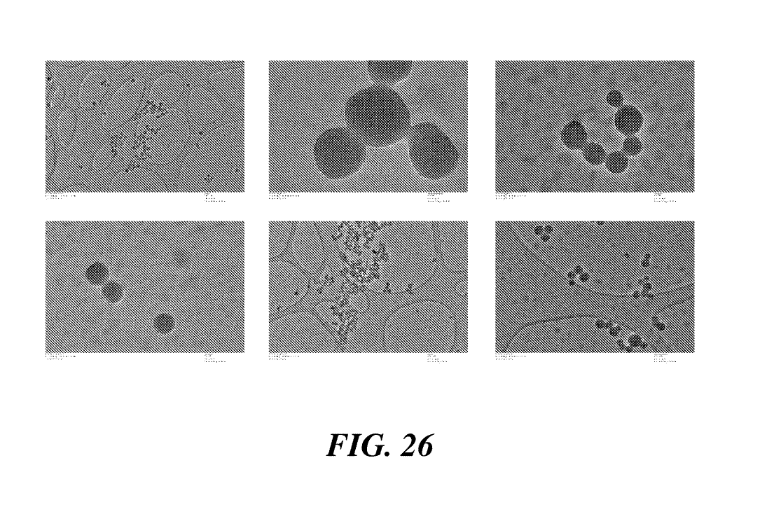

To image the nanoparticles, a small drop of liquid was placed on a transmission electron microscopy (TEM) grid (Ultrathin Carbon Film on Holey Carbon Support Film, 400 mesh, Copper, Ted Pella). The grid and liquid were then heated in an oven for 30 minutes at 100° C. temperature, and then gently rinsed off with deionized water to remove the ionic liquid, leaving some nanoparticles suspended on the TEM grid. FIG. 25 shows TEM images of tungsten particles sputtered at 100 W into EMI-BF₄ on a TEM grid. FIG. 26 shows TEM images of tungsten particles sputtered at 200 W into EMI-BF₄ on a TEM grid.

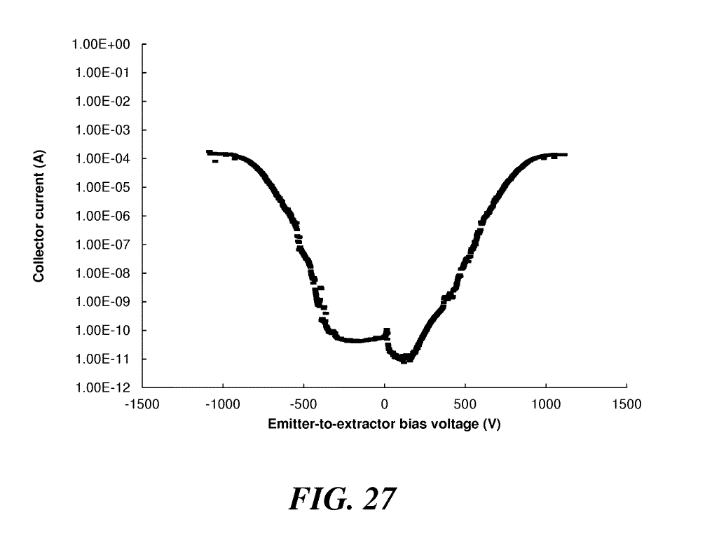

The prepared nanocolloid solutions were then electrosprayed in an electrospraying system. The electrospray emission was characterized by measuring current-voltage curves up to the maximum emission currents. A current-voltage curve for EMI-BF₄ sputtered with tungsten at 100 W is shown in FIG. 27. Additionally, imprints were collected on collector plates, mass spectrometry was collected using a quadrupole mass spectrometer, and UV-vis measurements were made using a Cary 500i UV-Vis-NIR Dual-Beam Spectrophotometer (TM).

### Example 5

This example describes the design, fabrication, and experimental characterization of an externally-fed, silicon batch fabricated MEMS electrospinning planar array with as many as 9 steady-operating emitting protrusions in 1 cm². The device could be used to simultaneously generate multiple nanofiber jets using a bias voltage of 20 kV or less by using an array of pointed emitting protrusions that enhance the local electric field to trigger the ionization of a polymer solution at the emitting protrusion tips. The surfaces of the emitting protrusions were patterned with a microstructure that allowed for the delivery of polymer solution to the emitting protrusion tips without the need for external pumping. Scanning electron microscope (SEM) images confirmed fiber diameters on the order of 150 nm.

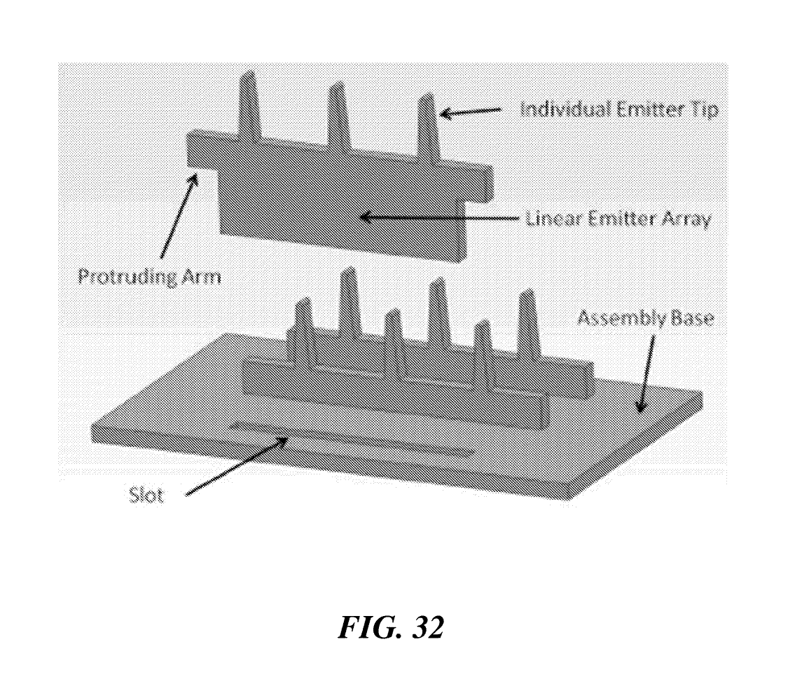

The devices described in this example included a hierarchically structured, externally-fed MEMS electrospinning array. One-dimensional (in this case, linear) arrays of meso-scale spikes, which serve as emitting protrusions, were assembled into a slotted base to form two-dimensional (in this case, planar) arrays, as shown in FIG. 32. Micro-scale structures on the surfaces of the emitting protrusions allowed for the delivery of fluid to the field-enhancing spike-tips where the fluid was spun into fibers. Using this technology, MEMS planar arrays with as many as 9 electrospinning emitting protrusions with 3-mm pitch were developed.

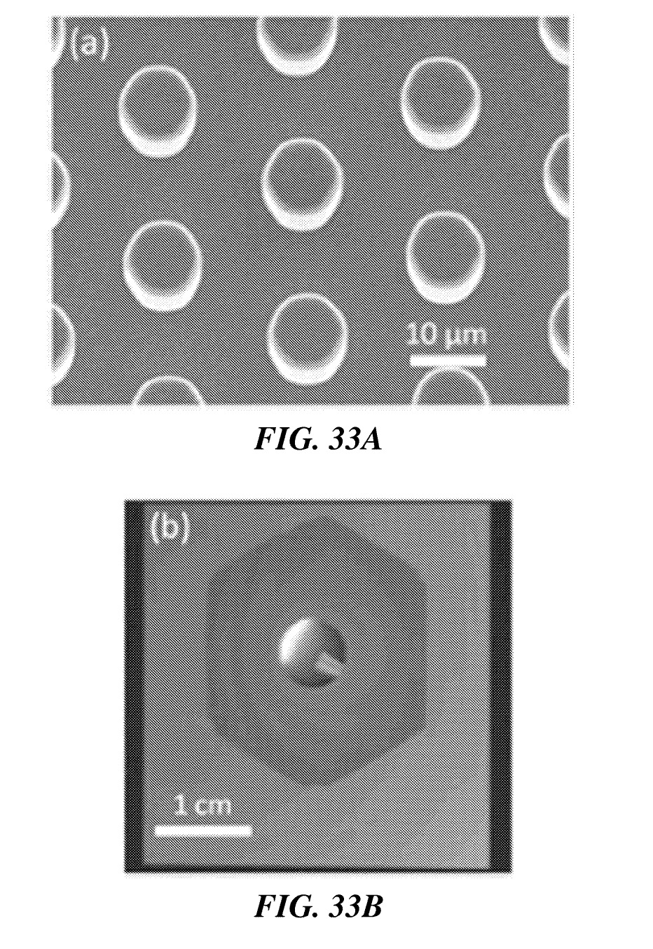

The MEMS multiplexed electrospinning sources used externally-fed emitting protrusions to circumvent the clogging and pumping problems that pressure-fed electrospinning sources often exhibit. In order to operate continuously, fluid is generally replenished to the emitting protrusion tips via free surface flow. A hydrophilic emitting protrusion surface is useful to allow for fluid spreading. On a smooth surface, complete spreading can generally only be achieved with contact angles approaching zero, which are rare. However, for roughened surfaces, surface energy minimization relaxes the spreading condition to:

$$cos ( θ ) \geq cos ( {θ}_{crit} ) = \frac{1 - ϕ}{r - ϕ}$$

where the roughness r is defined as the ratio of actual area to apparent area and is the ratio of dry area to apparent area in the spreading region. For a roughness structure of hexagonally packed micropillars (FIGS. 33A-33B), these quantities are easily calculated in terms of the diameter d, height h, and pitch p of the pillars. Capillary forces in these “micropillar forests” can “hemi-wick” liquid in a process that is analogous to capillary rise in a closed tube. The dynamics of hemi-wicking through the micropillar forest can be solved for numerically or approximated using Darcy's Law. For the relatively viscous solutions used in electrospinning, the dynamics are sufficiently slow that it is prudent to “prime” the emitting protrusions by coating them with polymer just prior to operation; this allows a liquid film to quickly impregnate the micropillars, which can then support a secondary film outside of the roughness. Under the influence of the electric field, this secondary layer contributes significantly to overall fluid replenishment rate, allowing steady operation of the emitting protrusions.

The MEMS multiplexed electrospinning source described in this example uses high aspect ratio emitting protrusions that act as field enhancers to ionize the polymer solution at low voltage. The emitting protrusions trigger nanofiber generation when the electrostatic pressure surpasses the pulling due to surface tension, a condition given by:

$$\frac{1}{2} {ɛ}_{o} \cdot {E}_{s}^{2} \geq \frac{2 \cdot γ}{{R}_{c}}$$

where ∈ₒ is the electrical permittivity of free space, Eₛ is the electric field at the surface of the tip, γ is the surface tension of the liquid, and R_{c} is the radius of curvature of the liquid free surface, which is on the order of the tip radius. Eₛ≈βV, where V is the bias voltage and β is the field factor; therefore, spikes with high field factor achieve ionization of the liquid with less voltage. For ideal spiked structures of length L and tip radius r, β should grow linearly with the aspect ratio L/r. The spike tips the MEMS multiplexed electrospinning source described in this example contained moderate curvature r in one direction and no curvature in the other direction except at the edges where the curvature is very high. COMSOL Multiphysics was used to simulate the electrostatics for this type of geometry and determine the field factor of the spike. The results revealed that the sharp edge curvature overpower the moderate curvature defined by the tip radius, such that variations in tip radius have only a minor effect on the field enhancement (FIGS. 34A-34B). Therefore, it is expected that electrospinning of nanofibers will be concentrated at the sharp edge where the micropillar forest terminates.

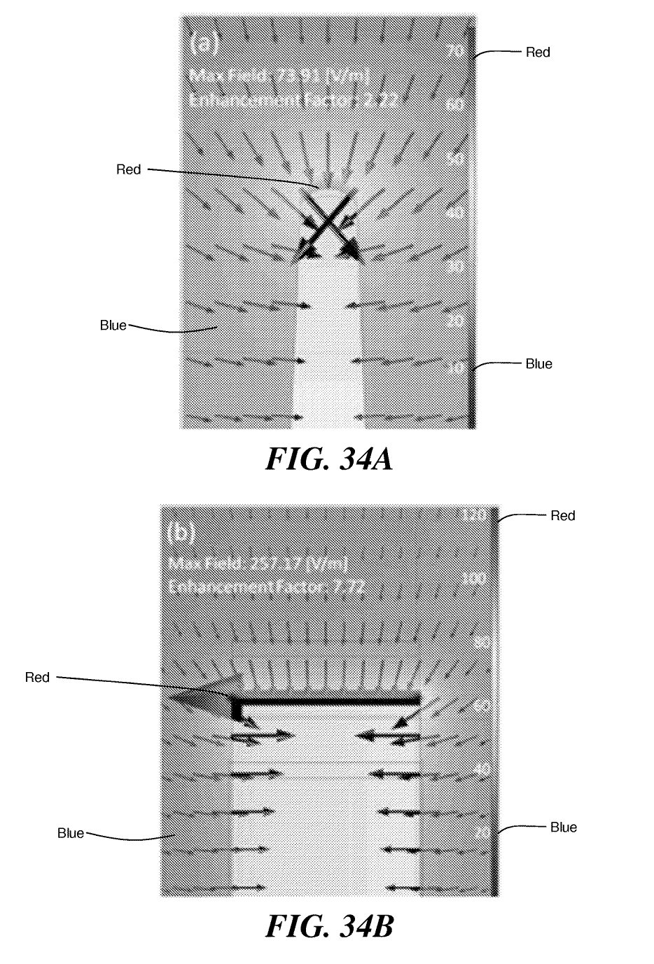

MEMS electrospinning emitting protrusion arrays were batch-microfabricated from 500 micrometer-thick, 6-inch double side polished silicon wafers. Deep reactive ion etching (DRIE) and a nested mask composed of a developed photoresist film on top of a reactive ion etching (RIE)-patterned silicon oxide film were used to etch the surface microstructure and extract the linear arrays of spikes from the silicon substrate. The resulting structure is shown in FIGS. 35A-35B. The slotted base piece was also microfabricated using DRIE, with the slot widths tapered for a sliding interference fit so that assembly of the emitting protrusions could be achieved with mild force using a pair of tweezers. Good vertical alignment was maintained with protruding arms on the linear emitting protrusion arrays that contact the top of the base on both sides of the slot. A single linear emitting protrusion array had an active length of 1 cm with 1 to 5 emitting protrusions measuring 0.5 to 5 mm in height and 50 to 250 micrometers in tip radius. The micropillar surface roughness included pillars with diameters of 5 to 35 micrometers, pitches of 20 to 40 micrometers, and heights of 100 to 200 micrometers.

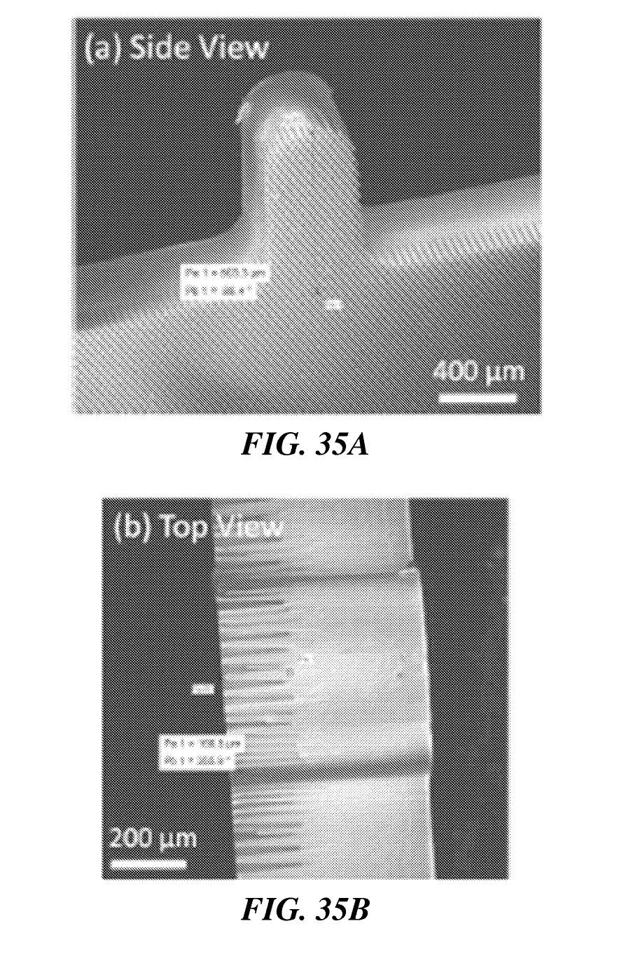

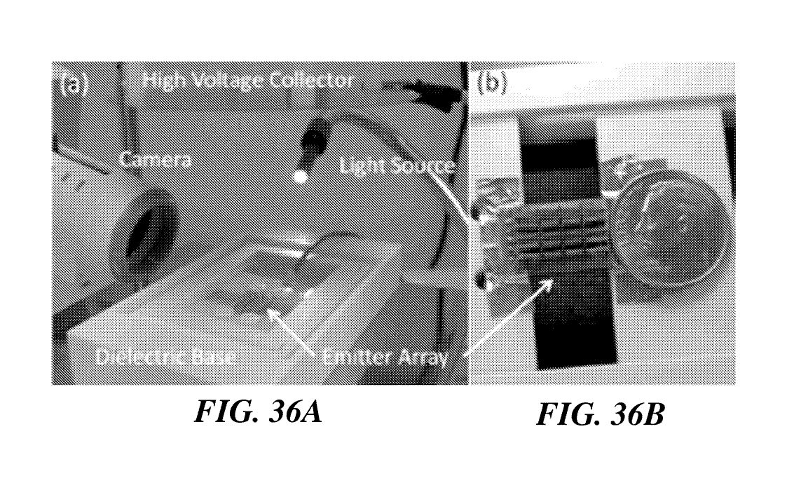

Polyethylene oxide (PEO) with an average molecular weight of 600,000 g/mol was dissolved in deionized water at a concentration of 6% w/v. This solution was further diluted to yield concentrations between 2 and 6 w/v % in water/ethanol mixtures ranging from 100/0 v/v to 60/40 v/v. Assembled planar emitting protrusion arrays were secured with to a grounded electrical contact on a support rig made of polyphenylene sulfide (PPS), a chemically resistant dielectric. DC high voltage was biased between the emitting protrusion array and a collector, which was placed between 1 and 15 cm away from the emitting protrusions (FIGS. 36A-36B). Polymer solution was deposited over the emitting protrusions with a pipette, and the voltage was increased until the initiation of fiber emission. Video images were recorded of full arrays and individual emitting protrusions during electrospinning to monitor the fiber production process.

The MEMS devices demonstrated successful electrospinning of PEO nanofibers, like those shown in FIGS. 37A-37B, with diameters of a few hundred nanometers or less. Electrospinning of higher concentration solutions with higher viscosity resulted in thicker, more uniform fibers. Several different regimes of electrospinning were also noted, which seemed to be determined by combinations of protrusion geometry, wetting characteristics, and electric field strength. In all cases, the starting voltage for fiber emission proved to be greater than what was needed to maintain electrospinning from already flowing jets, so in our tests we often lowered the voltage below the starting value once the process had initiated. In general, this resulted in more uniform, controlled emission.

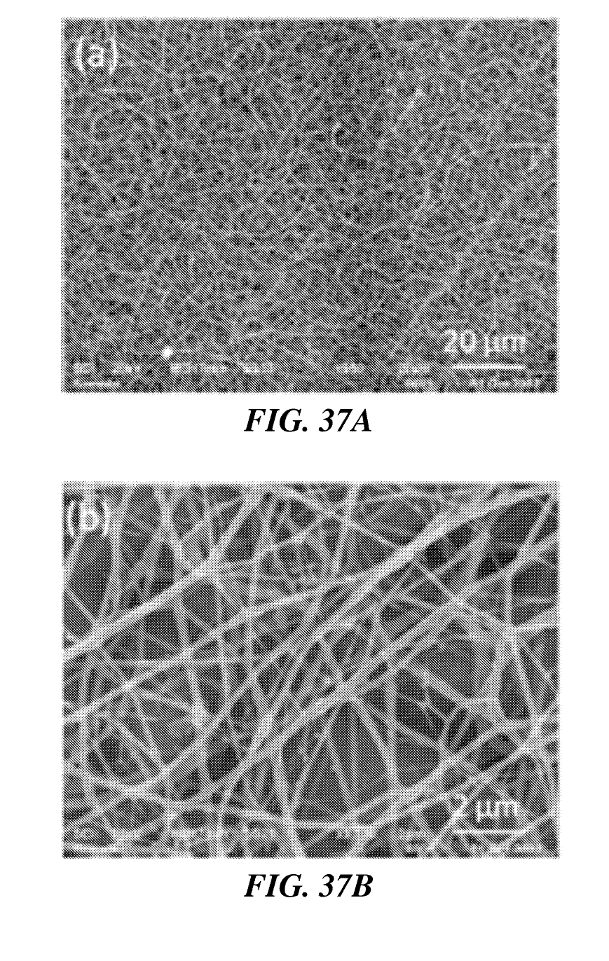

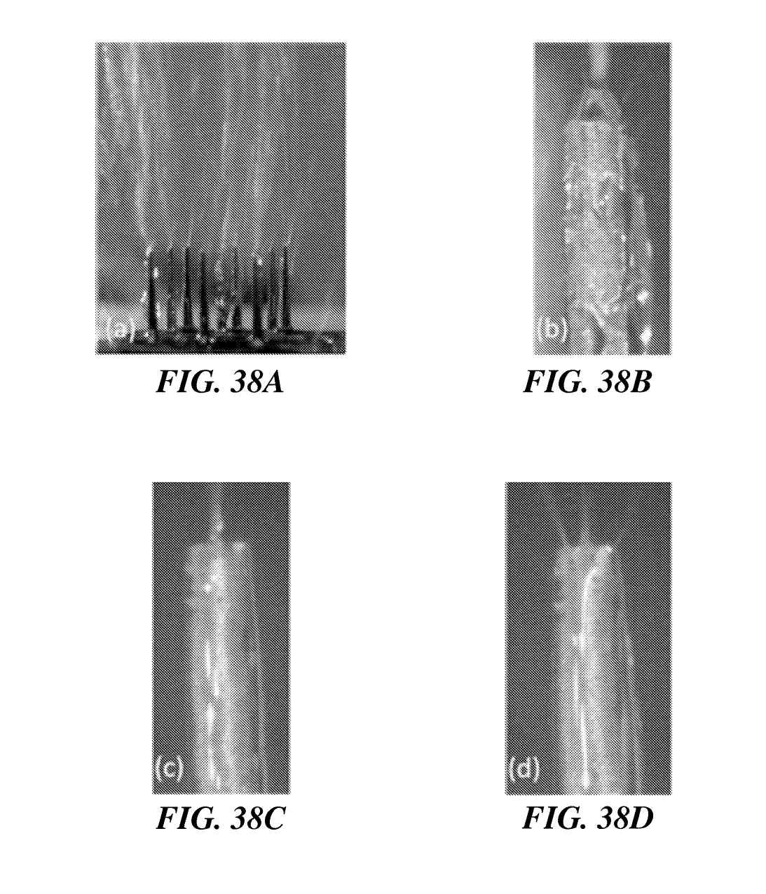

In one emission regime observed for shorter, closely-packed emitting protrusions, mobile emission jets roamed over the array area during the course of the electrospinning process. Jets occasionally pinned to individual emitting protrusion tips, but did not stay anchored for long and also emitted directly from the liquid free-surface. Electrospinning in this regime exhibited extensive chaotic whipping instability. Taller emitting protrusions were much better at anchoring emission jets to the emitting protrusion tips, and they activated at lower voltages. Not wishing to be bound by any particular theory, it is believed that the longer emitting protrusions were activated at lower voltages due to stronger electric field enhancement. FIG. 38A shows an array of nine 5 mm-tall emitting protrusions, each generating one or more jets from its tip; they are also able to support Taylor cones typical of traditional needle electrospinning sources that produce initially wider fibers (FIG. 38B) that narrow due to whipping on their way to the collector. This regime was characterized by chaotic electrostatic whipping instability, but offered more control due to the improved jet anchoring.

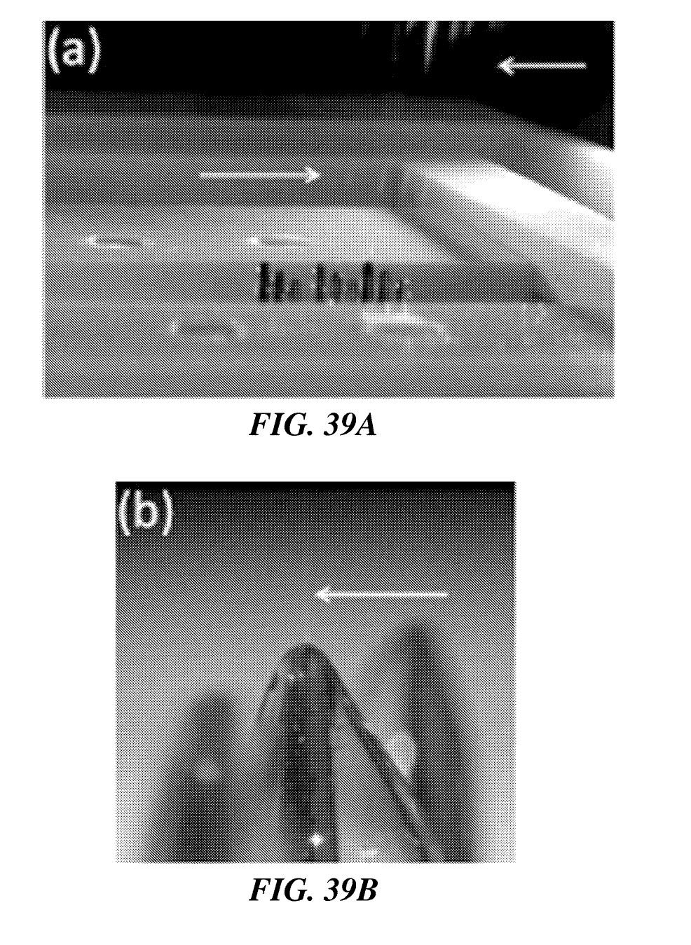

The 5 mm-tall electrospinning emitting protrusions could also support a more stable regime of emission at shorter working distances and lower voltages. However, such emission was more difficult to maintain, especially uniformly across the array. It was highly sensitive, not only to the operating voltage and alignment of the emitter and extractor electrode, but to the specific electric field profile as influenced by surrounding objects. Sometimes the strong field enhancement characteristic of shorter working distances produced a corona discharge, which seemed to inhibit electrospinning FIG. 39A captures stable emission from a 5 mm-tall array that sits in a bath of polymer solution and is partially shielded by the dielectric base. Only part of the array actually emitted fibers, but they were finer upon emission (FIG. 39B) and therefore, they required less whipping and stretching to reach desirable diameters. For an identical solution of 2.8% w/v PEO in 60/40 ethanol/water spun from 5 mm spikes, a sample of chaotically whipped fibers had an average diameter of 166 nm while a sample of stable fibers averaged 209 nm Reliably producing such narrow fibers without whipping can minimize jet-to-jet interaction and greatly increase the density with which emitting protrusions may be packed.

The following applications are hereby incorporated herein by reference in their entirety for all purposes: U.S. Provisional Patent Application Ser. No. 61/827,905, filed May 28, 2013, and entitled “High-Throughput Manufacturing of Nanofibers Using Massive Arrays of Electrospinning Emitters”; U.S. Provisional Patent Application Ser. No. 61/827,893, filed May 28, 2013, and entitled “Bio-Inspired Electrospray Emitter Arrays for High-Throughput Ionization of Liquids”; U.S. patent application Ser. No. 13/918,742, filed Jun. 14, 2013, and entitled “Electrospraying Systems and Associated Methods”; and U.S. patent application Ser. No. 13/918,759, filed Jun. 14, 2013 under Attorney Docket Number M0925.70380US01, and entitled “Electrically-Driven Fluid Flow and Related Systems and Methods, Including Electrospinning and Electrospraying Systems and Methods.”

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. An emitter configured for use in an electrospraying device, comprising:
an array of protrusions extending from an emitter substrate, at least a portion of the protrusions in the array comprising a plurality of elongated nanostructures extending from external surfaces of the protrusions.

2. The emitter of claim 1, wherein at least a portion of the elongated nanostructures are nanotubes.

3. The emitter of claim 2, wherein at least a portion of the elongated nanostructures are carbon nanotubes and/or inorganic nanotubes.

4. The emitter of any one of claims 1-3, wherein at least a portion of the elongated nanostructures are nanofibers.

5. The emitter of claim 4, wherein at least a portion of the elongated nanostructures are carbon nanofibers and/or silicon carbide nanofibers.

6. The emitter of any one of claims 1-5, wherein the elongated nanostructures are substantially aligned.

7. An emitter configured for use in an electrospraying device, comprising:
an array of protrusions extending from an emitter substrate, at least a portion of the protrusions in the array comprising a plurality of ordered nanostructures extending from external surfaces of the protrusions.

8. An emitter configured for use in an electrospraying device, comprising:
an array of protrusions extending from an emitter substrate, at least a portion of the protrusions in the array comprising a plurality of nanostructures extending from an ordered intermediate material between the nanostructures and external surfaces of the protrusions.

9. The emitter of claim 8, wherein the ordered intermediate material comprises a catalyst used to form the nanostructures.

10. The emitter of any one of claims 8-9, wherein the ordered intermediate material comprises a metal.

11. The emitter of claim 10, wherein the metal comprises iron and/or gold.

12. The emitter of any one of claims 8-11, wherein the ordered intermediate material comprises a plurality of islands of the intermediate material.

13. The emitter of claim 12, wherein each of the islands of intermediate material have a nearest neighbor distance, and the standard deviation of the nearest neighbor distances are less than about 100% of the average of the nearest neighbor distances.

14. The emitter of any one of claims 7-13, wherein at least a portion of the nanostructures are nanotubes.

15. The emitter of claim 14, wherein at least a portion of the nanostructures are carbon nanotubes and/or inorganic nanotubes.

16. The emitter of any one of claims 7-15, wherein at least a portion of the nanostructures are nanofibers.

17. The emitter of claim 16, wherein at least a portion of the nanostructures are carbon nanofibers and/or silicon carbide nanofibers.

18. The emitter of any one of claims 1-17, wherein at least a portion of the emitter substrate and/or the emitters are formed of a semiconductor.

19. The emitter of claim 18, wherein the semiconductor comprises silicon.

20. The emitter of any one of claims 1-19, wherein at least a portion of the protrusions have maximum cross-sectional dimensions of at least about 1 micron.

21. The emitter of any one of claims 1-20, wherein the array comprises at least 10 protrusions having an aerial density of at least about 10 protrusions/cm².

22. The emitter of claim 21, wherein the protrusions have an aerial density of between about 10 protrusions/cm² and about 100,000 protrusions/cm².

23. The emitter of any one of claims 1-22, wherein the nanostructures are configured to transport fluid from bases of the protrusions to tips of the protrusions via capillary forces.

24. The emitter of any one of claims 1-23, wherein the protrusions do not contain internal fluid passageways.

25. A system, comprising:
the emitter of any one of claims 1-24; and
an electrode;
wherein, when a voltage is applied across the emitter and electrode and the emitter is exposed to a fluid, droplets of the fluid are emitted from at least a portion of the protrusions of the emitter toward the electrode.

26. The system of claim 25, wherein the fluid is an ionic fluid.

27. The system of any one of claims 25-26, wherein the fluid comprises a plurality of particles suspended in the fluid.

28. The system of claim 27, wherein the plurality of particles suspended in the fluid forms a colloid.

29. The system of claim 28, wherein the plurality of particles makes up about 1 vol % or less of the colloid.

30. The system of any one of claims 27-29, wherein at least a portion of the particles are nanoparticles.

31. The system of any one of claims 27-30, wherein at least a portion of the particles comprise one or more metals.

32. The system of claim 31, wherein at least a portion of the particles comprise tungsten, cobalt, iron, nickel, molybdenum, copper, gold, silver, platinum, palladium, aluminum, zinc, tantalum, and/or titanium.

33. The system of any one of claims 27-32, wherein at least a portion of the particles comprise a ceramic materials, a carbon-containing material, a dielectric material, a semiconductor, a piezoelectric material, and/or a magnetic material.

34. The system of claim 33, wherein at least a portion of the particles comprise titanium dioxide.

35. A method, comprising applying a voltage across the emitter of any one of claims 1-34 and an electrode such that fluid positioned between the emitter and the electrode is emitted from at least a portion of the protrusions of the emitter toward the electrode.

36. The method of claim 35, wherein the fluid is an ionic fluid.

37. The method of any one of claims 35-36, wherein the fluid comprises a plurality of particles suspended in the fluid.

38. The method of claim 37, wherein the plurality of particles suspended in the fluid forms a colloid.

39. The method of claim 38, wherein the plurality of particles makes up about 1 vol % or less of the colloid.

40. The method of any one of claims 37-39, wherein at least a portion of the particles are nanoparticles.

41. The method of any one of claims 37-40, wherein at least a portion of the particles comprise one or more metals.

42. The method of claim 41, wherein at least a portion of the particles comprise tungsten, cobalt, iron, nickel, molybdenum, copper, gold, silver, platinum, palladium, aluminum, zinc, tantalum, and/or titanium.

43. The method of any one of claims 37-42, wherein at least a portion of the particles comprise a ceramic material, a carbon-containing material, a dielectric material, a semiconductor, a piezoelectric material, and/or a magnetic material.

44. The method of claim 43, wherein at least a portion of the particles comprise titanium dioxide.

45. The method of any one of claims 37-44, wherein applying the voltage across the emitter and the electrode results in the expulsion of at least a portion of the particles within the fluid from the emitter toward the electrode.

46. A method of making an emitter configured for use in an electrospraying device, comprising:
etching a fabrication substrate to produce a plurality of protrusions extending from the fabrication substrate; and
depositing a plurality of nanostructures on external surfaces of the protrusions.

47. The method of claim 46, wherein depositing the plurality of nanostructures comprises performing a chemical reaction to form the plurality of nanostructures.

48. The method of claim 47, wherein depositing the plurality of nanostructures comprises performing chemical vapor deposition.

49. The method of claim 48, wherein performing chemical vapor deposition comprises performing plasma enhanced chemical vapor deposition.

50. The method of any one of claims 46-49, wherein etching the fabrication substrate comprises performing reactive ion etching of the fabrication substrate.

51. The method of any one of claims 46-50, comprising depositing a catalyst over the fabrication substrate after etching the fabrication substrate to produce the plurality of protrusions and prior to depositing the plurality of nanostructures on the external surfaces of the protrusions.

52. The method of claim 51, comprising removing at least a portion of the catalyst after depositing the catalyst over the fabrication substrate.

53. The method of claim 52, wherein removing at least a portion of the catalyst results in the formation of catalyst nanoparticles over the fabrication substrate.
